(19) United States
(12) Patent Application Publication
(10) Pub. No.: US 2015/0263029 A1
(43) Pub. Date: Sep. 17, 2015

(54) NON-VOLATILE MEMORY DEVICES AND METHODS OF MANUFACTURING THE SAME

(71) Applicants: KI-JEONG KIM, HWASEONG-SI (KR); DAE-HYUN JANG, SUWON-SI (KR); BYEONG-JU KIM, HWASEONG-SI (KR); JUNG-IK OH, SEONGNAM-SI (KR)

(72) Inventors: KI-JEONG KIM, HWASEONG-SI (KR); DAE-HYUN JANG, SUWON-SI (KR); BYEONG-JU KIM, HWASEONG-SI (KR); JUNG-IK OH, SEONGNAM-SI (KR)

(21) Appl. No.: 14/645,758

(22) Filed: Mar. 12, 2015

(30) Foreign Application Priority Data
Mar. 12, 2014 (KR) 10-2014-0028685

(51) Int. Cl. H01L 27/115; H01L 23/544

(52) U.S. Cl. CPC H01L 27/11575; H01L 23/544; H01L 27/11519; H01L 27/11526; H01L 27/11548; H01L 27/11551; H01L 27/11565; H01L 27/11573; H01L 27/11578; H01L 2223/54453; H01L 2223/54426

(57) ABSTRACT

A semiconductor memory device includes a substrate including a cell region and peripheral region. The cell region is equipped with a photolithographic reference mark pattern and includes a memory cell array region and a staircase-shaped connection region connected to memory cells of the memory cell array region.

### CROSS-REFERENCE TO RELATED APPLICATION

A claim of priority under 35 USC §119 is made to Korean Patent Application No. 10-2014-0028685, filed on Mar. 12, 2014, in the Korean Intellectual Property Office (KIPO), the contents of which are herein incorporated by reference in their entirety.

### BACKGROUND

The inventive concepts generally relate to semiconductor memory devices, and more particularly, the inventive concepts relate to non-volatile memory devices and to methods of fabricating non-volatile memory devices.

As the semiconductor industry continues its advance, increased device integration, reduced power consumption and/or faster operation speeds are often required. Among these, device integration is particularly important since it has a significant impact on the price per unit of data storage.

As a result, in response to the demand for highly integrated semiconductor devices, fabrication technology has advanced to permit semiconductor devices of diverse structures to be manufactured, departing from traditional substantially flat or two-dimensional semiconductor devices. However, as semiconductor devices become highly integrated and diverse semiconductor device structures emerge, it is increasingly difficult to secure process margins for connecting diverse and complex patterns in semiconductor devices to conductive lines and other patterns. If a failure occurs in a semiconductor device a manufacturing process, the reliability of the semiconductor device decreases, which may cause lower performance of an electronic device incorporating the semiconductor device. Accordingly, it is desirable to enhance the reliability of highly integrated semiconductor devices by securing the process margins in semiconductor devices having complex patterns.

### SUMMARY

According to an aspect of the inventive concept, a semiconductor memory device is provided which includes a memory cell array region comprising an array of vertically arranged memory cells intersecting a stack of horizontally extending first connection lines, and a connection region adjacent the memory cell array region in a first direction in a top view, wherein the stack of first connection lines extend from the memory cell array region into the connection region to define a first staircase-shaped structure, and wherein ends of the connection lines constitute treads of the first staircase-shaped structure. The semiconductor device further includes a non-active region comprising second connection lines which define a second staircase-shaped structure in which ends of the second connection lines constitute treads of the second staircase-shaped structure. The second staircase-shaped structures comprises a staircase protrusion section located adjacent the memory cell array region in a second direction in the top view, the second direction perpendicular the first direction, and the staircase protrusion section includes first treads protruding from second treads in the top view, the first treads extending perpendicular to the first direction in the top view.

The first treads may protrude in a direction towards the memory cell array region in the top view.

The first treads may protrude in a direction away from the memory cell array region in the top view.

The staircase protrusion section may be a first staircase protrusion section, and the semiconductor memory device may further include a second stair protrusion section located on an opposite side of the memory cell array region relative the first staircase protrusion section.

The semiconductor memory device may include two or more staircase protrusion sections on each of opposite sides of the memory cell array region.

The staircase protrusion section may be a first staircase protrusion section, and the semiconductor memory may further include a second stair protrusion section located on a same side of the memory cell array region relative the first staircase protrusion section and closer to the memory cell array region relative to the first staircase protrusion section.

The first connections lines of the connection region may be contained in same respective layers as the second connection lines of the non-active region.

The cut-line may be interposed between the memory cell array area and the staircase protrusion section.

The first connection lines may be conductive such as word lines, and the ends of the first connection lines include respective word line pad areas.

According to another aspect of the inventive concept, a semiconductor memory device is provided which includes a stack of layers, and an isolating structure separating the stack of layers to define a active region on one side of the isolating structure and a non-active region on the other side of the isolating structure. The active region includes a memory cell array region containing a first portion of the layers, and a connection region in which a second portion of the layers defines a staircase-shaped structure, wherein ends of the second portion of the layers constitute treads of the staircase-shaped structure. The non-active region includes a third portion of the layers, wherein the third portion of the layers includes a photolithographic reference mark pattern.

The third portion of the layers in the non-active region may define a second staircase-shaped structure, and ends of the third portion of the layers may constitute treads of the second staircase-shaped structure. At least one of the treads of the second staircase-shaped structure may constitute the photolithographic reference mark pattern. Also, at least one of the treads of the second staircase-shaped structure may protrude in a direction towards or away from the memory cell array region.

The stack of layers may include alternating first and second layers, and each first layer may be an insulating layer. Each second layer within the cell region may be a word line, and the ends of the second portion of the layers may include respective word line pad areas.

The isolating structure may be a cut line.

According to still another aspect of the inventive concept, a semiconductor memory device is provided which includes a substrate including a cell region and peripheral region. The cell region includes a memory cell array region, a staircase-shaped connection region, and a photolithographic reference mark pattern.

The semiconductor memory device may further includes a staircase-shaped structure which is separate from the staircase-shaped connection region, and the photolithographic reference mark pattern may be located within the staircase-shaped structure.

The staircase-shape connection region may include a plurality of treads having respective word line pads.

According to yet another aspect of the inventive concept, a method of fabricating a semiconductor device is provided which includes forming a stack of layers on a substrate, the substrate including a cell region and a peripheral region. The method further includes forming a reference layer pattern defining a reference mark on a portion of the stack located within the cell region, and forming a preliminary photoresist pattern on the reference layer pattern, the preliminary photoresist pattern having a reference key overlaying the cell region. The method still further includes using the reference key and the reference mark to determine at least one of a scale and a position of the preliminary photoresist pattern, and when the at least one of the scale and the position of the preliminary photoresist pattern is within a predetermined design tolerance, etching the stack using the preliminary photoresist pattern as an etch mask.

When the at least one of the scale and the position of the preliminary photoresist pattern is not within the predetermined design tolerance, the method may further include replacing the preliminary photoresist pattern with a new photoresist pattern, and etching the stack of layers using the new photoresist pattern as an etch mask.

The use of the reference key and the reference mark to determine the at least one of the scale and the position of the preliminary photoresist pattern may include measuring a distance as viewed in plan between a boundary of the reference key and a boundary of the reference mark, and determining the at least one of the scale and the position of the preliminary photoresist pattern based on the measured distance.

The method may further include, after etching the stack, removing the photoresist pattern or the new photoresist pattern, and patterning the stack of layers to expose ends of at least some of the layers in a connection region of the cell region, wherein the patterning produces a staircase-shaped section in the connection region in which respective ends of the at least some of the layers constitute treads of the staircase-shaped section. Also, the method may further icnlude, after patterning the stack of layers, forming a second preliminary photoresist pattern on the patterned stack of layers, the second preliminary photoresist pattern having a second reference key overlaying the cell region. The method may further include the second reference key and a second reference mark to determine at least one of a scale and a position of the second preliminary photoresist pattern. The second reference mark may be at least partially defined by an edge of a tread among the treads of the staircase-shaped section. When the at least one of the scale and the position of the second preliminary photoresist pattern is within a predetermined design tolerance, the method may further include etching the stack of layers using the second preliminary photoresist pattern as an etch mask. On the other hand, when the at least one of the scale and the position of the second preliminary photoresist pattern is not within the predetermined design tolerance, the method may further include replacing the second preliminary photoresist pattern with a new second photoresist pattern, and etching the stack of layers using the new second photoresist pattern as an etch mask.

The method may further include, after etching the stack of layers using the second preliminary photoresist pattern or the new second preliminary photoresist pattern, removing the preliminary photoresist pattern or the new preliminary photoresist pattern, and second patterning the stack of layers to expose ends of at least some other of the layers in a connection region of the cell region, wherein the second patterning produces a second staircase-shaped section in the connection region in which respective ends of the at least some other of the layers constitute treads of the second staircase-shaped section.

According to another aspect of the inventive concept, a method of fabricating a semiconductor device is provided which includes forming a stack of layers on a substrate. The method further includes forming a reference layer on the stack, forming a first photoresist pattern on the reference layer, and etching the reference layer using the first photoresist pattern to form a reference layer pattern on the stack in a cell region of the substrate. The method further includes forming a second photoresist pattern on the reference layer pattern, wherein the second photoresist pattern has one boundary that covers and is spaced, as viewed in plan, a predetermined distance along a first direction from one boundary of the reference layer pattern, and another boundary that exposes and is spaced, as viewed in plan, along a second direction from another boundary of the reference layer patter, and etching the stack using the second photoresist pattern as an etch mask. The another boundary of the second photoresist pattern delimits a recess or opening in the second photoresist pattern.

The method may further include, after etching the stack, removing the second photoresist pattern, and patterning the stack of layers to expose ends of at least some of the layers in a connection region of the cell region of the substrate, wherein the patterning produces a staircase-shaped section in the connection region in which respective ends of the at least some of the layers constitute treads of the staircase-shaped section.

According to another aspect of the inventive concept, a method of fabricating a semiconductor device is provided which includes forming a stack of layers on a substrate, forming a photoresist pattern on the stack in a cell region of the substrate, etching only some of the layers of the stack using the photoresist pattern as an etch mask, thereby leaving a lower portion of the stack unetched, and removing the etch mask. The method further includes forming a second photoresist pattern on respective ones of the etched layers of the stack and on the unetched layers of the stack, wherein the second photoresist pattern has one boundary that covers and is spaced, as viewed in plan, a distance along a first direction from one boundary of the lowermost one of the etched layers of the stack, and another boundary that exposes and is spaced, as viewed in plan, along a second direction from another boundary of the lowermost one of the etched layers, and etching at least some of the unetched layers of the stack using the second photoresist pattern as an etch mask. The another boundary of the second photoresist pattern delimits a recess or opening in the second photoresist pattern.

The method may further include, after etching the at least some of the unetched layers, removing the second photoresist pattern, and patterning the stack of layers to expose ends of at least some of the layers in a connection region of the cell region of the substrate, wherein the patterning produces a staircase-shaped section in the connection region in which respective ends of the at least some of the layers constitute treads of the staircase-shaped section.

### BRIEF DESCRIPTION OF THE DRAWINGS

The above and other aspects and features of the inventive concept will become readily understood from the detail description that follows, with reference to the accompanying drawings, in which like reference numbers refer to like elements unless otherwise noted, and in which:

FIGS. 1 through 47 are plan views and cross-sectional views illustrating fabrication stages of a vertical non-volatile memory device in accordance with example embodiments;

FIGS. 48, 49, 50, 51A, 51B and are plan views illustrating first, second and third photoresist patterns used in manufacturing a vertical non-volatile memory device in accordance with example embodiments;

FIGS. 52 through 87 are plan views and cross-sectional views illustrating fabrication stages of a vertical non-volatile memory device in accordance with example embodiments;

FIGS. 88, 89, 90 and 91 are plan views illustrating first, second and third photoresist patterns used in manufacturing a vertical non-volatile memory device in accordance with example embodiments; and

FIGS. 92 through 106 are plan views and cross-sectional views illustrating fabrication stages of a vertical non-volatile memory device in accordance with example embodiments.

### DETAILED DESCRIPTION

Example embodiments will now be described more fully with reference to the accompanying drawings, in which example embodiments are shown. Example embodiments may, however, be embodied in many different forms and should not be construed as limited to the example embodiments set forth herein. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As will be described below by way of exemplary embodiments, a semiconductor memory device may include a substrate having a cell region and peripheral region. The cell region is provided with a photolithographic reference mark pattern, and includes a memory cell array region and a staircase-shaped connection region for application or sensing of voltages to or from memory cells of the memory cell array region. The photolithographic reference mark pattern may be located in a non-active region of the cell region, and may be separated by from the memory cell array region and the connection region by an isolating structure such as a cut line. In addition, the photolithographic reference mark pattern may be contained in a staircase-shaped structure which is separate from the staircase-shaped connection region.

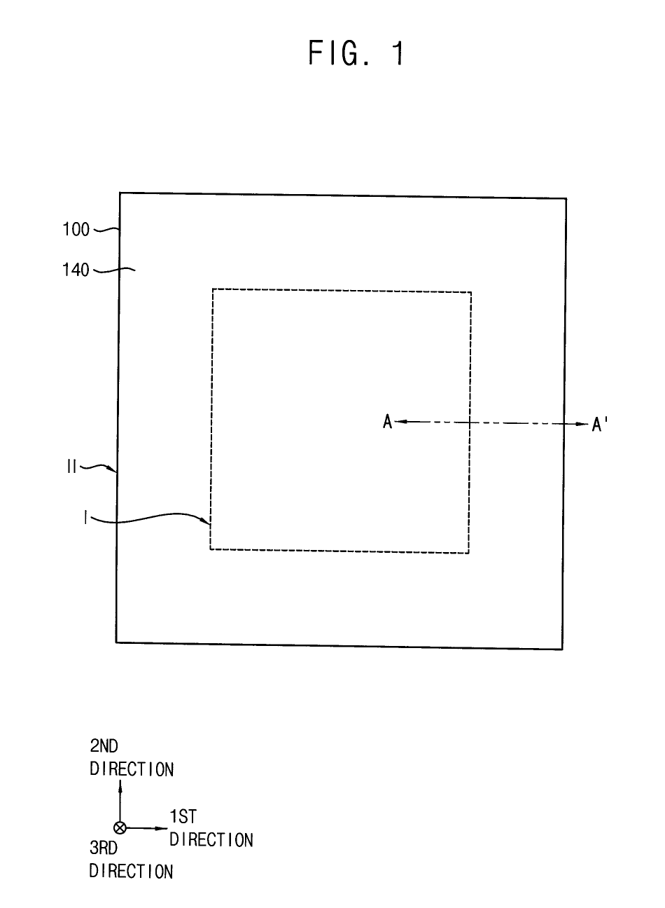

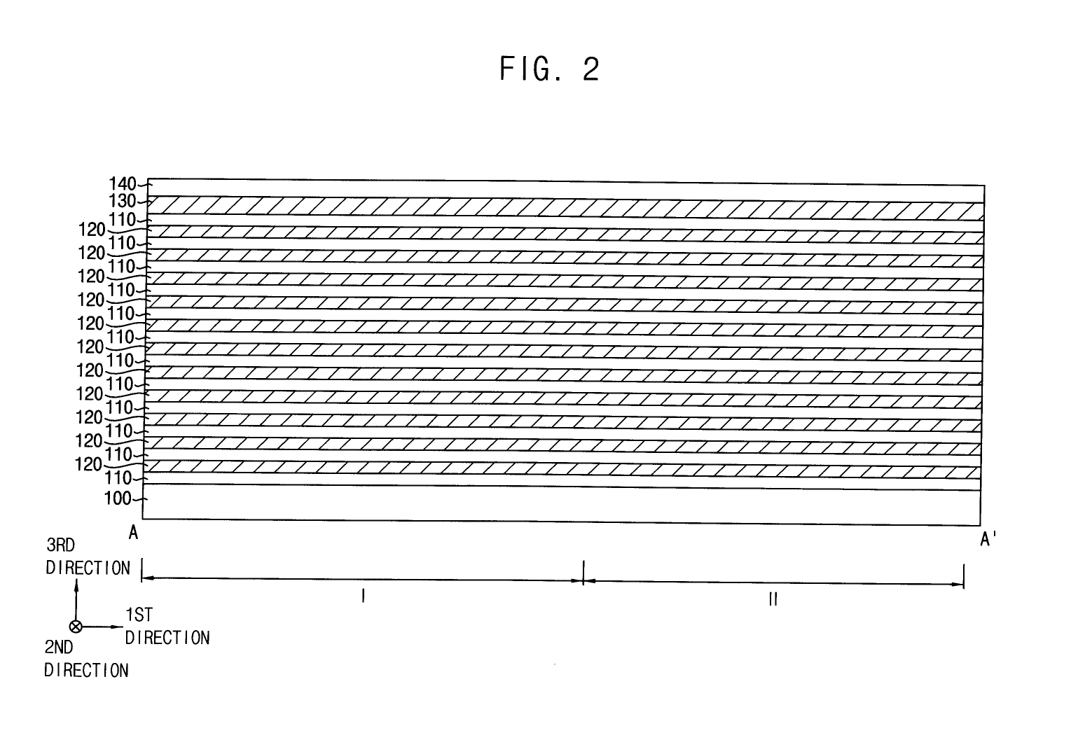

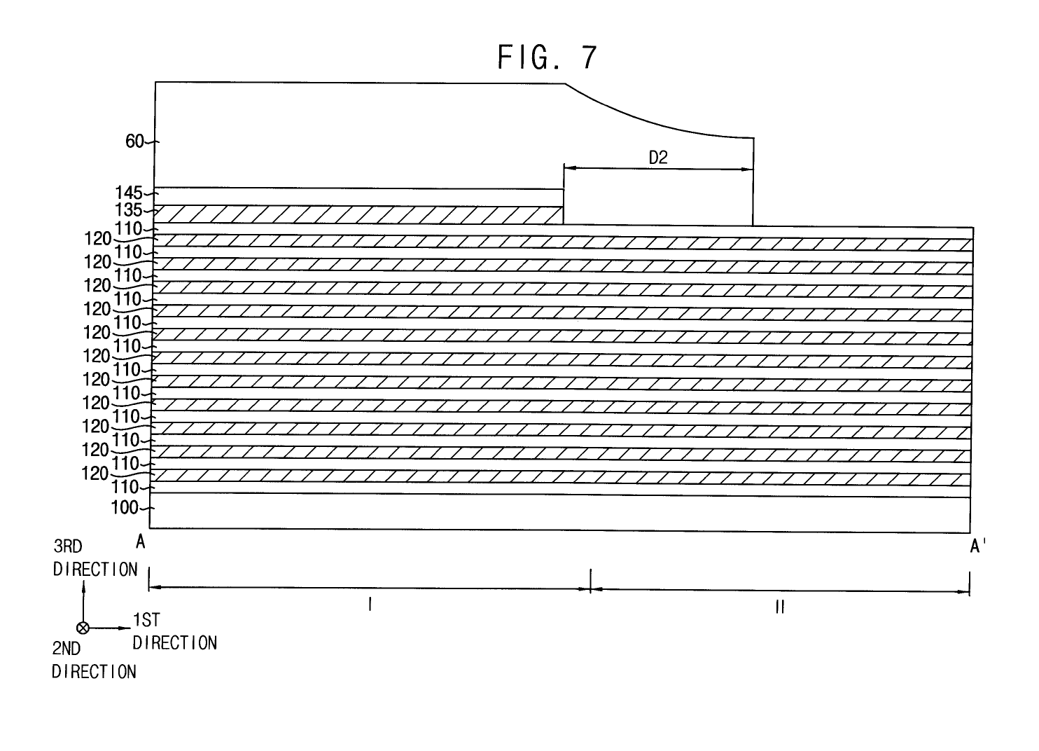

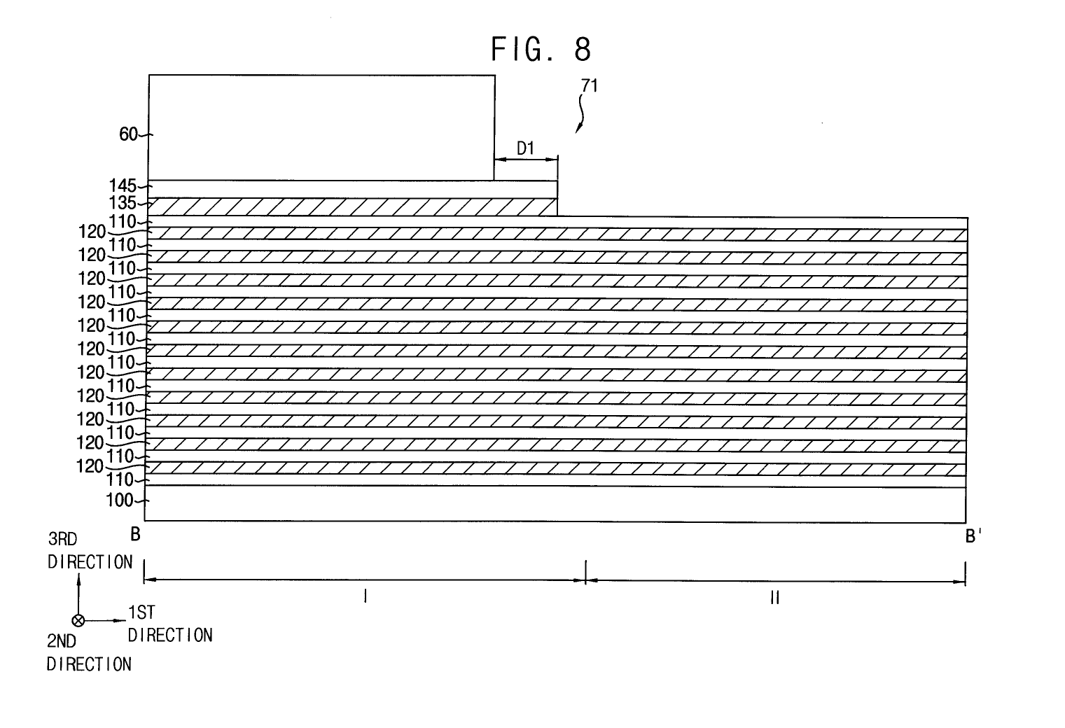

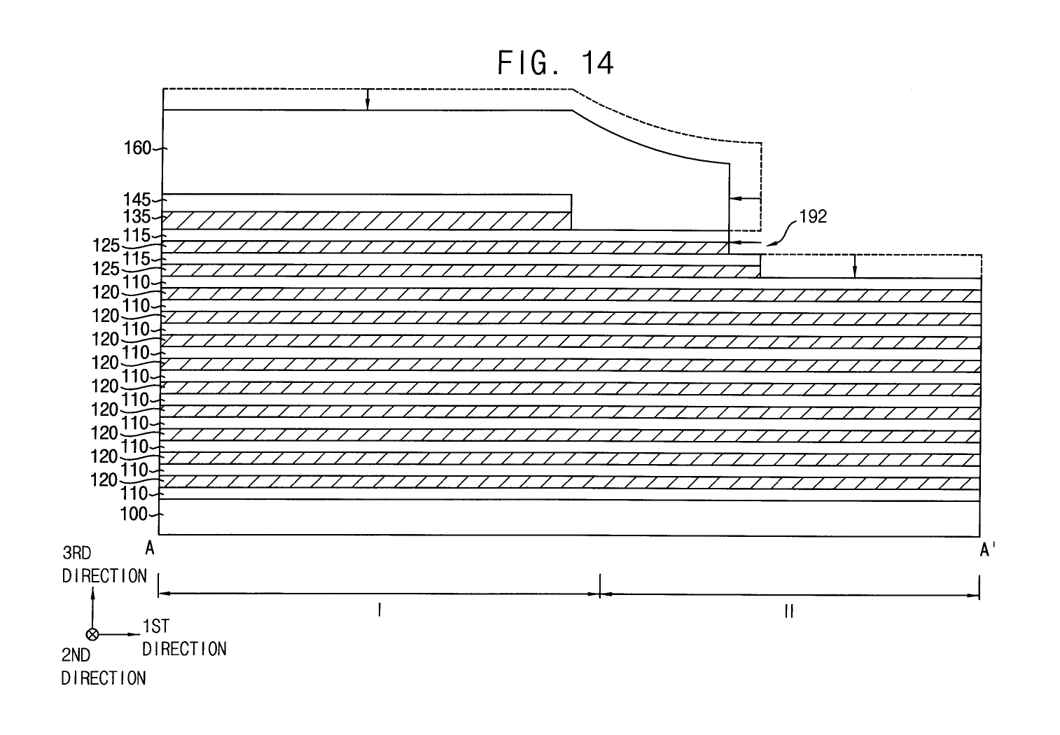

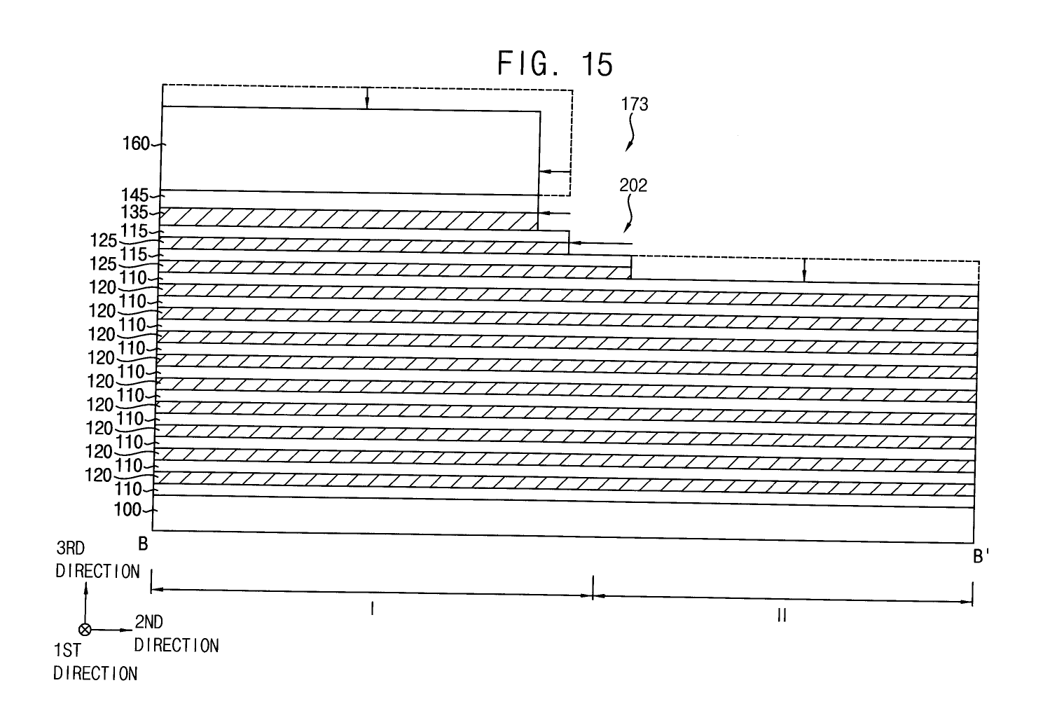

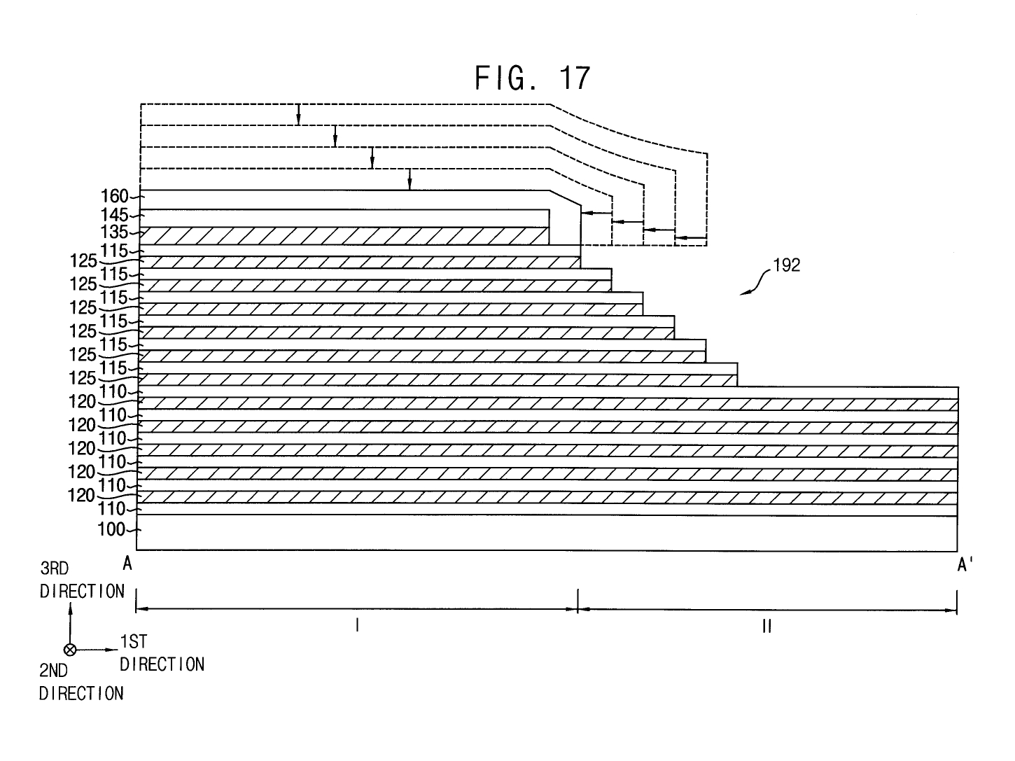

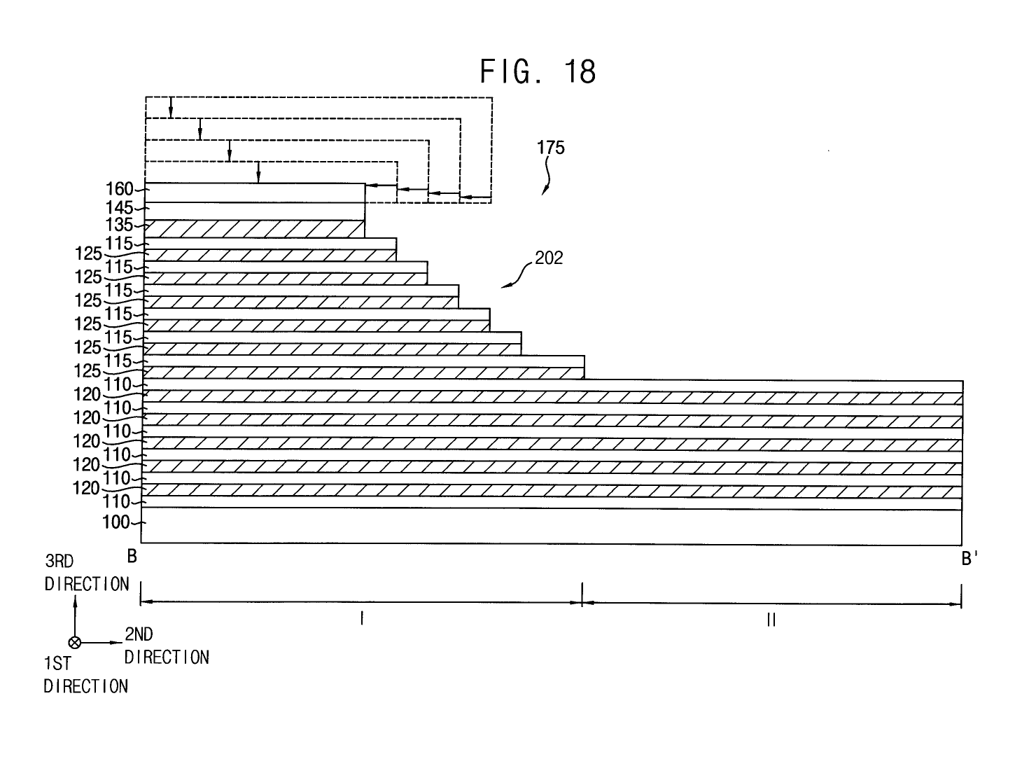

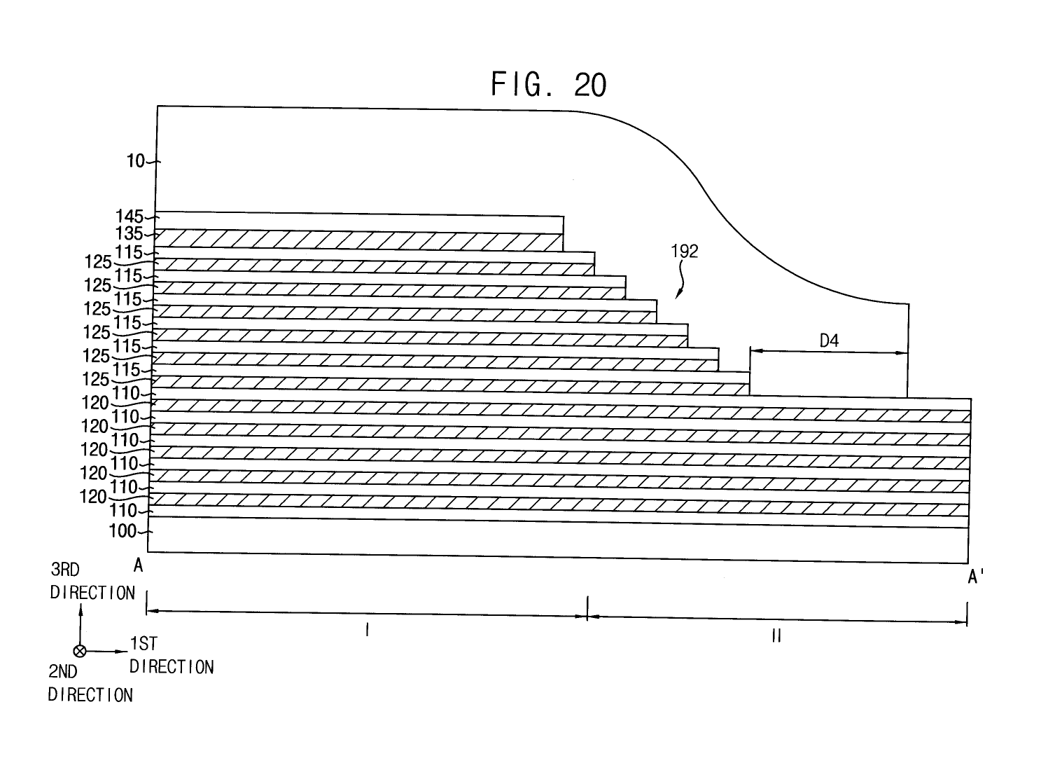

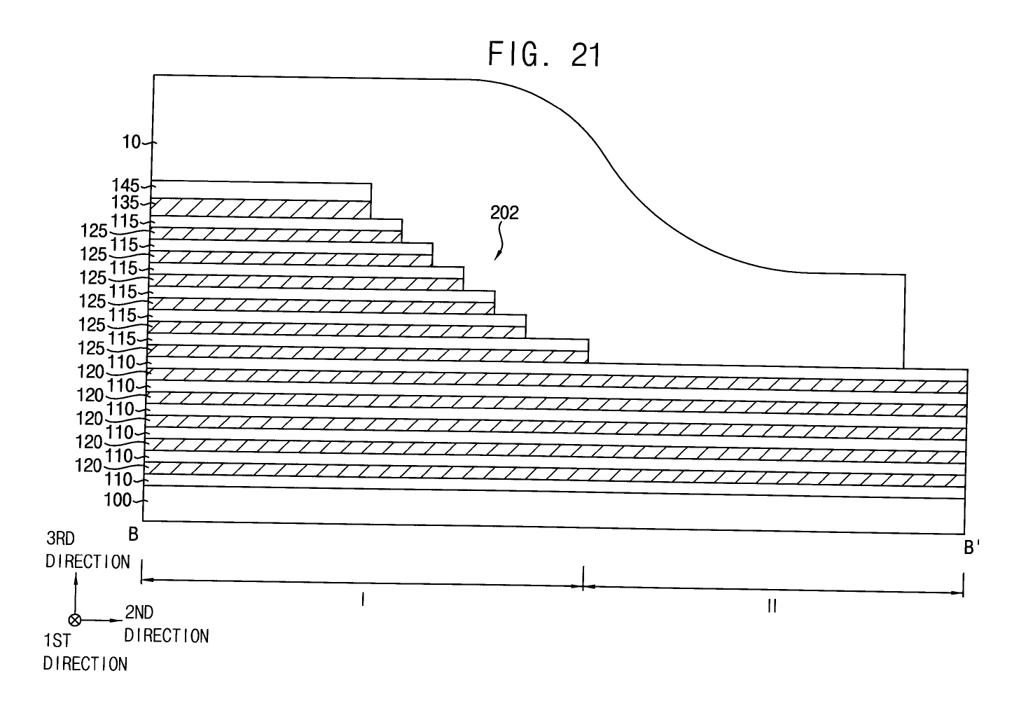

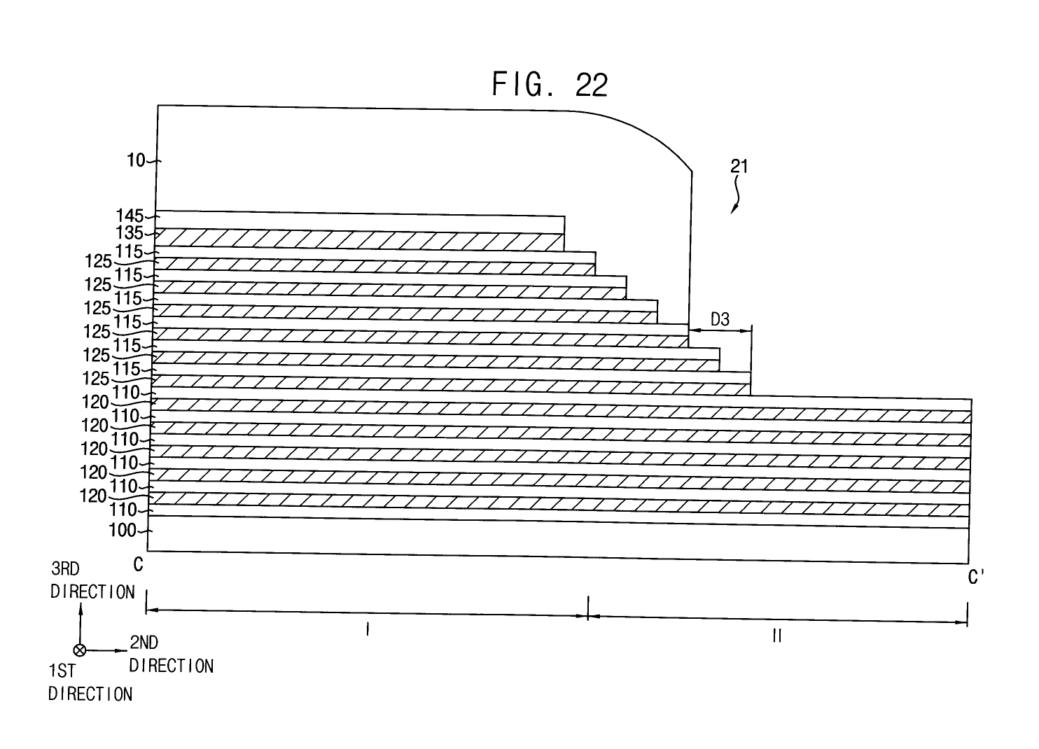

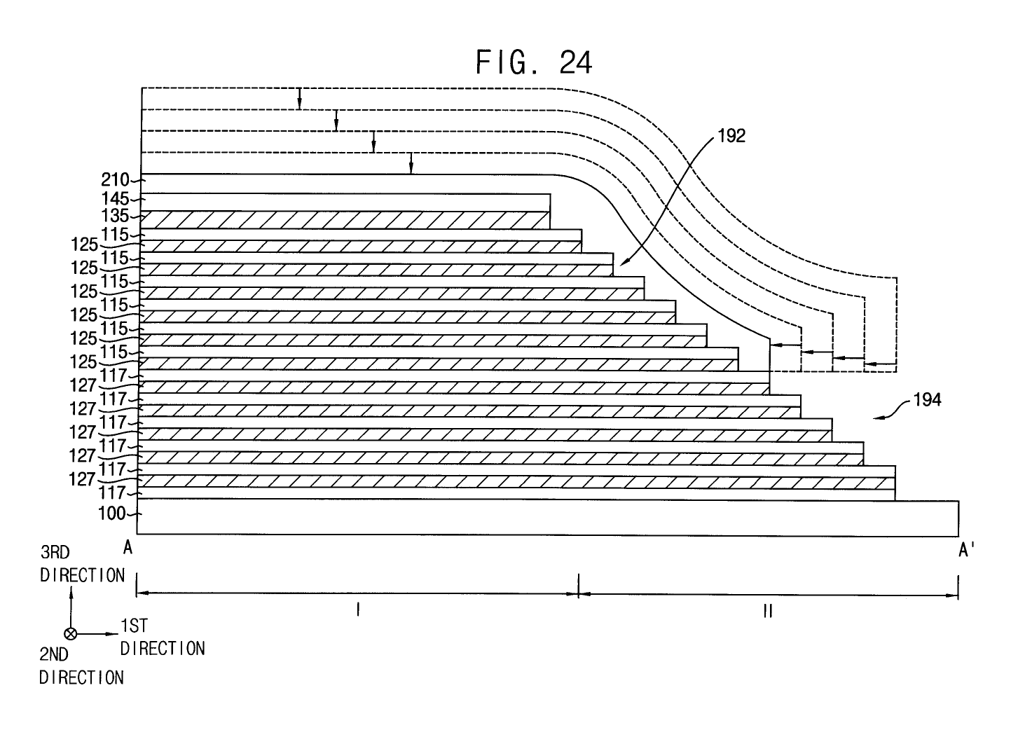

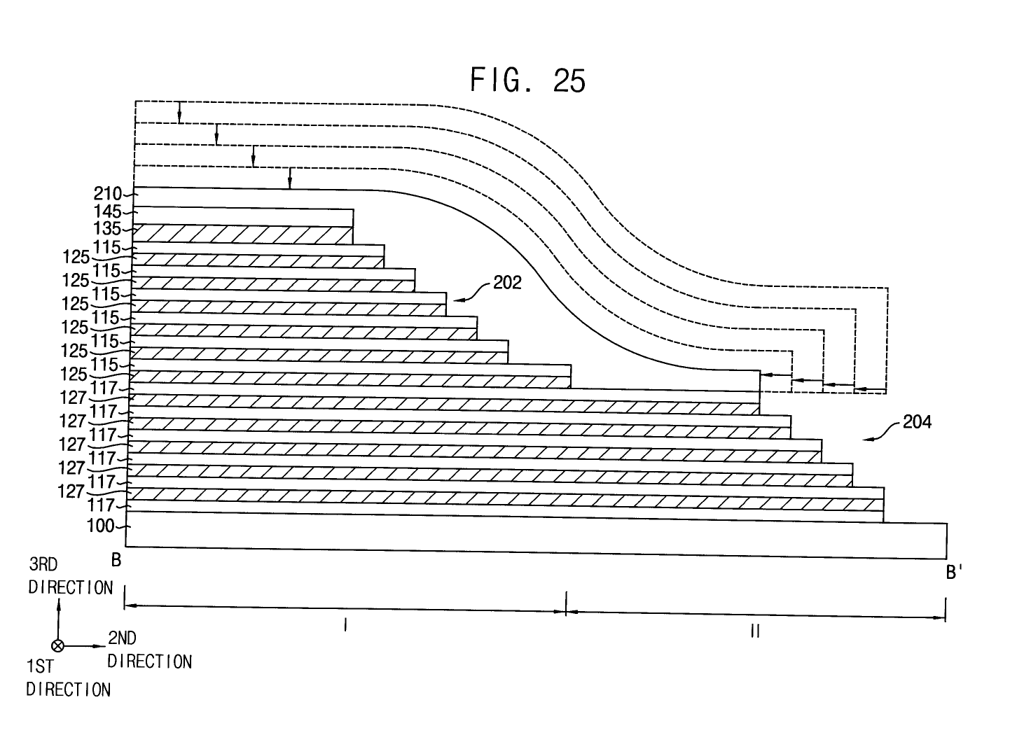

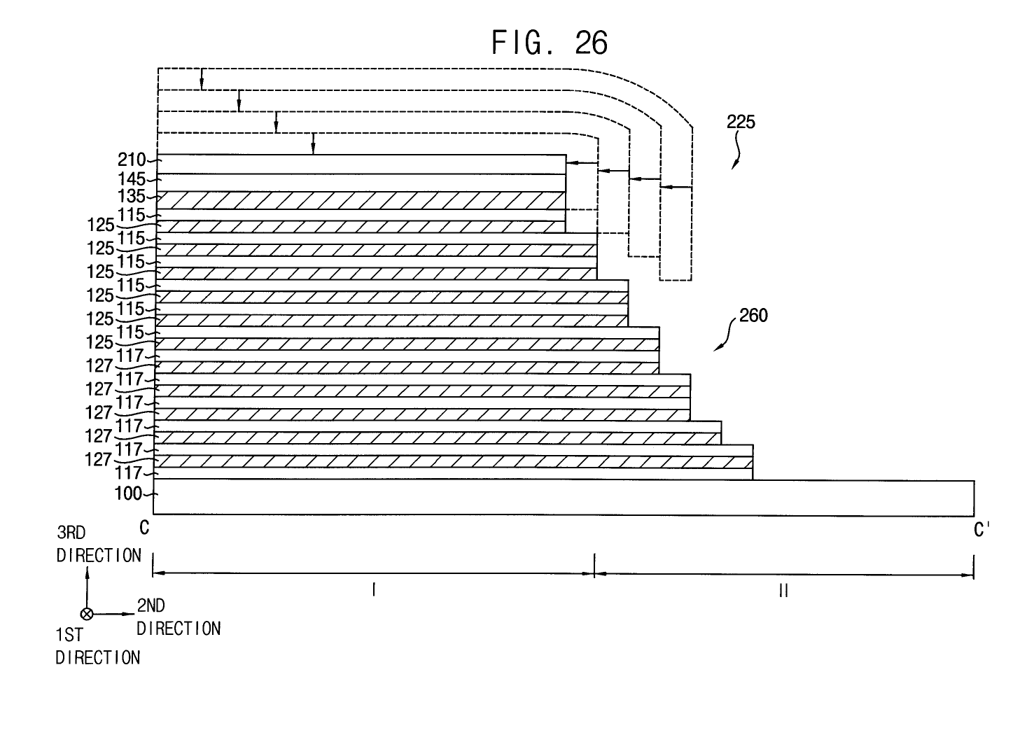

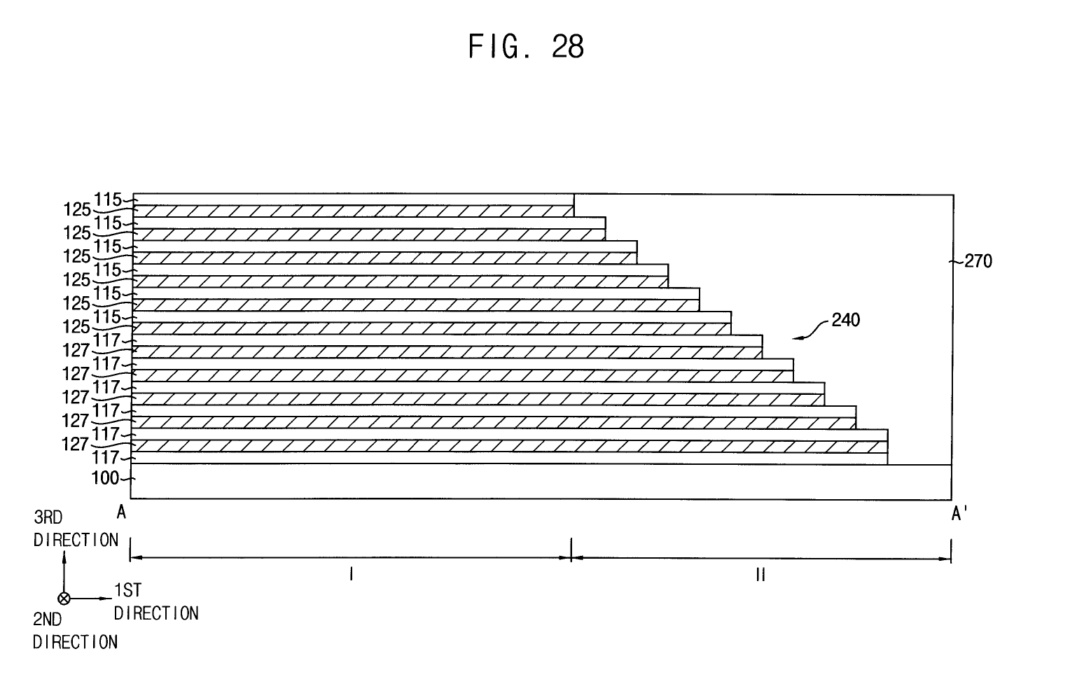

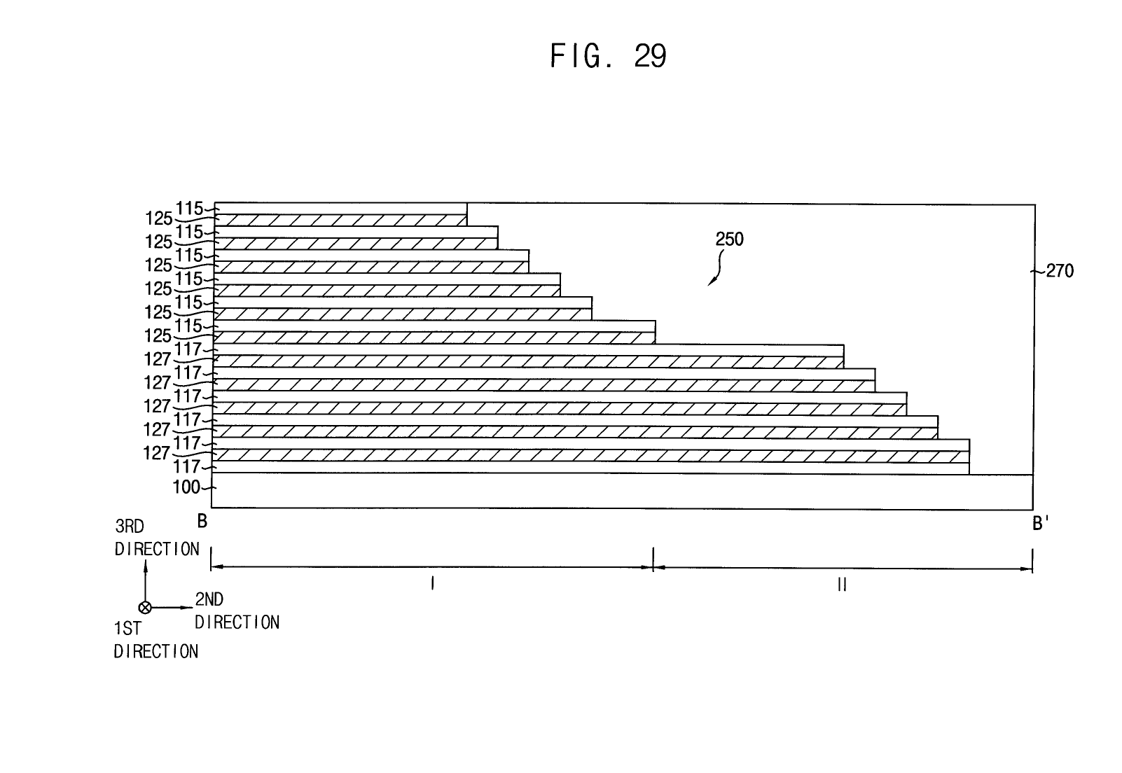

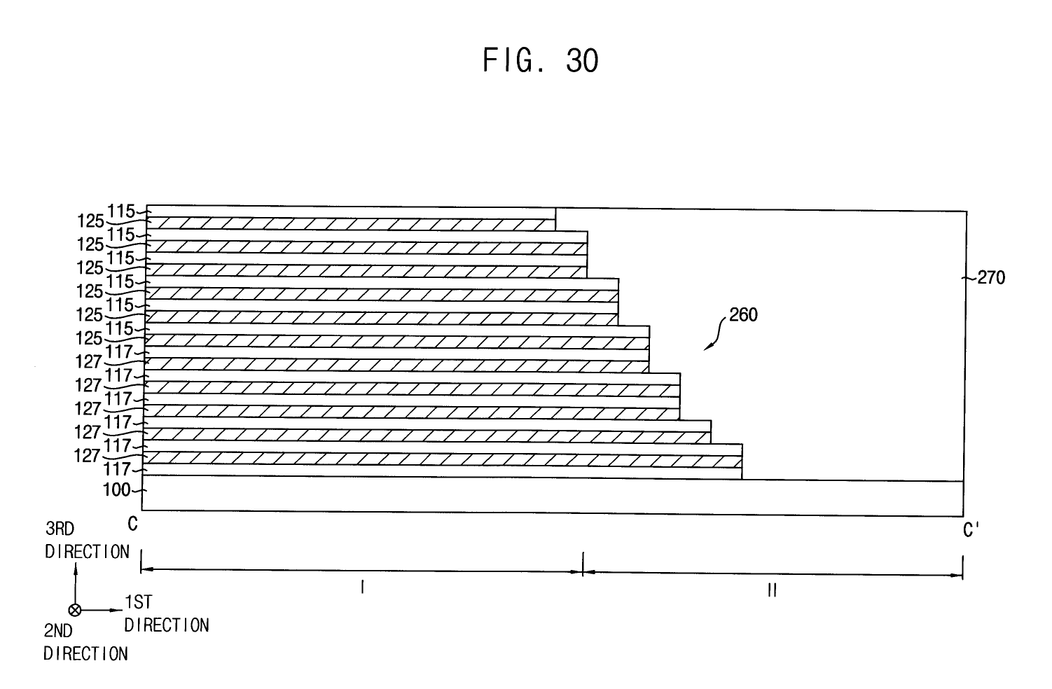

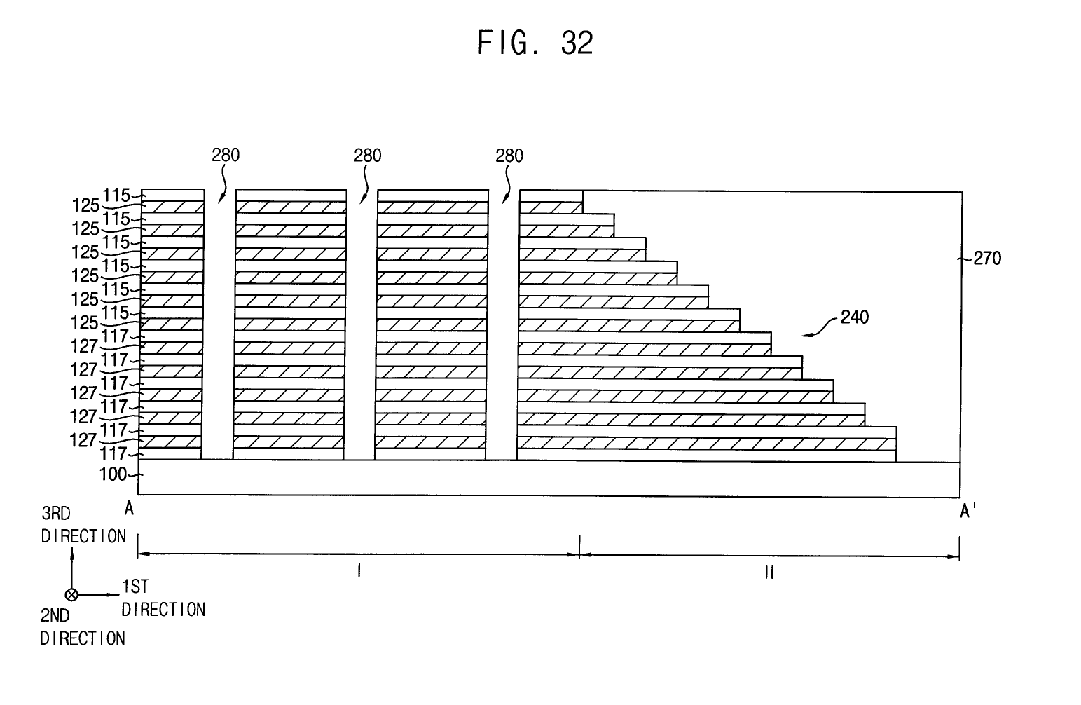

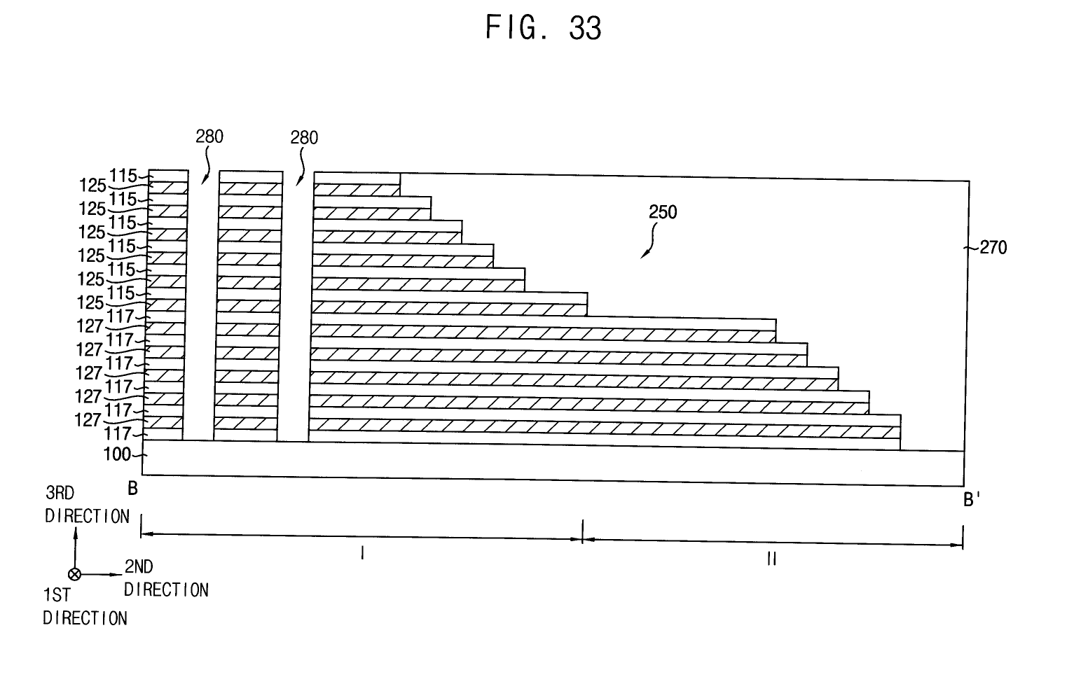

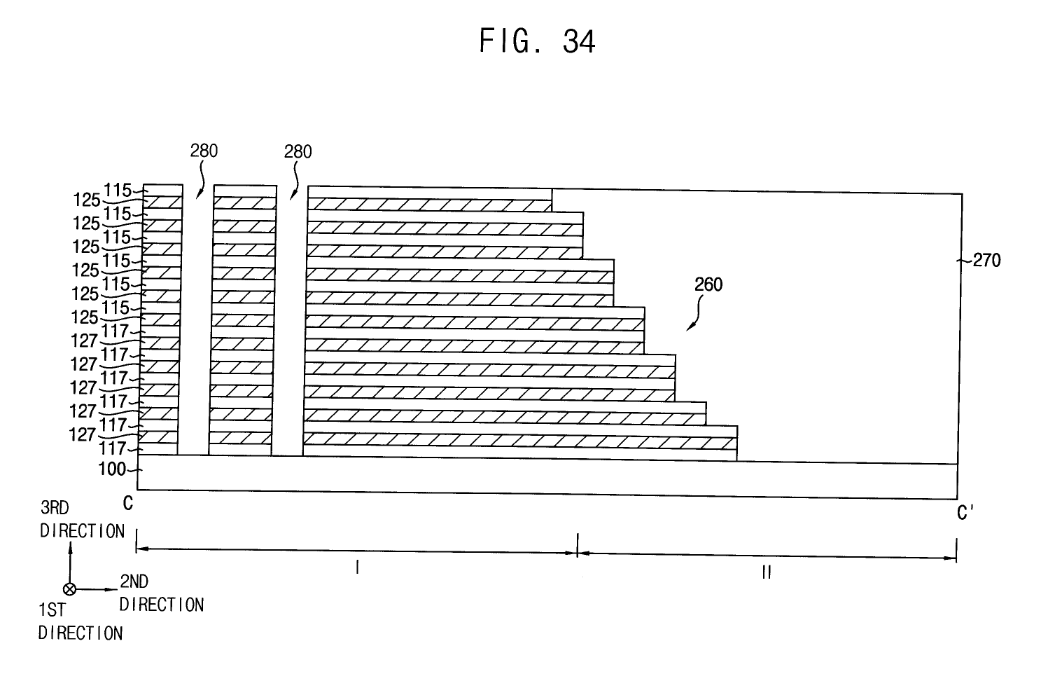

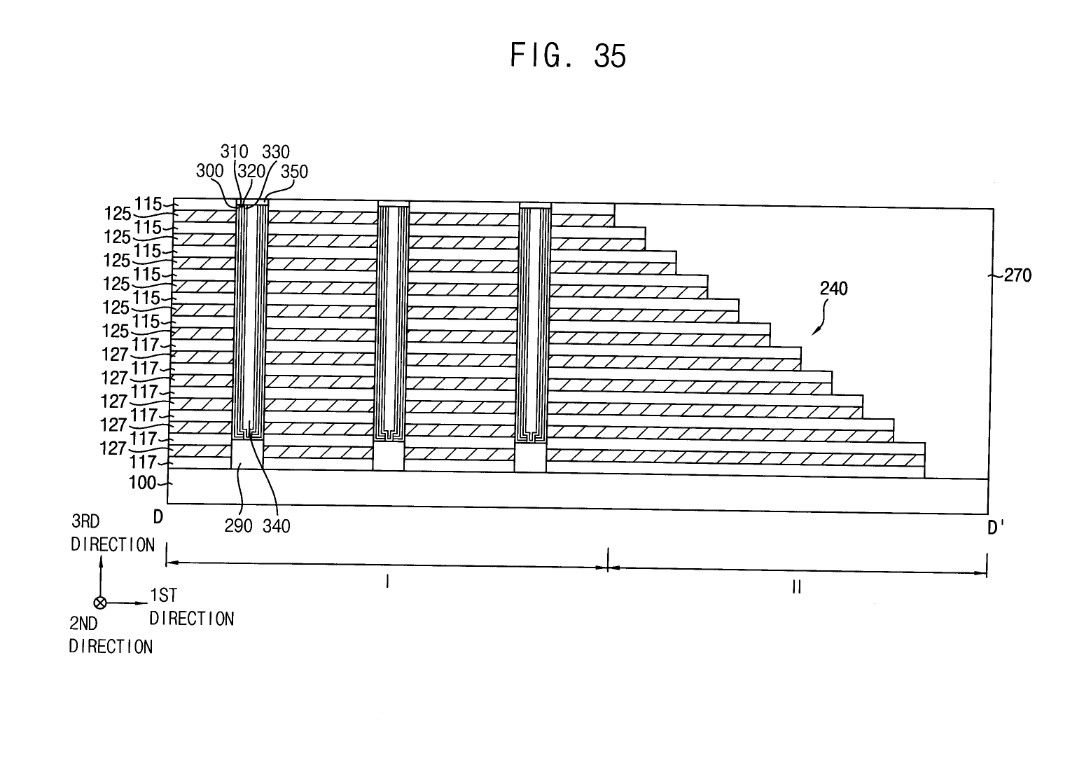

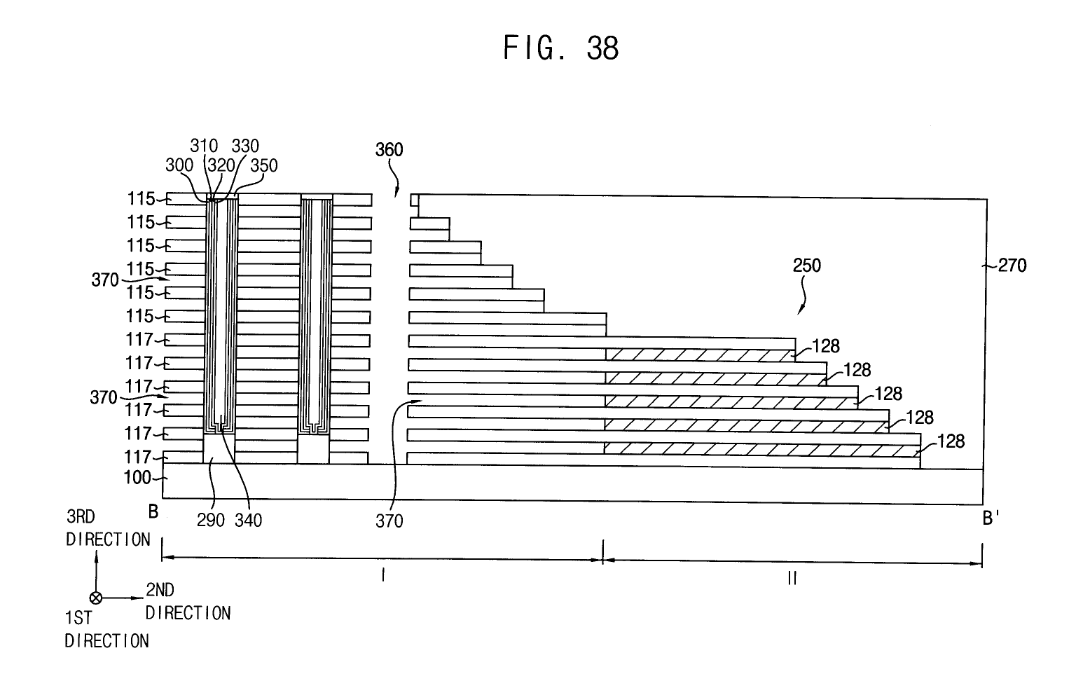

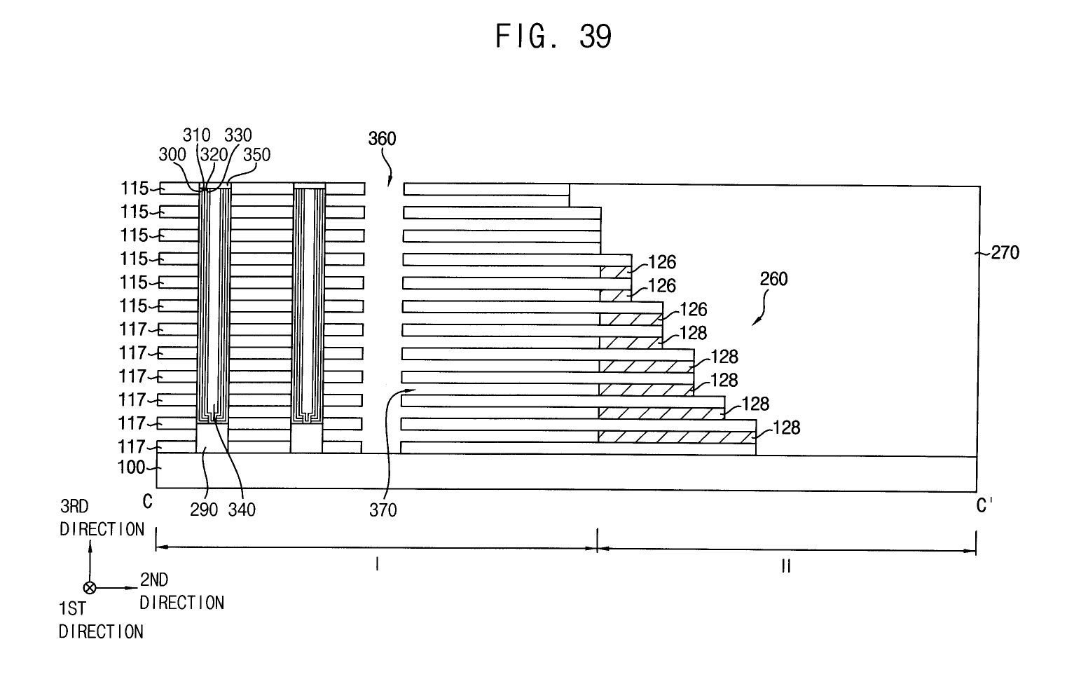

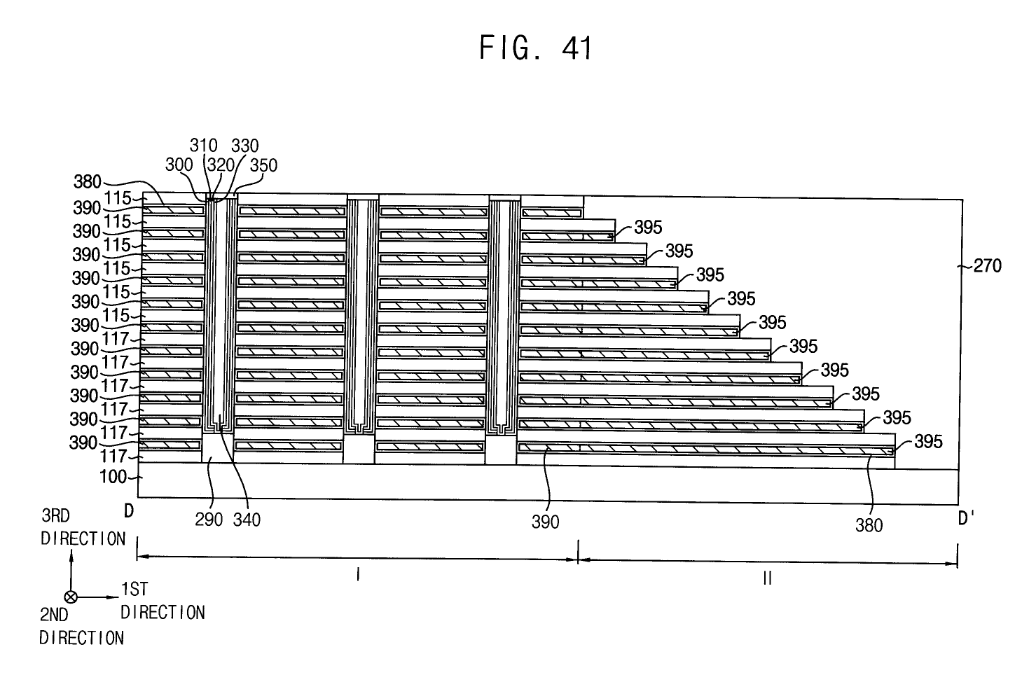

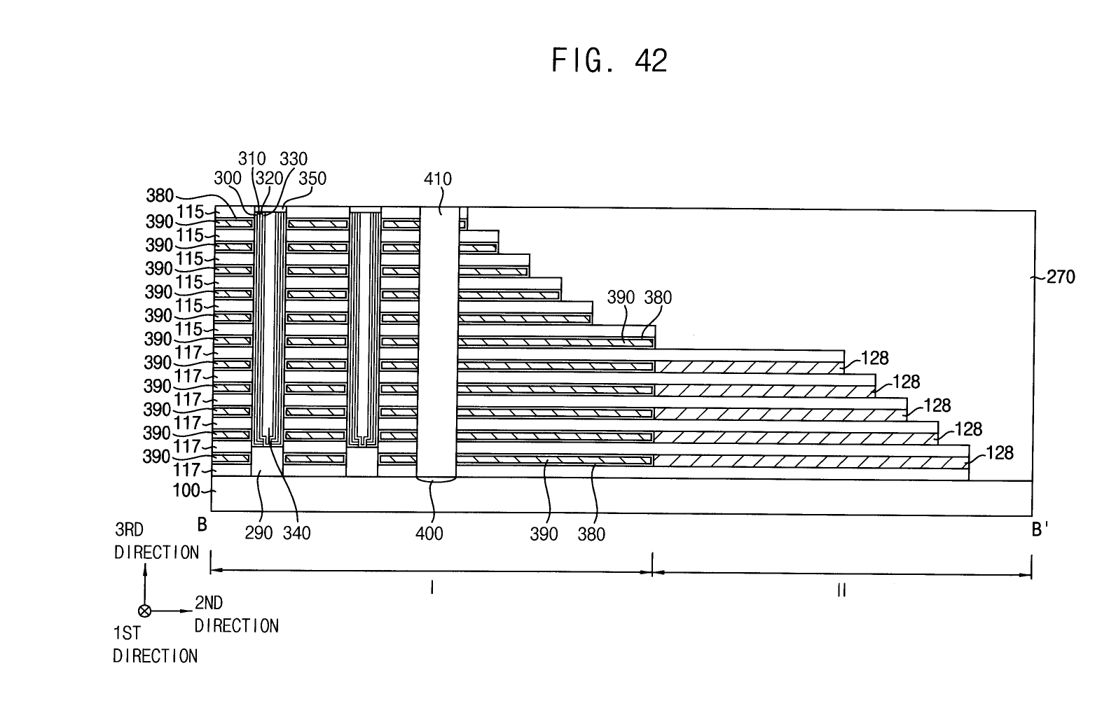

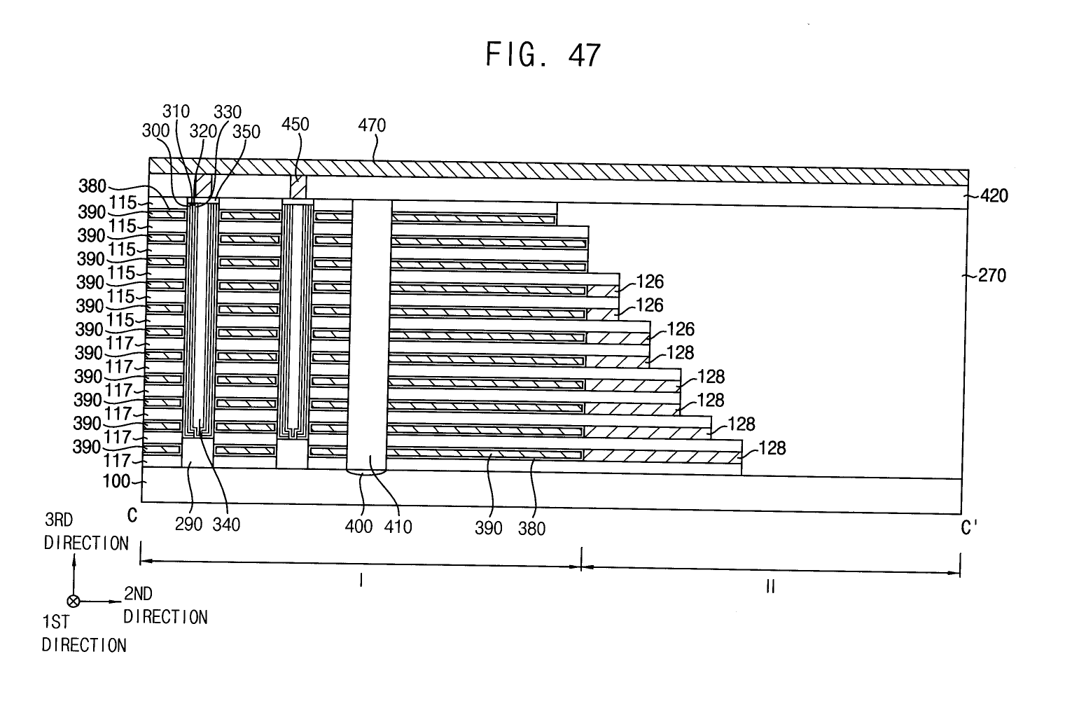

FIGS. 1 through 47 are plan views and cross-sectional views illustrating fabrication stages of a vertical non-volatile memory device throughout a manufacturing method in accordance with example embodiments. In particular, FIGS. 1, 3, 6, 9, 10, 13, 16, 19, 23, 27, 31, 37 and 40 are plan views, and FIGS. 2, 4-5, 7-8, 11-12, 14-15, 17-18, 20-22, 24-26, 28-30, 32-36, 38-39 and 41-47 are cross-sectional views. Among the cross-sectional views, FIGS. 2, 4, 5, 7, 11, 14, 17, 20, 24, 28 and 32 are cross-sectional views along a cutline A-A′ extending in a first direction substantially parallel to a top surface of a substrate, FIGS. 8, 12, 15, 18, 21, 25, 29, 33, 36, 38, 42, 44 and 46 are cross-sectional views along a cutline B-B′ extending in a second direction substantially parallel to the top surface of the substrate and substantially perpendicular to the first direction, FIGS. 22, 26, 30, 34, 39 and 47 are cross-sectional views along a cutline C-C′ extending in the second direction, and FIGS. 35, 41, 43 and 45 are cross-sectional views along a cutline D-D′ extending in the first direction. For purposes of illustration, a direction substantially perpendicular to the top surface of the substrate is defined as a third direction. Throughout the present disclosure, the first, second and third directions are as defined above and as shown in the drawings.

Referring to FIGS. 1 and 2, an insulation layer 110 and a sacrificial layer 120 may be alternately and repeatedly formed on a substrate 100 having a first region I and a second region II. Thus, a plurality of insulation layers 110 and a plurality of sacrificial layer layers 120 may be alternately stacked on each other over the substrate 100 in the third direction. FIG. 1 shows for purposes of illustration twelve insulation layers 110 and eleven sacrificial layers 120 alternately stacked on the substrate 100. However, the inventive concepts are not limited to any particular number of insulation layers 110 and sacrificial layers 120.

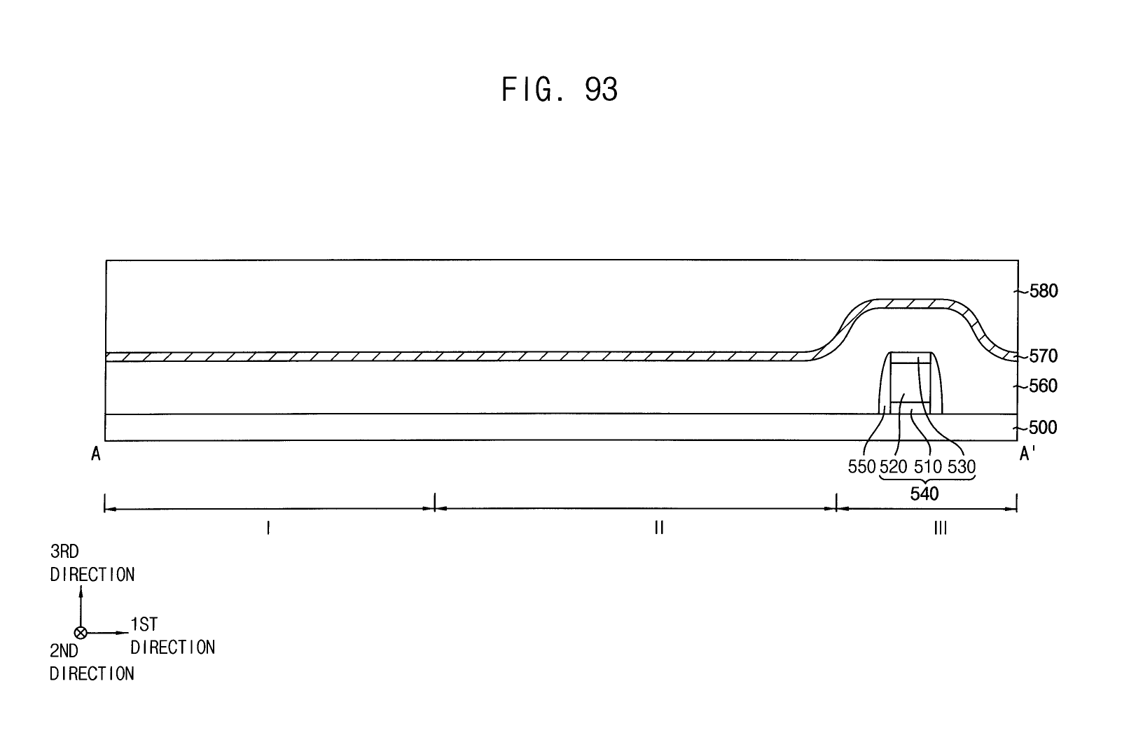

The substrate 100 may include a semiconductor material such as silicon, germanium, and the like. In example embodiments, the first region I may serve as a memory cell array region in which memory cells including channels and gate electrodes are formed, and the second region II may serve as a connection region (i.e., pad region) in which pads extending from the gate electrodes may be formed. The first and second regions I and II may together define a cell region, and the substrate 100 may further include a peripheral circuit region (e.g., III of FIG. 93) in which circuits for driving the memory cells may be formed.

Also, as will be explained later, the second region II may be divided (for example, by a cut line) into an active region and a non-active region. The active region of the second region II may contain a structure for connection to memory cells contained in the first region I, while the non-active region of the second region II may contain a photolithographic reference mark pattern.

In example embodiments, the first region I may have a rectangular shape in a top view, i.e., when viewed from above. The rectangular shape may include two pairs of sides, and a first pair of opposite sides may extend in the second direction and a second pair of opposite sides may extend in the first direction. The second region II may have a rectangular ring shape surrounding the first region I in a top view.

In example embodiments, the insulation layers 110 and the sacrificial layers 120 may be formed by a chemical vapor deposition (CVD) process, a plasma chemical vapor deposition (PECVD) process, an atomic layer deposition (ALD) process, etc. In an example embodiment, a lowermost one of the plurality of insulation layers 110 directly formed on the top surface of the substrate 100 may be formed by a thermal oxidation process.

The insulation layers 110 may be formed to include a silicon oxide, e.g., plasma enhanced tetraethylorthosilicate (PE-TEOS), high density plasma (HDP) oxide, plasma enhanced oxide (PEOX), etc. The sacrificial layers 120 may be formed to include a material having an etching selectivity with respect to the insulation layers 110, e.g., silicon nitride.

A polish stop layer 130 and an upper insulation layer 140 may be sequentially formed on an uppermost one of the stacked insulation layers 110 and the sacrificial layers 120.

FIG. 1 shows by way of example that an uppermost one of the insulation layers 110 is the uppermost one of layers of the stack formed by the insulation layers 110 and the sacrificial layers 120, and thus the polish stop layer 130 in this example is formed on the uppermost one of the insulation layers 110.

The polish stop layer 130 and the upper insulation layer 140 may be formed to include materials which are substantially the same as those of the sacrificial layer 120 and the insulation layer 110, respectively. Thus, the polish stop layer 130 may be formed to include, e.g., silicon nitride, and the upper insulation layer 140 may be formed to include, e.g., silicon oxide. In an example embodiment, the polish stop layer 130 and the upper insulation layer 140 may be formed to have thicknesses greater than those of the sacrificial layer 120 and the insulation layer 110, respectively.

The polish stop layer 130 and the upper insulation layer 140 are together referred to herein as a reference layer.

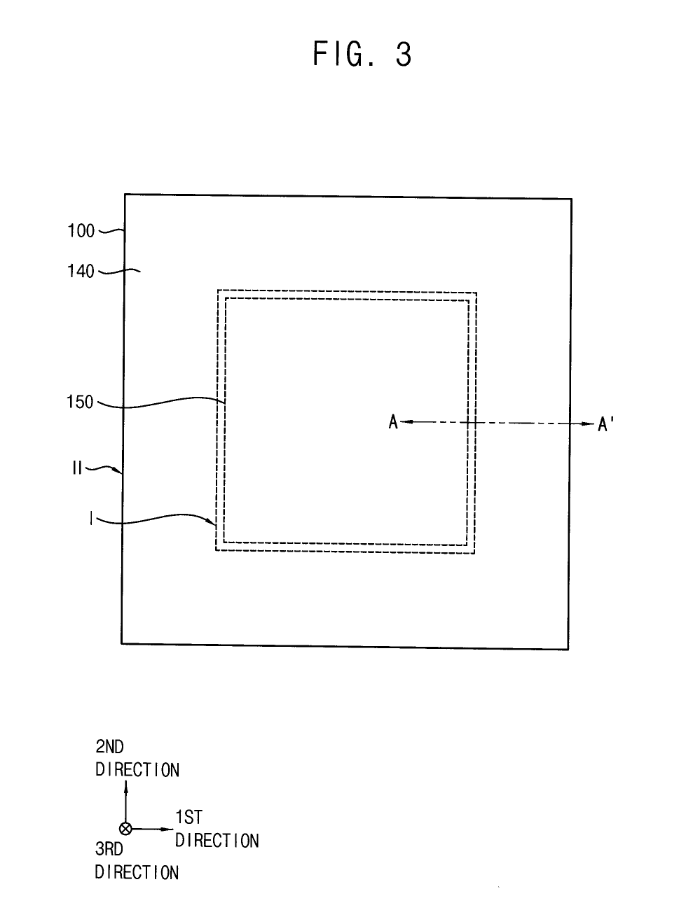

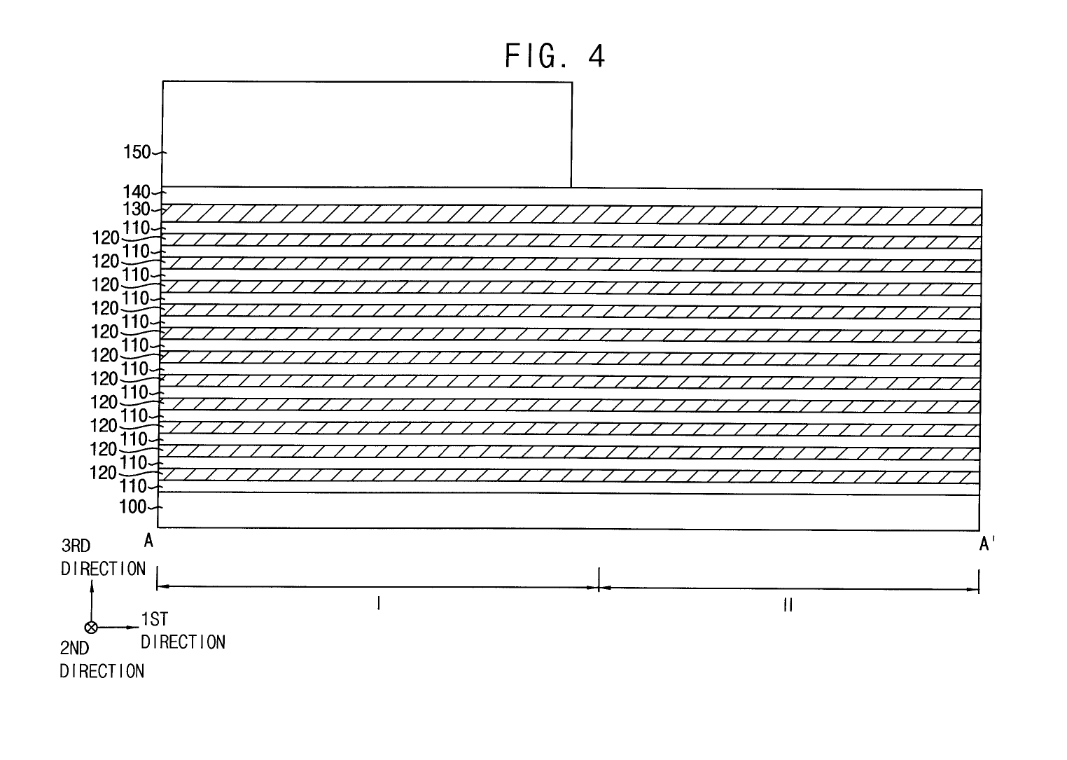

Referring to FIGS. 3 and 4, a first photoresist pattern 150 may be formed on the reference layer.

The first photoresist pattern 150 may not cover the second region II of the substrate 100, and partially cover the first region I. In example embodiments, the first photoresist pattern 150 may have a rectangular shape in a top view, which may be reduced at a given ratio from the rectangular shape of the first region I. Thus, four sides of the rectangular shape of the first photoresist pattern 150 may be spaced apart from the four sides of the rectangular shape of the first region I, respectively, by substantially the same distance.

An area covered by the first photoresist pattern 150 in a top view may be defined as a first area, which may have a rectangular shape.

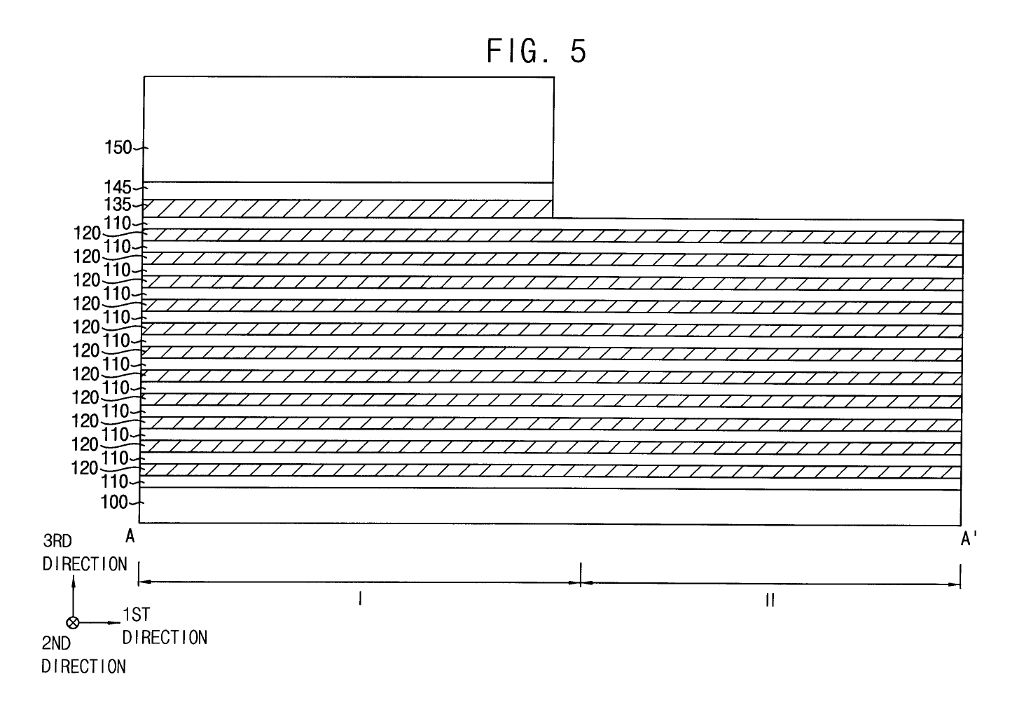

Referring to FIG. 5, the upper insulation layer 140 and the polish stop layer 130 may be etched using the first photoresist pattern 150 as an etching mask to form an upper insulation layer pattern 145 and a polish stop layer pattern 135, respectively. That is, the reference layer may be patterned to form a reference layer pattern including a polish stop layer pattern 135 and an upper insulation layer pattern 145 that are sequentially stacked.

In example embodiments, the reference layer pattern may have a rectangular shape in a top view in correspondence with the rectangular shape of the first photoresist pattern 150, and four sides of the rectangular shape of the reference layer pattern may be spaced apart from the four sides of the rectangular shape of the first region I, respectively, by substantially the same distance.

The first photoresist pattern 150 may be removed by an ashing process and/or a stripping process.

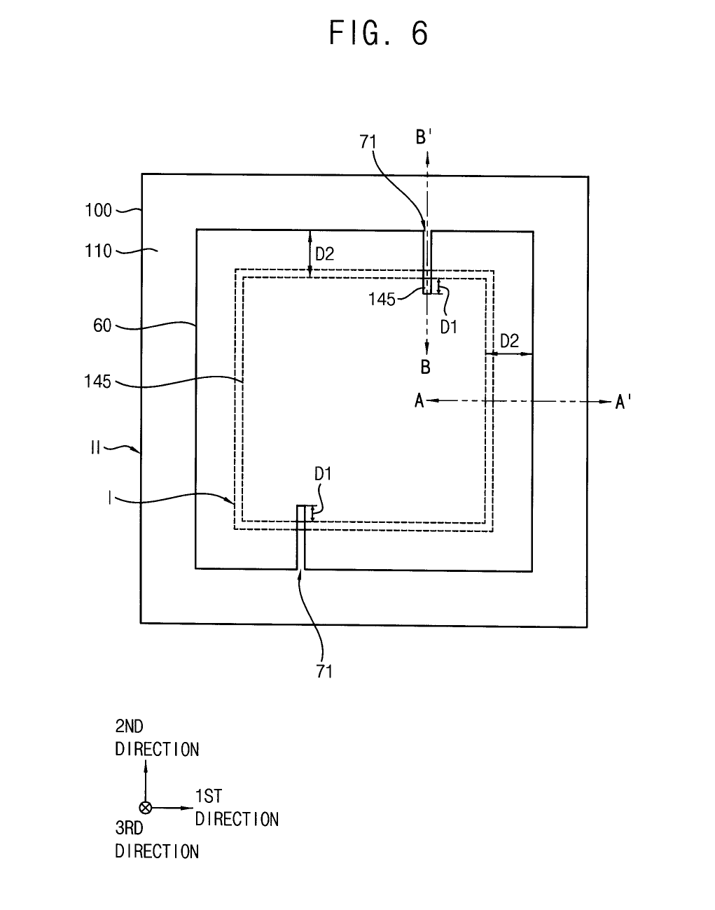

Referring to FIGS. 6 to 8, a preliminary second photoresist layer covering the reference layer pattern may be formed on the uppermost one of the insulation layers 110, and patterned to form a preliminary second photoresist pattern 60.

The preliminary second photoresist pattern 60 may, for example, be formed by irradiating a light through a first reticle (not shown) onto the preliminary second photoresist layer to form an exposed portion (not shown) therein, which may be referred to as an exposure process, and removing the exposed portion of the preliminary second photoresist layer by a developing process.

In example embodiments, the preliminary second photoresist pattern 60 may be formed to cover an entirety of the reference layer pattern, except that the preliminary second photoresist layer pattern 60 may have an opening or recess which partially exposes a portion of the reference layer pattern. Herein, the opening or recess of the preliminary second photoresist pattern may be referred to as a reference key, and an edge of the exposed portion of the reference layer pattern may be referred to as a photolithographic reference mark.

When the reference layer pattern has a rectangular shape in a top view, the preliminary second photoresist pattern 60 may also have a rectangular shape that may be larger than the reference layer pattern. Particularly, a first pair of sides of the rectangular shape of the preliminary second photoresist pattern 60 may extend in the second direction, and a second pair of sides of the rectangular shape of the preliminary second photoresist pattern 60 may extend in the first direction. However, as mentoned above and as shown in FIG. 6, the second pair of sides define a preliminary first recess 71 contituting a reference key partially exposing the peripheral portion of the reference layer pattern including the photolithographic reference mark of the reference layer pattern.

A boundary (edge) of the peripheral portion of the reference layer pattern (i.e., the photolithographic reference mark) exposed by the preliminary first recess 71 (i.e. reference key) may be spaced apart from a boundary of the preliminary second photoresist pattern 60 in the second direction, i.e., a bottom of the preliminary first recess 71 in the second direction by a first distance D1. A boundary of the reference layer pattern not exposed by the preliminary first recess 71 may be spaced apart from the boundary of the preliminary second photoresist pattern 60 by a second distance D2. The preliminary second photoresist pattern 60 may cover almost an entire area of the reference layer pattern so that the second distance D2 may not be measured directly. However, in example embodiments, the preliminary second photoresist pattern 60 may have the preliminary first recess 71 exposing the peripheral portion of the reference layer pattern, and the preliminary second photoresist pattern 60 may be formed so that the first distance D1 changing according to a depth of the preliminary first recess 71 in the second direction may have a given relationship with the second distance D2. Thus, the second distance D2 may be known from the first distance D1.

In example embodiments, the reference layer pattern may have a rectangular shape, while the preliminary second photoresist pattern 60 may have a rectangular shape enlarged with a given ratio from the rectangular shape of the reference layer pattern and each of the second pair of sides of the rectangular shape of the preliminary second photoresist pattern 60 may have the preliminary first recess 71 exposing the peripheral portion of the reference layer pattern. That is, the four sides of the preliminary second photoresist pattern 60 may be spaced apart from the corresponding four sides of the reference layer pattern, respectively, by the second distance D2, and the preliminary first recess 71 exposing the peripheral portion of the reference layer pattern may be formed with a given depth at each of the second pair of sides. The first distance D1 may have a single value corresponding to a value of the second distance D2, and thus the second distance D2 may be calculated by measuring the first distance D1.

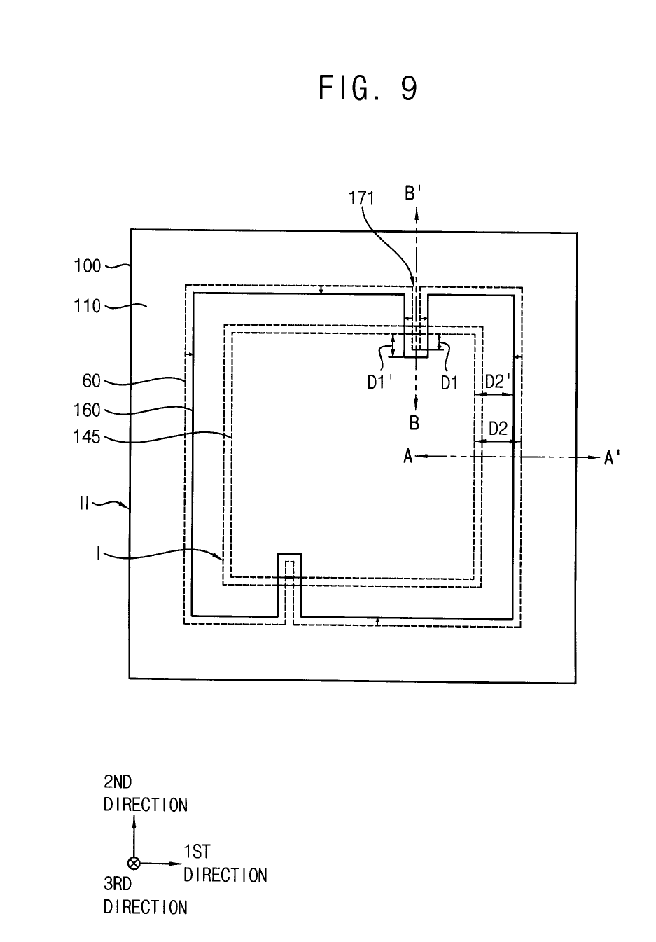

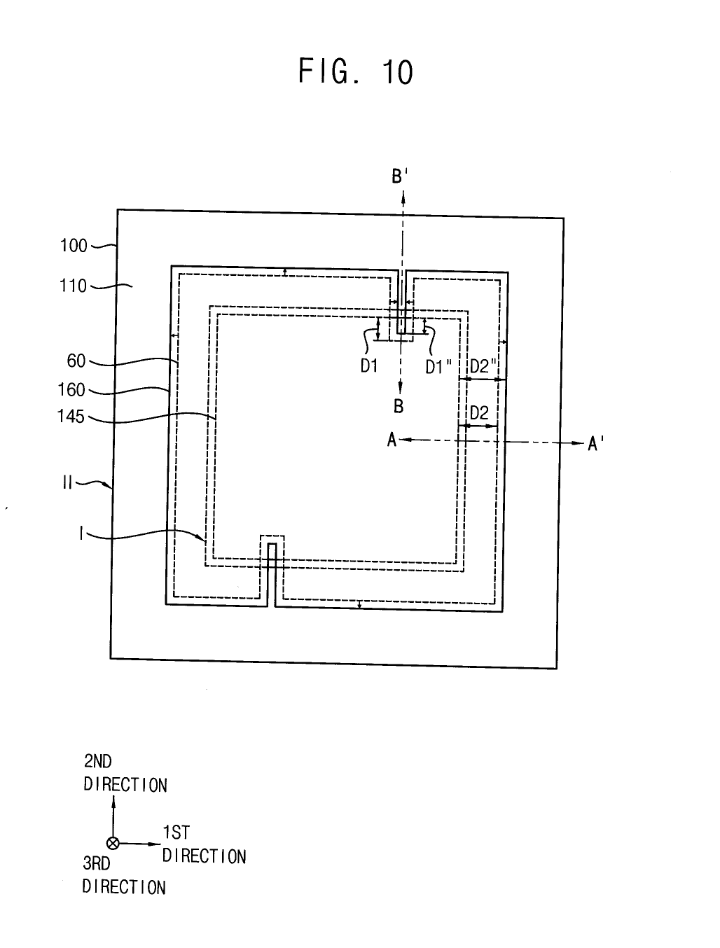

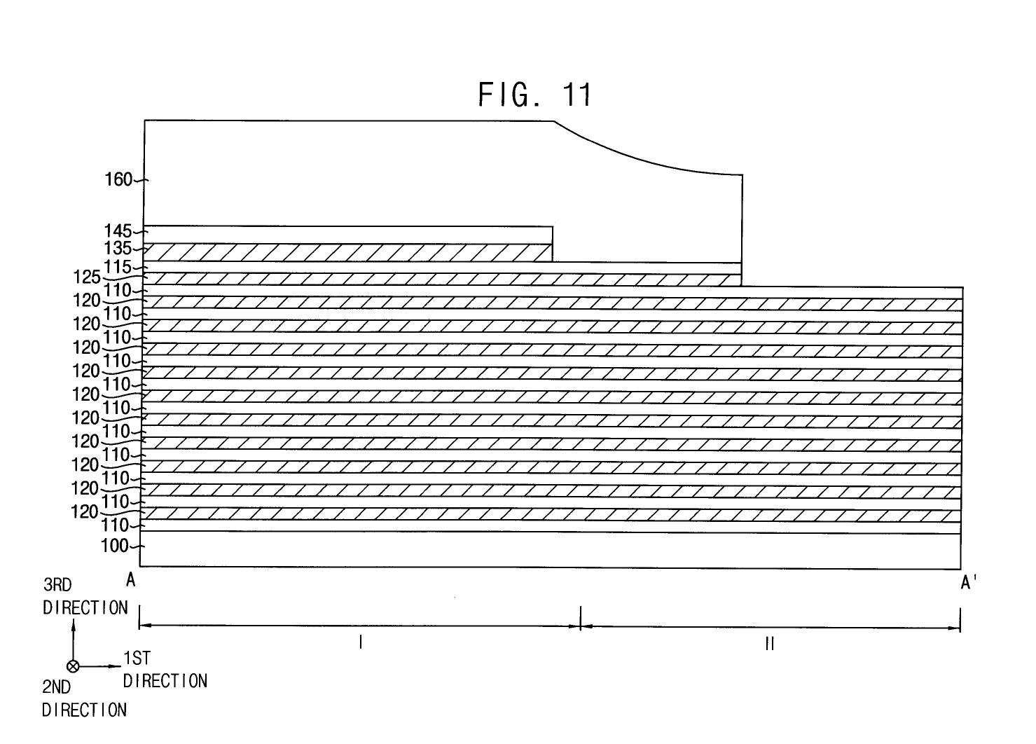

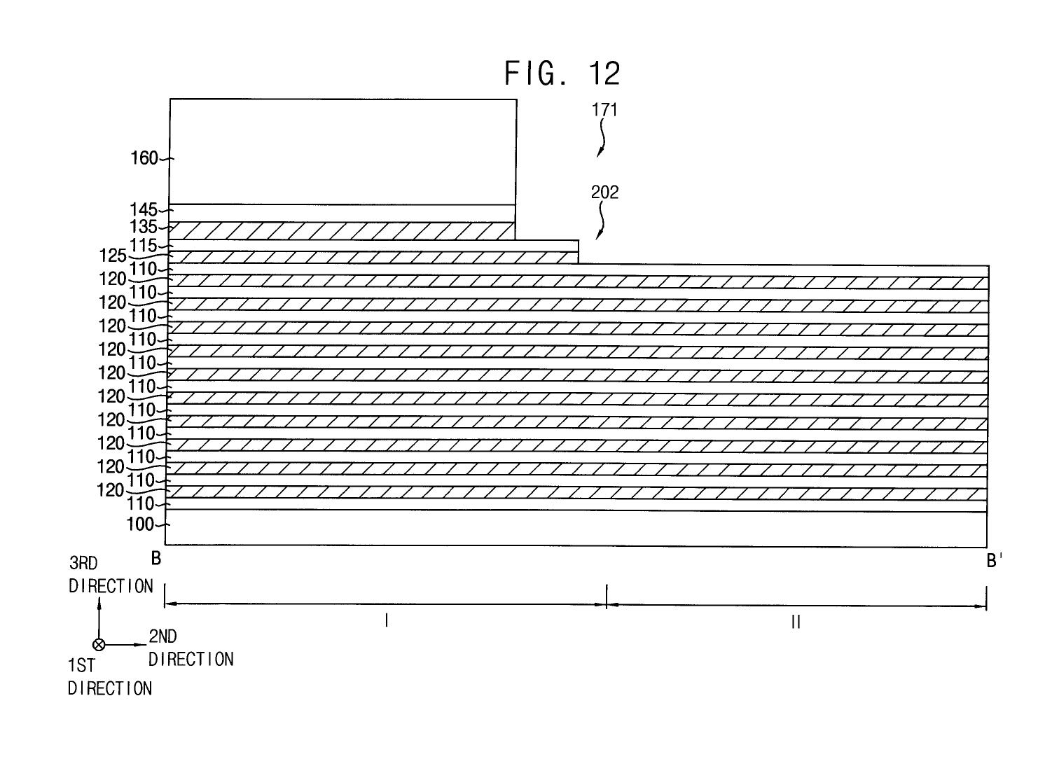

Using the photolithographic reference mark defined by the edge of the exposed portion of the reference layer pattern and the reference key (recess 71) of the preliminary second photoresist pattern 60, whether a scale and/or position of the preliminary second photoresist pattern 60 is within a design tolerance may be determined If the scale and/or position of the preliminary second photoresist pattern 60 is within a design tolerance, the processes described below with reference to FIGS. 9 and 10 may be omitted, and the fabrication may proceed directly to the processes described below with reference to FIGS. 11 and 12. On the other hand, if the scale and/or position of the preliminary second photoresist pattern 60 is not within a design tolerance, the processes described below with reference to FIG. 9 or 10 may be carried out, followed by the processes described below with reference to FIGS. 11 and 12.

Referring to FIG. 9, when for example the second distance D2 corresponding to the measured first distance D1 is larger than a desired distance (i.e., not with design tolerance), the preliminary second photoresist pattern may be removed, and a second photoresist pattern 160 may be formed in its place to have an area reduced from that of the preliminary second photoresist pattern 60.

In example embodiments, after forming a second photoresist layer covering the reference layer pattern on the uppermost one of the insulation layers 110, the second photoresist layer may be patterned using the first reticle for forming the preliminary second photoresist pattern 60 to form the second photoresist pattern 160. However, an amount of light used in an exposure process for forming the second photoresist pattern 60 may be increased when compared to an amount of light used in the exposure process for forming the preliminary second photoresist pattern 160, so that an area of an exposed portion of the second photoresist layer may be increased when compared to that of the preliminary second photoresist layer. Thus, the exposed portion of the second photoresist layer having an area larger than that of the exposed portion of the preliminary second photoresist layer may be removed during a subsequent developing process, so that the second photoresist pattern 160 may be formed to have an area smaller than that of the preliminary second photoresist pattern 60.

The area of the second photoresist pattern 160 may be reduced by a given ratio from that of the preliminary second photoresist pattern 60, and a size, e.g., a depth of the first recess 171 of the second photoresist pattern 160 in the second direction may be increased by a given ratio from that of the preliminary first recess 71 of the preliminary second photoresist pattern 60. Thus, the first distance D1 between the boundary of the peripheral portion exposed by the preliminary first recess 71 and the boundary of the preliminary second photoresist pattern 60 in the second direction may be increased to the first distance D1′ between the boundary of the peripheral portion exposed by the first recess 171 and the boundary of the second photoresist pattern 160 in the second direction, while the second distance D2 between the boundary of the peripheral portion not exposed by the preliminary first recess 71 and the boundary of the preliminary second photoresist pattern 60 may be reduced to the second distance D2′ between the boundary of the peripheral portion not exposed by the first recess 171 and the boundary of the second photoresist pattern 160.

Referring to FIG. 10, when for example the second distance D2 corresponding to the measured first distance D1 is smaller than the desired distance (i.e., not within design tolerance), the preliminary second photoresist pattern 160 may be removed, and a second photoresist pattern 160 may be formed in its place to have an area increased from that of the preliminary second photoresist pattern 60.

That is, an amount of light used in the exposure process for forming the second photoresist pattern 60 may be reduced when compared to the amount of light used in the exposure process for forming the preliminary second photoresist pattern 160, so that an area of the exposed portion of the second photoresist layer may be reduced when compared to that of the preliminary second photoresist layer. Thus, the exposed portion of the second photoresist layer having an area smaller than that of the exposed portion of the preliminary second photoresist layer may be removed during a following developing process, so that the second photoresist pattern 160 may be formed to have an area larger than that of the preliminary second photoresist pattern 60.

The area of the second photoresist pattern 160 may be increased by a given ratio from that of the preliminary second photoresist pattern 60, and a size, e.g., a depth of the first recess 171 of the second photoresist pattern 160 in the second direction may be reduced by a given ratio from that of the preliminary first recess 71 of the preliminary second photoresist pattern 60. Thus, the first distance D1 between the boundary of the peripheral portion exposed by the preliminary first recess 71 and the boundary of the preliminary second photoresist pattern 60 in the second direction may be reduced to the first distance D1″ between the boundary of the peripheral portion exposed by the first recess 171 and the boundary of the second photoresist pattern 160 in the second direction, while the second distance D2 between the boundary of the peripheral portion not exposed by the preliminary first recess 71 and the boundary of the preliminary second photoresist pattern 60 may be increased to the second distance D2″ between the boundary of the peripheral portion not exposed by the first recess 171 and the boundary of the second photoresist pattern 160.

As illustrated with reference to FIGS. 9 and 10, an area of a photoresist pattern may be reduced or increased by a given ratio by controlling an amount of light used in an exposure process even using substantially the same reticle, and thus, in the preliminary second photoresist pattern 60 having the preliminary first recess 71 and the second photoresist pattern 160 having the first recess 171, the first distance D1 and the second distance D2 may be inversely proportional to each other.

When the measured distance D1 is smaller than a first standard, i.e., a boundary of the preliminary second photoresist pattern 60 is spaced apart from a boundary of the reference layer pattern by a distance which is larger than a desired distance in a top view, the amount of light used to form the preliminary second photo resist pattern may be increased when forming the second photoresist pattern 160 such that the second photoresist pattern 160 has a reduced area relative to that of the preliminary second photoresist pattern 60.

On the other hand, when the measured distance D1 is larger than the first standard, i.e., a boundary of the preliminary second photoresist pattern 60 is spaced apart from a boundary of the reference layer pattern by a distance which is smaller than the desired distance in a top view, the amount of light used to form the preliminary second photo resist pattern may be reduced when forming the second photoresist pattern 160 such that the second photoresist pattern 160 has an increased area relative to that of the preliminary second photoresist pattern 60.

For purposes of description, an area covered by the second photoresist pattern 160 in a top view may be referred to as a second area, which may cover the the previously decribed first area except for a peripheral portion thereof, and have an area larger than that of the first area.

Referring to FIGS. 11 and 12, the uppermost one of the insulation layers 110 and an uppermost one of the sacrificial layers 120 therebeneath may be etched using the second photoresist pattern 160 as an etching mask to form a first insulation layer pattern 115 and a first sacrificial layer pattern 125, respectively. During the etching process, the exposed portion of the reference layer pattern by the first recess 171 may be also etched.

Thus, a first level of a first pattern structure including a first sacrificial layer pattern 125 and a first insulation layer pattern 115 sequentially stacked may be formed. The first level of first pattern stucture may define a second upper step structure 202 at a second area at which the first recess 171 is formed.

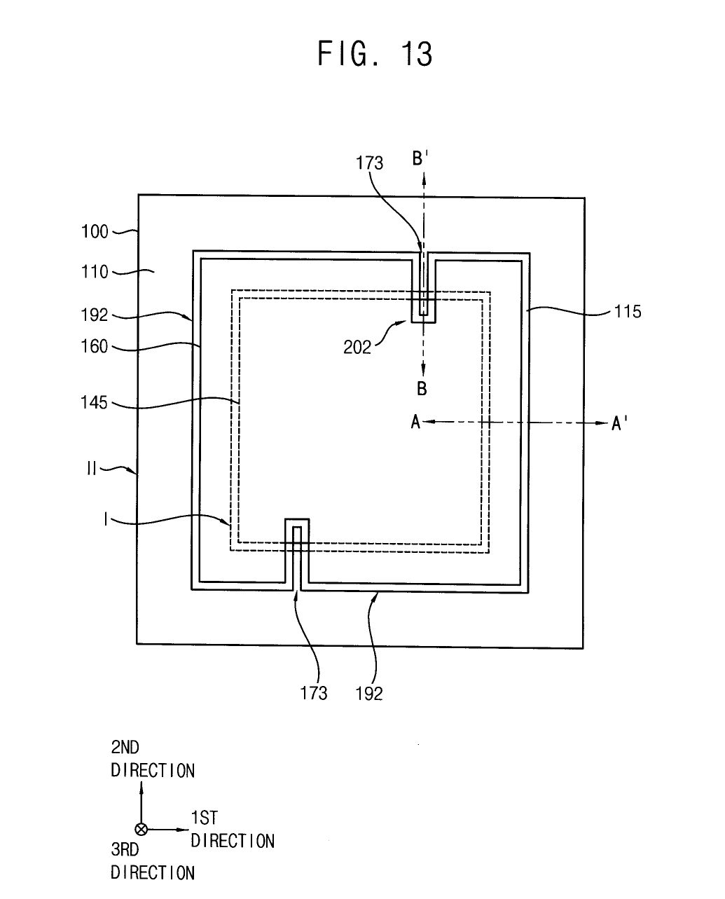

Referring to FIGS. 13, 14 and 15, the second photoresist pattern 160 may be reduced by a trimming process to expose a portion of the first level of first pattern stucture, and the exposed portion of the first level of first pattern stucture, an uppermost one of the insulation layers 110 and an uppermost one of the sacrificial layers 120 therebeneath may be etched using the trimmed second photoresist pattern 160 as an etching mask. A second recess 173 having an area larger than that of the first recess 171 may be formed at the second area at which the first recess 171 is formed by the trimming process to expose a portion of the reference layer pattern, and during the etching process, the exposed portion of the reference layer pattern by the second recess 173 may be also etched. Thus, a second level of first pattern stucture including a first sacrificial layer pattern 125 and a first insulation layer pattern 115 sequentially stacked may be formed beneath the first level of first pattern stucture. The second level of first pattern stucture together with the first level of first pattern stucture may define the second upper step structure 202 at the second area at which the first and second recesses 171 and 173 are formed, and may form a first upper step structure 192 at a first area at which no recess is formed.

In an example embodiment, the trimming process may be performed by a mixed plasma including oxygen, chlorine, ozone, etc., and upper and lateral portions of the second photoresist pattern 160 may be removed by the trimming process so that a volume of the second photoresist pattern 160 may be reduced.

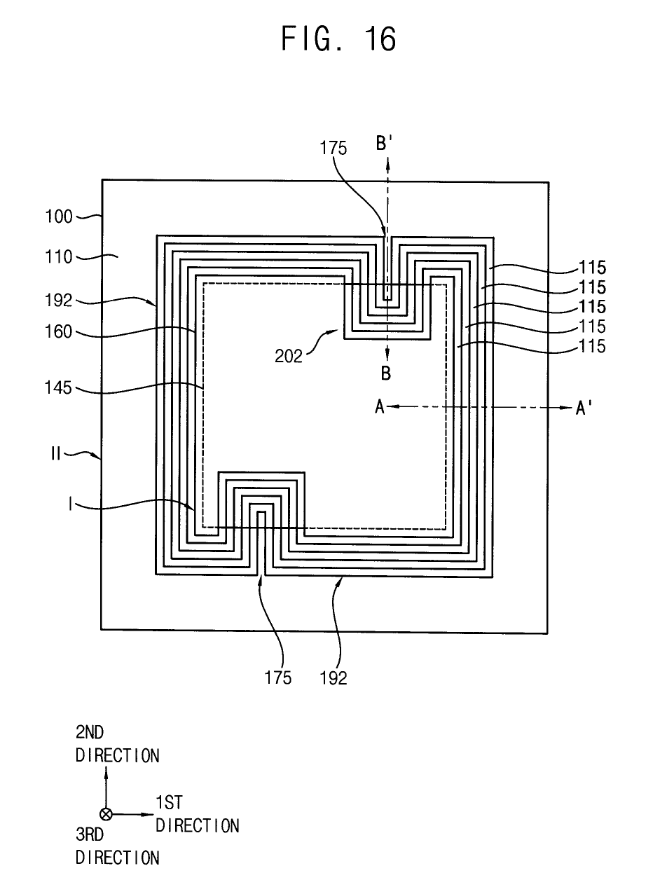

Referring to FIGS. 16, 17 and 18, the trimming process illustrated with reference to FIGS. 13 to 15 may be performed plural times.

That is, the second photoresist pattern 160 may have a reduced volume or area with a given ratio by each trimming process to expose a portion of the first level of first pattern stucture, and the exposed portion of the first level of first pattern stucture, the second level of first pattern stucture, and an uppermost one of the insulation layers 110 and an uppermost one of the sacrificial layers 120 therebeneath may be etched using the trimmed second photoresist pattern 160 as an etching mask. A third recess 175 having an area larger than that of the second recess 173 may be formed at the second area at which the first and second recesses 171 and 173 are formed by the trimming process to expose a portion of the reference layer pattern, and during the etching process, the exposed portion of the reference layer pattern by the second recess 175 may be also etched. Thus, a plurality of first pattern structures each of which may include a first sacrificial layer pattern 125 and a first insulation layer pattern 115 sequentially stacked may be formed under the second level of first pattern stucture. For example, four levels of first pattern structures, i.e., a third level of first pattern stucture, a fourth level of first pattern stucture, a fifth level of first pattern stucture and a sixth level of first pattern stucture may be sequentially formed. However, the number of trimming processes and the number of levels of first pattern structure are not limited thereto.

Accordingly, a plurality of first pattern structures each of which may include one sacrificial layer pattern 125 and one insulation layer pattern 115 sequentially stacked may be formed at a plurality of levels. The third to sixth levels of first pattern structure together with the first and second levels of first pattern structure may define the second upper step structure 202 at the second area at which the first, second and third recesses 171, 173 and 175 are formed, and may define the first upper step structure 192 at the first area at which no recess is formed.

In example embodiments, each of the first and second upper step structures may have a width that may gradually decrease at a constant first ratio from a bottom level to a top level.

The second photoresist pattern 160 may be removed to expose the first pattern structures.

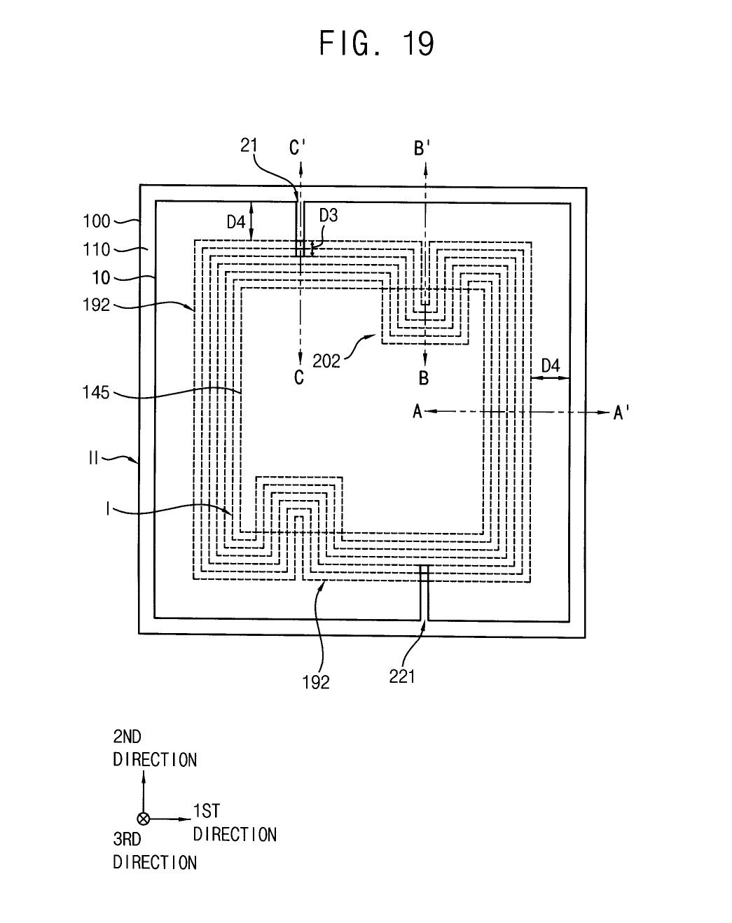

Referring to FIGS. 19, 20, 21 and 22, a process substantially the same as or similar to that illustrated with reference to FIGS. 6 to 8 may be performed.

That is, a preliminary third photoresist layer covering the exposed first pattern structures may be formed on an uppermost one of the insulation layers 110, and patterned to form a preliminary third photoresist pattern 10.

The preliminary third photoresist pattern 10 may be formed by irradiating a light through a second reticle (not shown) onto the preliminary third photoresist layer to form an exposed portion (not shown) and removing the exposed portion of the preliminary third photoresist layer through a developing process.

In example embodiments, the preliminary third photoresist pattern 10 may be formed to cover the first pattern structures but to partially expose a peripheral portion of at least one of the first pattern structures. When the first pattern structures have a rectangular shape except for the second area in a top view, the preliminary third photoresist pattern 10 may also have a rectangular shape as a whole that may be larger than the first pattern structures. Particularly, a first pair of sides of the rectangular shape of the preliminary third photoresist pattern 10 may extend in the second direction, and a second pair of sides of the rectangular shape of the preliminary third photoresist pattern 10 may extend in the first direction but have a preliminary fourth recess 21 partially exposing the peripheral portion of the at least one of the first pattern structures.

In example embodiments, the preliminary fourth recess 21 may be formed at a third area spaced apart from the second area in the first direction. In FIGS. 19 to 22, the preliminary fourth recess 21 partially exposes peripheral portions of two levels of first pattern structure, however, is not limited thereto, but may partially expose a peripheral portion of one level of first pattern stucture or peripheral portions of more than two levels of first pattern structure.

A boundary of the peripheral portion of the at least one of the first pattern structures, e.g., a lowermost level of first pattern stucture (the sixth level of first pattern stucture in FIGS. 19 to 22) exposed by the preliminary fourth recess 21 may be spaced apart from a boundary of the preliminary third photoresist pattern 10 in the second direction, i.e., a bottom of the preliminary fourth recess 21 in the second direction by a third distance D3. A boundary of the at least one of the first pattern structures, e.g., the lowermost level of first pattern stucture (the sixth level of first pattern stucture in FIGS. 19 to 22) not exposed by the preliminary fourth recess 21 may be spaced apart from the boundary of the preliminary third photoresist pattern 10 by a fourth distance D4. The preliminary third photoresist pattern 10 may cover almost an entire area of the first pattern structures so that the fourth distance D4 may not be measured directly, however, in example embodiments, the fourth distance D4 may be calculated from the third distance D3.

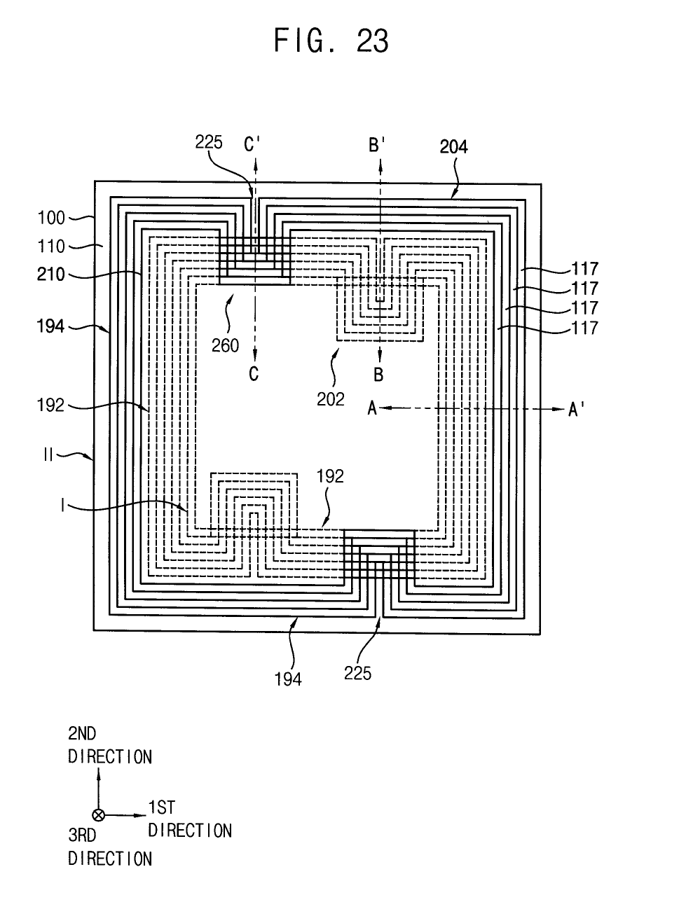

Accordingly, whether the preliminary third photoresist pattern 10 having an area larger than that of the first pattern structures is formed with a desired size and/or scale and/or a desired position with respect to the first pattern structures may be confirmed, and if not, a third photoresist pattern 210 (refer to FIGS. 23 to 26) with desired properties with respect to the first pattern structures may be formed by the method illustrated with reference to FIGS. 9 and 10. However, when the preliminary third photoresist pattern 10 is formed with the desired properties with respect to the first pattern structures, the method illustrated with reference to FIGS. 9 and 10 may not be performed, and an etching process illustrated with reference to following FIGS. 23 to 26 may be directly performed using the preliminary third photoresist pattern 10.

As illustrated with reference to FIGS. 9 and 10, in the preliminary third photoresist pattern 10 having the preliminary fourth recess 21 and the third photoresist pattern 210 having the fourth recess (not shown), the third distance D3 and the fourth distance D4 may be inverse proportional to each other.

When the fourth distance D4 corresponding to the measured third distance D3 is larger than a desired distance, the third photoresist pattern 210 may be formed to have an area reduced from that of the preliminary third photoresist pattern 10. On the other hand, when the fourth distance D4 corresponding to the measured third distance D3 is smaller than the desired distance, the third photoresist pattern 210 may be formed to have an area increased from that of the preliminary third photoresist pattern 10.

An area covered by the third photoresist pattern 210 in a top view may be defined as a third area, which may cover the second area except for a peripheral portion thereof and have an area larger than that of the second area.

Referring to FIGS. 23, 24, 25 and 26, processes substantially the same as or similar to those illustrated with reference to FIGS. 11 to 18 may be performed.

That is, the third photoresist pattern 210 may be reduced by at least one trimming process to expose a portion of the first pattern structures, and the exposed portion of the first pattern structures, an uppermost one of the insulation layers 110 and an uppermost one of the sacrificial layers 120 therebeneath may be etched using the trimmed third photoresist pattern 210 as an etching mask by an etching process. FIGS. 23 to 25 show four times of performance of the trimming process and etching processes corresponding thereto, however, the number of performing the trimming process and the corresponding etching process is not limited thereto.

Accordingly, a plurality of second pattern structures each of which may include one second sacrificial layer pattern 127 and one second insulation layer pattern 117 sequentially stacked may be formed at a plurality of levels. A fifth recess 225 having an area larger than that of the fourth recess may be formed at the third area at which the fourth recess is formed. The second pattern structures may define a second lower step structure 204 at the second area at which the first, second and third recesses 171, 173 and 175 are formed, may define a lower portion of a third step structure 260 at the third area at which the fourth recess and the fifth recess 225 are formed, and may define a first lower step structure 194 at the first area at which no recess is formed.

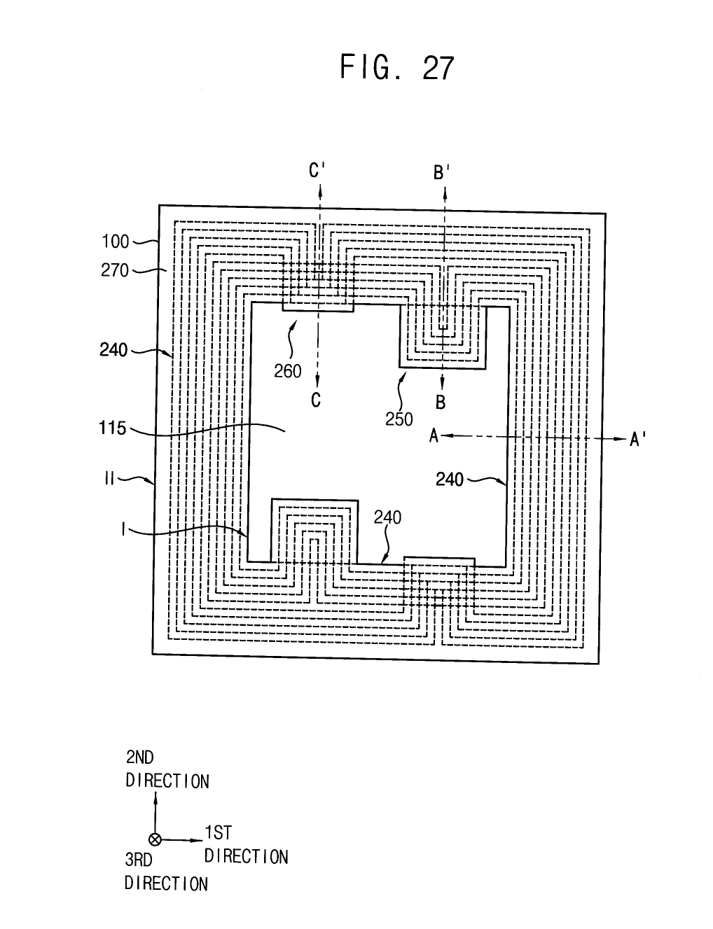

Referring to FIGS. 27, 28, 29 and 30, a first insulating interlayer may be formed on the substrate 100 to cover the first and second pattern structures and the reference layer pattern, and an upper portion of the first insulating interlayer may be planarized to form a first insulating interlayer pattern 270.

The first insulating interlayer may be formed to include an oxide, e.g., silicon oxide, and thus may be merged with the upper insulation layer pattern 145 of the reference layer pattern.

The planarization process may be performed by a chemical mechanical polishing (CMP) process and/or an etch back process. In the CMP process, the polish stop layer pattern 135 of the reference layer pattern may serve as an ending point of the planarization process. Thus, the upper insulation layer pattern 145 together with the upper portion of the first insulating interlayer may be removed in the planarization process. The planarization process may be performed until the polish stop layer pattern 135 of the reference layer pattern may be removed.

Accordingly, a first mold structure including the first and second pattern structures may be formed on the substrate 100, and the first insulating interlayer pattern 270 surrounding a sidewall of the first mold structure may be formed. The first mold structure may have a first step structure 240 including the first lower and upper step structures 194 and 192 sequentially stacked at the first area, a second step structure 250 including the second lower and upper step structures 204 and 202 sequentially stacked at the second area, and the third step structure 260 at the third area.

In example embodiments, portions of the first and second insulation layer patterns 115 and 117 and the first and second sacrificial layer patterns 125 and 127 defining the first step structure 240 may have a staircase shape with a width gradually decreasing at the constant first ratio from a bottom level to a top level when viewed from a lateral side. However, portions of the first and second insulation layer patterns 115 and 117 and the first and second sacrificial layer patterns 125 and 127 defining the second step structure 250 may have a staircase shape with a width that may not gradually decrease at a constant ratio from a bottom level to a top level when viewed from a lateral side. The width of the staircase shape of the portions of the first and second insulation layer patterns 115 and 117 and the first and second sacrificial layer patterns 125 and 127 defining the second step structure 250 may decrease at a second ratio that may be changed according to the level thereof. Further, portions of the first and second insulation layer patterns 115 and 117 and the first and second sacrificial layer patterns 125 and 127 defining the third step structure 260 may have a staircase shape of a width that may decrease at a third ratio that may be changed according to the level thereof.

As illustrated in FIG. 27, at least one of the first pattern structures, e.g., an uppermost one of the first pattern structures may have a first pair of boundaries that may be opposite to each other in the first direction and extend in the second direction, and a second pair of boundaries that may be opposite to each other in the second direction and extend in the first direction, and recesses extending in the second direction may be formed at the second and third areas in the second pair of boundaries. However, according to the depth of the preliminary fourth recess 21 of the preliminary third photoresist pattern 10 or the fourth recess of the third photoresist pattern 210 (refer to FIG. 19), the uppermost one of the first pattern structures may have no recess at the third area. In example embodiments, the boundaries of the first pattern structures may be linear.

Additionally, at least one of the second pattern structures, e.g., a lowermost one of the second pattern structures may have a first pair of boundaries that may be opposite to each other in the first direction and extend in the second direction, and a second pair of boundaries that may be opposite to each other in the second direction and extend in the first direction, and a recess extending in the second direction may be formed at the third area in the second pair of boundaries. In example embodiments, the boundaries of the second pattern structures may be linear.

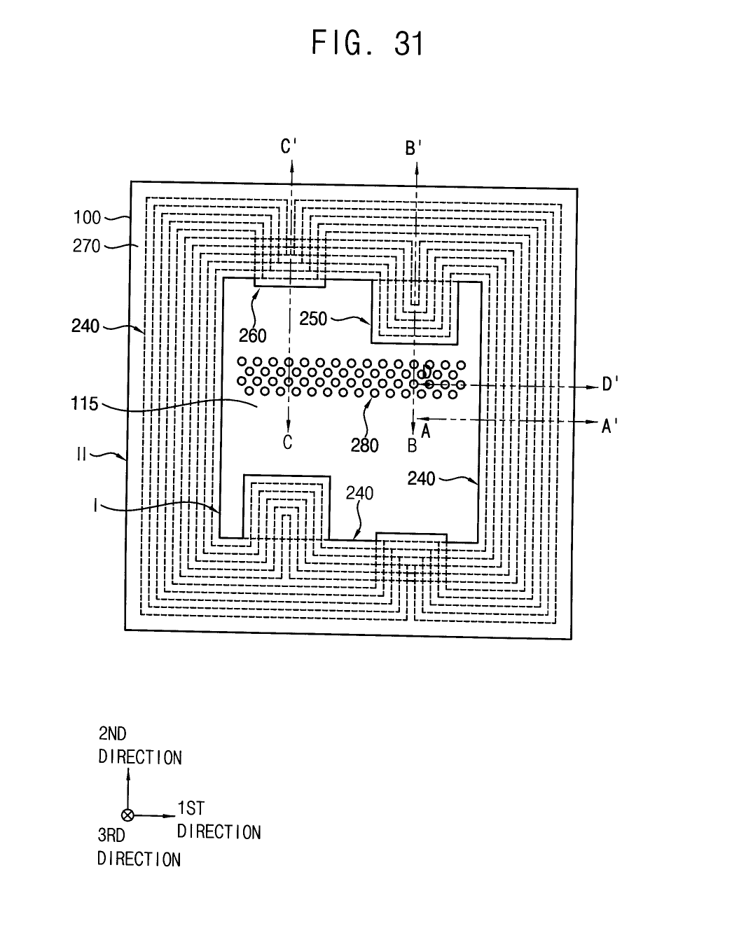

Referring to FIGS. 31, 32, 33 and 34, a plurality of holes 280 may be formed through the first and second insulation layer patterns 115 and 117 and the first and second sacrificial layer patterns 125 and 127 in the first region Ito expose a top surface of the substrate 100.

In example embodiments, the plurality of holes 280 may be formed in the first and second directions, and may define a hole array. In example embodiments, the hole array may include a first hole column including a plurality of first holes 280 in the first direction, and a second hole column including a plurality of second holes 280 in the first direction, which may be spaced apart from the first hole column in the second direction. The first holes 280 may be disposed at acute angles from the second holes 280 along the first direction or the second direction. Thus, the first and second holes 280 may be arranged in a zigzag layout in the first direction so as to be densely formed in a unit area. The first and second hole columns may be disposed alternately and repeatedly in the second direction.

In other example embodiments, the hole array may include the plurality of holes 280 arranged in a layout which differs from a zigzag layout.

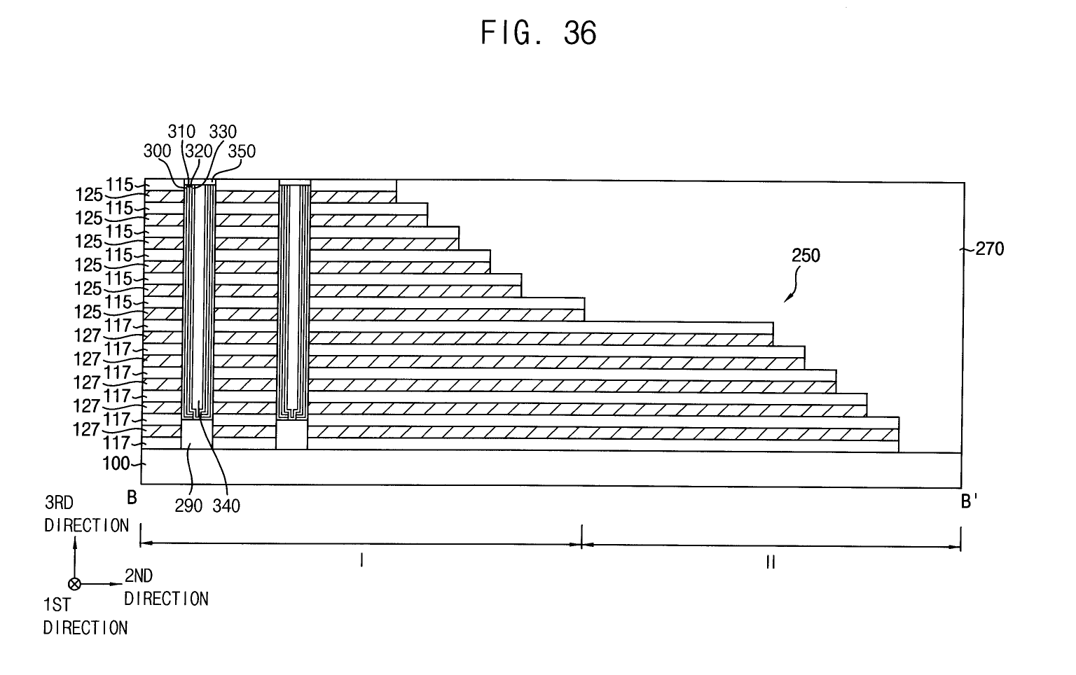

Referring to FIGS. 35 and 36, a semiconductor pattern 290 may be formed to partially fill each hole 280.

Particularly, a selective epitaxial growth (SEG) process may be performed using the exposed top surface of the substrate 100 as a seed to form the semiconductor pattern 290 partially filling the holes 280. Thus, the semiconductor pattern 290 may be formed to include single crystalline silicon or single crystalline germanium according to the material of the substrate 100, and in some cases, impurities may be doped thereinto. Alternatively, an amorphous silicon layer may be formed to fill the holes 280, and a laser epitaxial growth (LEG) process or a solid phase epitaxy (SPE) process may be performed on the amorphous silicon layer to form the semiconductor pattern 290.

A first blocking layer, a charge storage layer, a tunnel insulation layer and a spacer layer may be sequentially formed on inner walls of the holes 280, top surfaces of the semiconductor patterns 290, and a top surface of an uppermost one of the first insulation layer patterns 115 and a top surface of the first insulating interlayer pattern 270, and the spacer layer may be anisotropically etched to form spacers (not shown) on the inner walls of the holes 280, respectively. The tunnel insulation layer, the charge storage layer and the first blocking layer may be etched using the spacers as an etching mask to form a tunnel insulation layer pattern 320, a charge storage layer pattern 310 and a first blocking layer pattern 300, respectively, in each hole 280. Each of the tunnel insulation layer pattern 320, the charge storage layer pattern 310 and the first blocking layer pattern 300 may have a cup shape of which a central bottom is opened, and thus a top surface of the semiconductor pattern 290 may be exposed.

In example embodiments, the first blocking layer may be formed to include an oxide, e.g., silicon oxide, the charge storage layer may be formed to include a nitride, e.g., silicon nitride, the tunnel insulation layer may be formed to include an oxide, e.g., silicon oxide, and the spacer layer may be formed to include a nitride, e.g., silicon nitride.

After removing the spacers, a channel layer may be formed on the exposed top surface of the semiconductor pattern 290, the tunnel insulation layer patterns 320, the uppermost one of the first insulation layer patterns 115 and the first insulating interlayer pattern 270, and a first filling layer may be formed on the channel layer to sufficiently fill remaining portions of the holes 280.

In example embodiments, the channel layer may be formed to include doped or undoped polysilicon or amorphous silicon. When the channel layer is formed to include amorphous silicon, an LEG (laser epitaxy growth) process or an SPE (solid phase epitaxy) process may be further performed so that the amorphous silicon layer may be changed to a crystalline silicon layer. The first filling layer may be formed to include an oxide, e.g., silicon oxide.

The first filling layer and the channel layer may be planarized until the top surface of the uppermost one of the first insulation layer patterns 115 or the top surface of the first insulating interlayer pattern 270 may be exposed to form a first filling layer pattern 340 filling a remaining portion of each hole 280, and the channel layer may be transformed into a channel 330 in each hole 280.

Thus, the first blocking layer pattern 300, the charge storage layer pattern 310, the tunnel insulation layer pattern 320, the channel 330 and the first filling layer pattern 340 may be sequentially stacked on the semiconductor pattern 290 in each hole 280. Each of the first blocking layer pattern 300, the charge storage layer pattern 310 and the tunnel insulation layer pattern 320 may have a cup shape of which a central bottom is opened, the channel 330 may have a cup shape, and the first filling layer pattern 340 may have a pillar shape.

According as the holes 280 for forming the channels 330 may define the hole array including the first and second holes 280, the channels 330 may also define a channel array including first and second channels 330.

An upper portion of a first structure including the first filling layer pattern 340, the channel 330, the tunnel insulation layer pattern 320, the charge storage layer pattern 310 and the first blocking layer pattern 300 sequentially stacked in each hole 280 may be removed to form a trench (not shown), and a capping layer pattern 350 filling the trench may be formed on the first structure in each hole 280.

Particularly, after removing the upper portions of the first structures by an etch back process to form the trenches, a capping layer filling the trenches may be formed on the first structures, the uppermost one of the first insulation layer patterns 115 and the first insulating interlayer pattern 270, and an upper portion of the capping layer may be planarized until the top surface of the uppermost one of the first insulation layer patterns 115 or the top surface of the first insulating interlayer pattern 270 may be exposed to form the capping layer pattern 350 in each hole 280. In example embodiments, the capping layer may be formed to include doped or undoped polysilicon or amorphous silicon. When the capping layer is formed to include amorphous silicon, a crystallization process may be further performed thereon.

The capping layer patterns 350 may be formed on the channels 330, and thus may form a capping layer pattern array in accordance with the channel array.

The first structure, the semiconductor pattern 290 and the capping layer pattern 350 in each hole 280 may form a second structure.

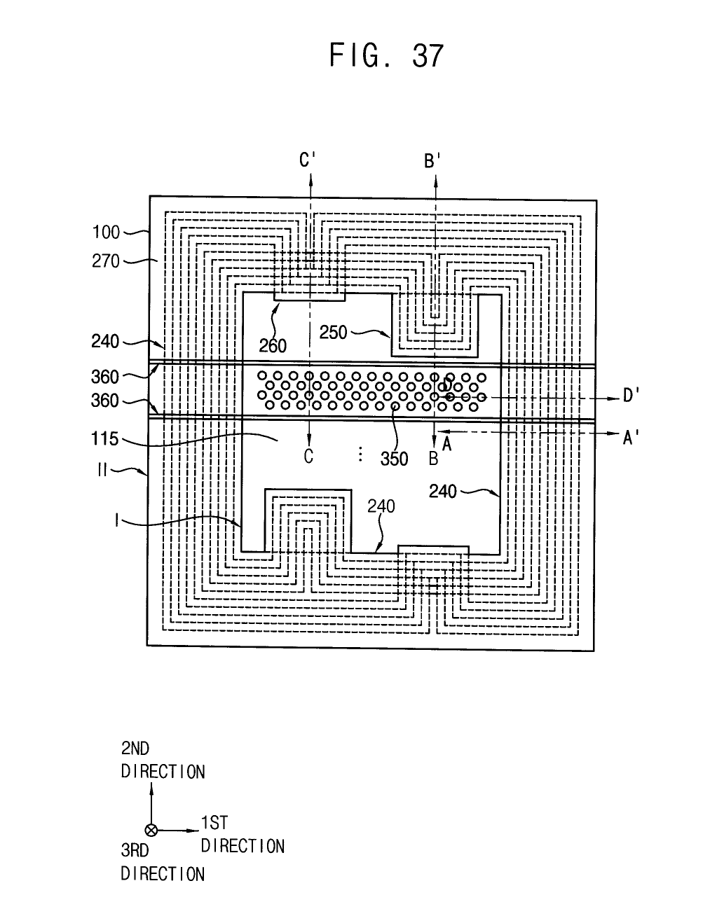

Referring to FIGS. 37, 38 and 39, a first opening 360 may be formed through the first and second insulation layer patterns 115 and 117 and the first and second sacrificial layer patterns 125 and 127 to expose a top surface of the substrate 100.

In example embodiments, a plurality of first openings 360 may be formed in the second direction, and each of the first openings 360 may extend in the first direction. According as the plurality of first openings 360 is formed in the second direction, a plurality of hole columns may be formed between the first openings 360, and FIG. 37 illustratively shows four hole columns are disposed between neighboring two first openings 360, however, the number of the hole columns therebetween may not limited thereto. The first openings 360 may be formed not only in the first region I but also in portions of the second region II before and after the first region I in the first direction, however, may not be formed in portions of the second region II before and after the first region I in the second direction.

The first and second sacrificial layer patterns 125 and 127 exposed by the first openings 360 may be removed to form a gap 370 between the first and second insulation layer patterns 115 and 117 at adjacent levels. In example embodiments, a plurality of gaps 370 may be formed between neighboring first insulation layer patterns 115, between neighboring second insulation layer patterns 117, and between neighboring first and second insulation layer patterns 115 and 117, respectively. Portions of outer sidewalls of the first blocking layer patterns 300 and sidewalls of the semiconductor patterns 290 may be exposed by the gaps 370. In example embodiments, the first and second sacrificial layer patterns 125 and 127 exposed by the first openings 360 may be removed by, for example, a wet etch process using an etch solution including phosphoric acid and/or sulfuric acid.

However, the first openings 360 may not be formed in the portions of the second region II before and after the first region I in the second direction, and thus portions of the first and second sacrificial layer patterns 125 and 127 may not be removed by the wet etching process but may remain, which may be referred to as first and second insulation pads 126 and 128, respectively.

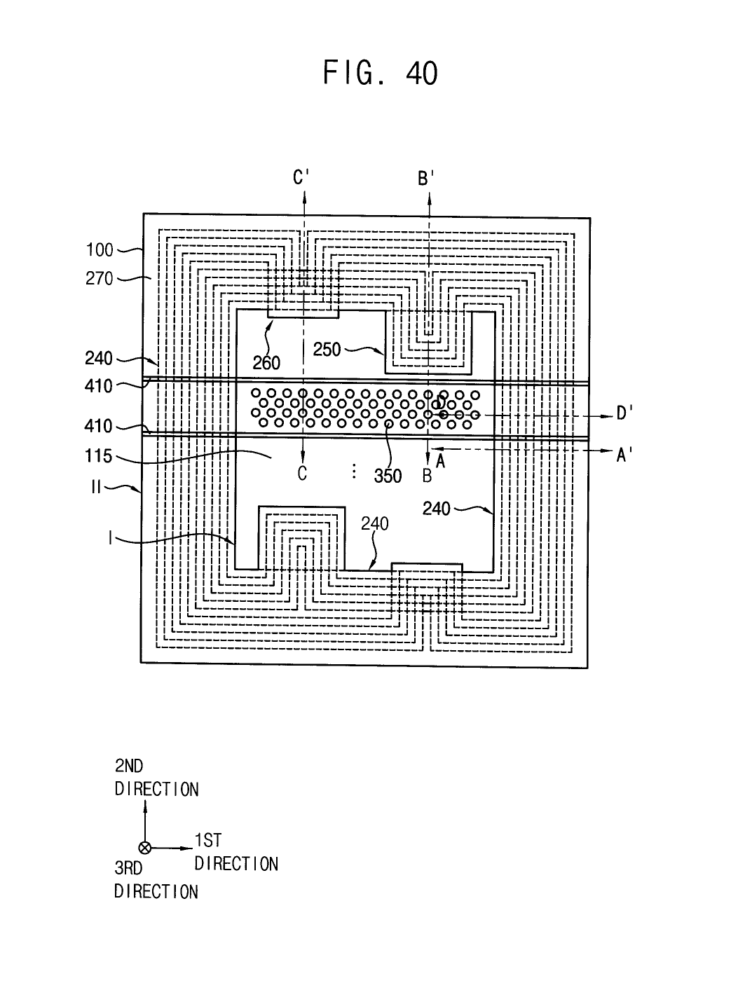

Referring to FIGS. 40, 41 and 42, a second blocking layer may be formed on the exposed portions of the outer sidewalls of the first blocking layer patterns 300, the exposed portions of the sidewalls of the semiconductor patterns 290, inner walls of the gaps 370, surfaces of the first and second insulation layer patterns 115 and 117, the exposed top surface of the substrate 100 and a top surface of the capping layer pattern 350, and a conductive layer may be formed on the second blocking layer to sufficiently fill remaining portions of the gaps 370.

The second blocking layer may be formed to include a metal oxide, e.g., aluminum oxide, hafnium oxide, lanthanum oxide, lanthanum aluminum oxide, lanthanum hafnium oxide, hafnium aluminum oxide, titanium oxide, tantalum oxide and/or zirconium oxide.

The conductive layer may be formed to include a metal and/or a metal nitride. For example, the conductive layer may be formed to include a metal having a low resistance, e.g., tungsten, titanium, tantalum, platinum, etc., or a metal nitride thereof, e.g., titanium nitride, tantalum nitride, etc.

The conductive layer may be partially removed to form a conductive structure 390 in each gap 370. In example embodiments, the conductive layer may be partially removed by a wet etching process.

In example embodiments, each conductive structure 390 may be formed to extend in the first direction in the first region I, and may further extend to a portion of the second region II adjacent to the first region I in the first direction. Hereinafter, a portion of each conductive structure 390 in the first region I may be referred to as a gate electrode 390, and a portion of each conductive structure 390 in the second region II may be referred to as a conductive pad 395.

In example embodiments, the gate electrodes 390 may include a ground select line (GSL), a word line and a string select line (SSL) sequentially stacked on the substrate 100. Each of the GSL, the word line and the SSL may be formed at a single level or at a plurality of levels. In example embodiments, the GSL may be formed at one level, the SSL may be formed at two levels, and the word line may be formed at eight levels between the GSL and the SSL. However, the numbers of the GSL, the word line and the SSL is not limited thereto. The GSL may be formed adjacent to the semiconductor patterns 290, and the word line and the SSL may be formed adjacent to the channels 330.

When the conductive layer is partially removed, portions of the second blocking layer on surfaces of the first and second insulation layer patterns 115 and 117, on the top surface of the substrate 100, on the top surface of the capping layer patterns 350 and on the top surface of the first insulating interlayer pattern 270 may also be removed to form a second blocking layer pattern 380 surrounding sidewalls of the gate electrode 390 and the conductive pad 395 in each gap 370. The first and second blocking layer patterns 300 and 380 may define a blocking layer pattern structure.

As the conductive layer and the second blocking layer are partially removed, the first opening 360 exposing a top surface of the substrate 100 and extending in the first direction may be formed again, and impurities may be implanted into the exposed top surface of the substrate 100 to form an impurity region 400. In example embodiments, the impurities may include n-type impurities, for example, phosphorus and/or arsenic. In example embodiments, the impurity region 400 may extend in the first direction and serve as a common source line (CSL).

A metal silicide pattern (not shown), e.g., a cobalt silicide pattern or a nickel silicide pattern may be further formed on the impurity region 400.

A second filling layer pattern 410 may be formed to fill each of the first openings 360. In example embodiments, after forming a second filling layer on the substrate 100, the uppermost one of the first insulation layer patterns 115, the capping layer patterns 350 and the first insulating interlayer pattern 270 to fill the first openings 360, an upper portion of the second filling layer may be planarized until the top surface of the uppermost one of the first insulation layer patterns 115 or the top surface of the first insulating interlayer pattern 270 may be exposed to form the second filling layer pattern 410 in each first opening 360.

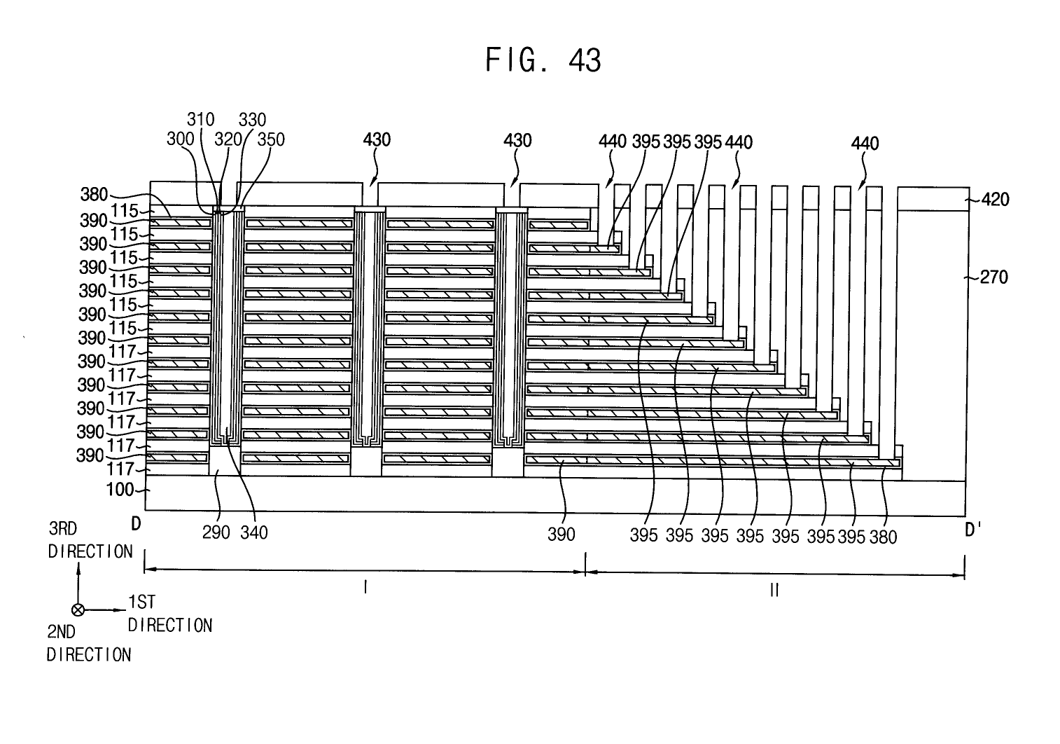

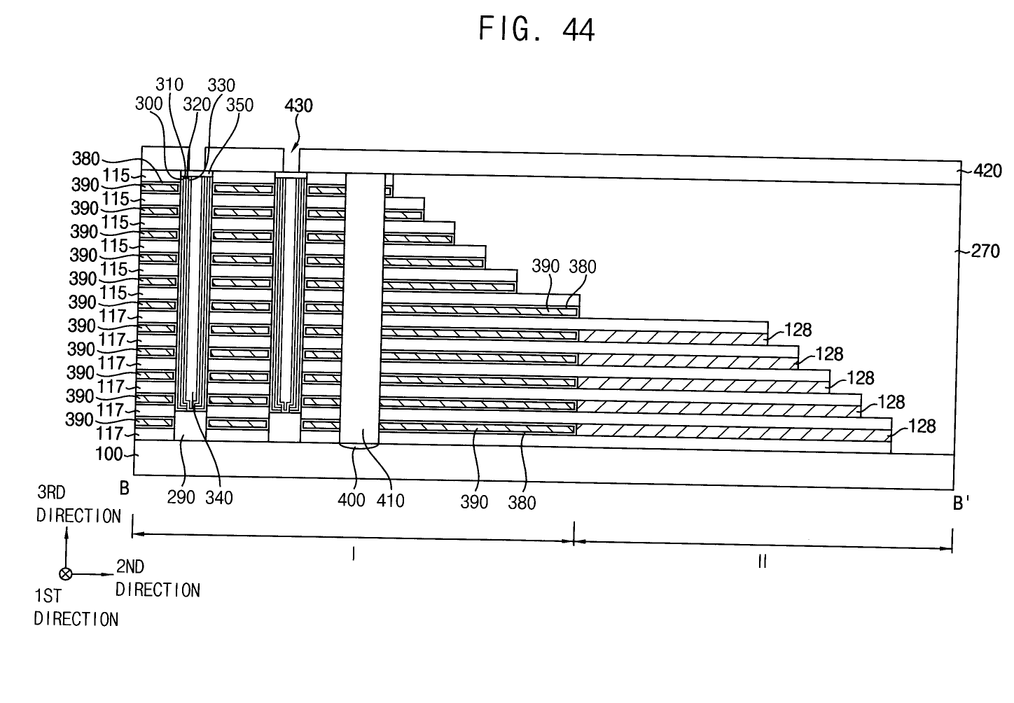

Referring to FIGS. 43 and 44, after forming a second insulating interlayer 420 on the uppermost one of the first insulation layer patterns 115, the capping layer patterns 350, the first insulating interlayer pattern 270 and the second filling layer patterns 410, the second insulating interlayer 420 may be partially removed to form second openings 430 exposing top surfaces of the capping layer patterns 350, respectively, and the second insulating interlayer 420, the first insulating interlayer pattern 270, the first and second insulation layer patterns 115 and 117 and the second blocking layer pattern 380 may be partially removed to form third openings 440 exposing top surfaces of the conductive pads 395, respectively. The second openings 430 may be formed in the first region I, and the third openings 440 may be formed in the second region II. The third openings 440 may not be formed in the portions of the second region II before and after the first region I in the second direction, and thus the first and second insulation pads 126 and 128 may not be exposed.

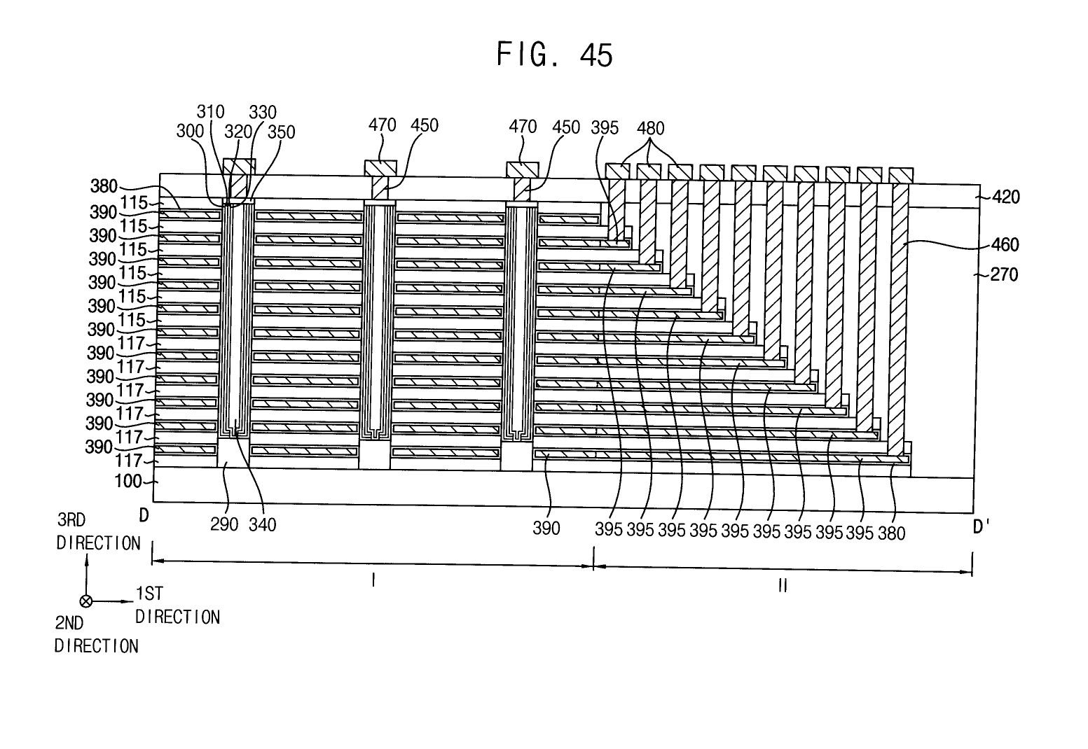

Referring to FIGS. 45, 46 and 47, a plurality of bit line contacts 450 filling the second openings 430 may be formed on the capping layer patterns 350, respectively, and a plurality of first contact plugs 460 filling the third openings 440 may be formed on the conductive pads 395.

In example embodiments, the bit line contacts 450 and the first contact plugs 460 may be formed by forming a contact layer on the exposed capping layer patterns 350, the exposed conductive pads 395 and the second insulating interlayer 420 to sufficiently fill the second and third openings 430 and 440, and by planarizing an upper portion of the contact layer until the top surface of the second insulating interlayer 420 may be exposed. The contact layer may be formed to include, e.g., a metal, a metal nitride and/or doped polysilicon.

A bit line 470 electrically connected to the bit line contact 450 and a first wiring 480 electrically connected to the first contact plug 460 may be formed to complete the vertical non-volatile memory device. The bit line 470 and the first wiring 480 may be formed to include, for example, a metal, a metal nitride and/or doped polysilicon.

In example embodiments, a plurality of bit lines 470 may be formed in the first direction, and each bit line 470 may be formed to extend in the second direction. Additionally, in example embodiments, a plurality of first wirings 480 may be formed in the first direction, and each first wiring 480 may be formed to extend in the second direction. A second contact plug (not shown) and a second wiring (not shown) may be further formed on the first wiring 480.

As described above, in the method of manufacturing the vertical non-volatile memory device, in order to form a mold structure of a staircase shape of which a width may gradually decrease from a bottom level to a top level, after forming a reference layer pattern including a photolithographic reference mark, a photoresist pattern serving as an etching mask for etching insulation layers and sacrificial layers may be formed to have an area greater than that of the reference layer pattern and to include a referenc key which partially exposes a peripheral portion of the photolithographic reference mark of reference layer pattern. By measuring a distance between a boundary of the exposed peripheral portion of the reference layer pattern and a boundary of the photoresist pattern, a determination can be made as to whether the photoresist pattern is formed to have a desired size and/or scale and/or position with respect to the reference layer pattern.

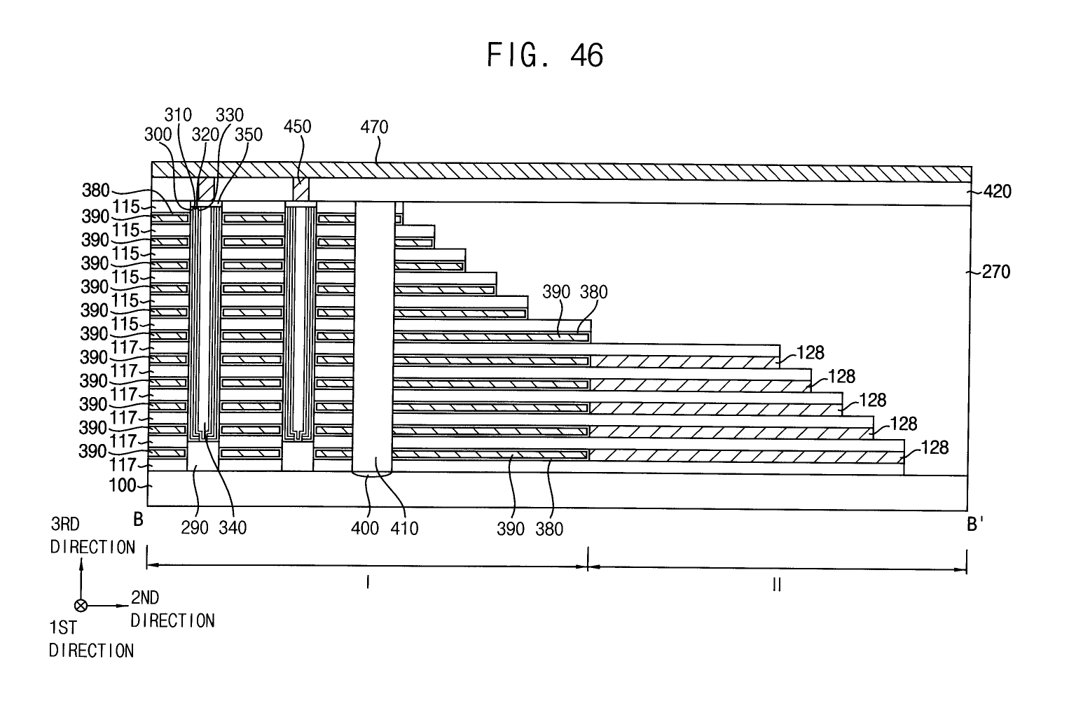

Referring to FIGS. 40 through 47, a resultant semiconductor memory device includes a memory cell array region I including an array of vertically arranged memory cells intersecting a stack of horizontally extending first connection layers 390 (of FIG. 45), and a connection region II (of FIG. 45) adjacent the memory cell array region I in a first direction in a top view. The stack of first connection lines 390 (of FIG. 45) extend from the memory cell array region I into the connection region II to define a first staircase-shaped structure in the connection region II, where ends of the connection lines 390 constitute treads of the first staircase-shaped structure. The semiconductor device further includes a non-active region which is delimited, for example, by the cut line 410 shown in FIGS. 40, 46 and 47. The non-active region includes second connection lines 390 (of FIGS. 45 and 46) which define a second staircase-shaped structure (FIG. 45 or 46) in which ends of the second connection lines 390 constitute treads of the second staircase-shaped structure. Referring to the top view of FIG. 40, the second staircase-shaped structure includes a staircase protrusion section (e.g., the portion bisected by line B-B′) located adjacent the memory cell array region I in a second direction in the top view. As shown in the top view of FIG. 40, each of the treads of the staircase protrusion section include a first tread portion protruding in the second direction towards the memory cell array from second tread portions running parallel to the first direction.

In the method illustrated with reference to FIGS. 1 to 47, second and third photoresist patterns are used for etching the insulation layers and the sacrificial layers in addition to a first photoresist pattern for etching a reference layer, however, the numbers of the photoresist patterns is not limited thereto, and one or a plurality of photoresist patterns may be used for etching the insulation layers and the sacrificial layers in consideration of the number of gate electrodes or the number of performances of trimming process. A third area in which the third photoresist pattern relatively formed subsequently is formed may cover a second area in which the second photoresist pattern relatively formed in advance is formed, except for a peripheral portion of the second area, and may have an area greater than that of the second area. By measuring a distance between a boundary of the peripheral portion of the second area not covered by the third area and a boundary of the third area, whether the third photoresist pattern is formed to have a desired size with respect to the second photoresist pattern.

Referring to FIGS. 40 and 45 to 47 again, the vertical non-volatile memory device may include a plurality of gate electrodes 390, a plurality of conductive pads 395, a plurality of insulation pads 126 and 128, and a channel 330. The plurality of gate electrodes 390 may be stacked on the substrate 100 in the third direction. The plurality of conductive pads 395 may be stacked on the substrate 100 in the third direction, and each of the conductive pads 395 may extend in the first direction from each of the gate electrodes 390. Lengths of the conductive pads 395 extending in the first direction may gradually decrease from a bottom level to a top level at a constant first ratio. The plurality of insulation pads 126 and 128 may be stacked on the substrate 100 in the third direction, and each of the insulation pads 126 and 128 may extend in the second direction from each of at least one of the gate electrodes 390. The insulation pads 126 and 128 may include the second area at which lengths of the insulation pads 126 and 128 extending in the second direction may decrease from a bottom level to a top level at a changing second ratio. The channel 330 may extend in the third direction through the gate electrodes 390. The insulation pads 126 and 128 may further include the third area at which lengths of the insulation pads 126 and 128 may decrease from a bottom level to a top level at a changing third ratio. The third area may be spaced apart from the second area. At the first area that is the other area except for the second and third areas, lengths of the insulation pads 126 and 128 extending in the second direction may decrease from a bottom level to a top level at the constant first ratio.

At least one of the gate electrodes 390 may have a first pair of boundaries opposite to each other in the first direction and a second pair of boundaries opposite to each other in the second direction in a top view, and a recess in the second direction may be formed in each boundary of the second pair of boundaries. In example embodiments, a depth in the second direction of the recess may be larger than a length difference in the first direction between the conductive pads 395 at neighboring levels. A portion of the gate electrode 390 in which the recess is formed may be formed by a process for monitoring the length difference between the conductive pads 395 at neighboring levels, and may be referred to as a monitoring portion.

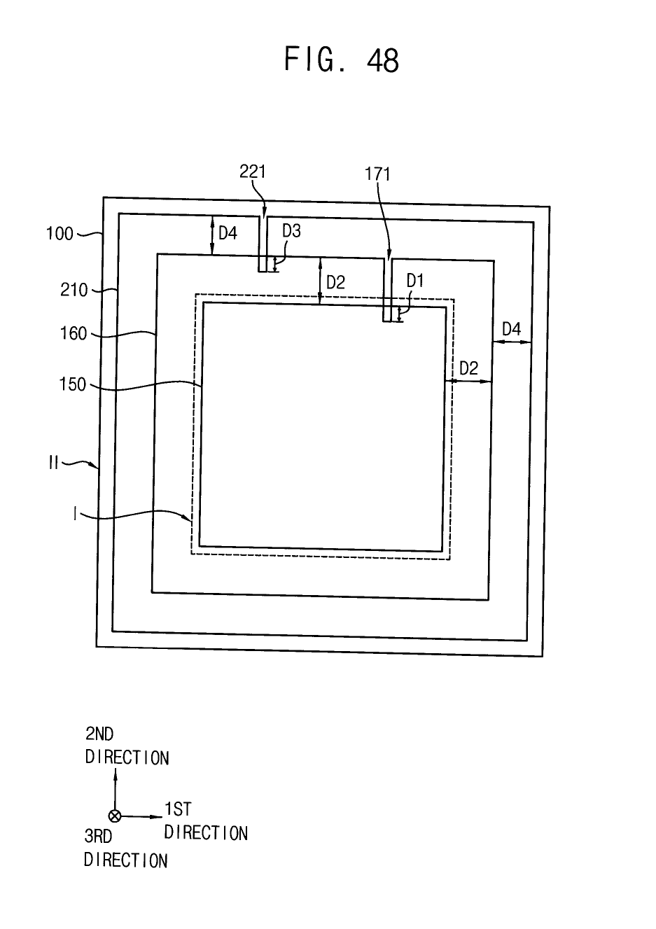

FIGS. 48, 49, 50, 51 and 52 are plan views illustrating first, second and third photoresist patterns used for manufacturing a vertical non-volatile memory device in accordance with example embodiments. The first, second and third photoresist patterns may have a rectangular shape as a whole in a top view, like the first, second and third photoresist patterns 150, 160 and 210 illustrated with reference to FIGS. 1 to 47. However, the first, second and third photoresist patterns of FIGS. 48 to 52 may have a different number or position of recesses, or may have an opening instead of a recess. Hereinafter, only the differences of the first, second and third photoresist patterns of FIGS. 48 to 52 in comparison with those of FIGS. 1 to 47 will be described.

Referring to FIG. 48, the second photoresist pattern 160 may include a first pair of boundaries that may be opposite to each other in the first direction and extend in the second direction, and a second pair of boundaries that may be opposite to each other in the second direction and extend in the first direction, and the first recess 171 partially exposing a peripheral portion of the first area covered by the first photoresist pattern 150 may be formed only in one boundary of the second pair of boundaries. The third photoresist pattern 210 may include first and second pairs of boundaries, and a fourth recess 221 partially exposing a peripheral portion of the second area covered by the second photoresist pattern 160 may be formed only in one boundary of the second pair of boundaries.

Even though the first and fourth recesses 171 and 221 may be formed only in one boundary of the second pair of boundaries of each of the second and third photoresist patterns 160 and 210, whether the second and third photoresist patterns 160 and 210 are formed to have desired sizes may be confirmed by measuring sizes of the peripheral portions of the first and second areas exposed by the first and fourth recesses 171 and 221, respectively.

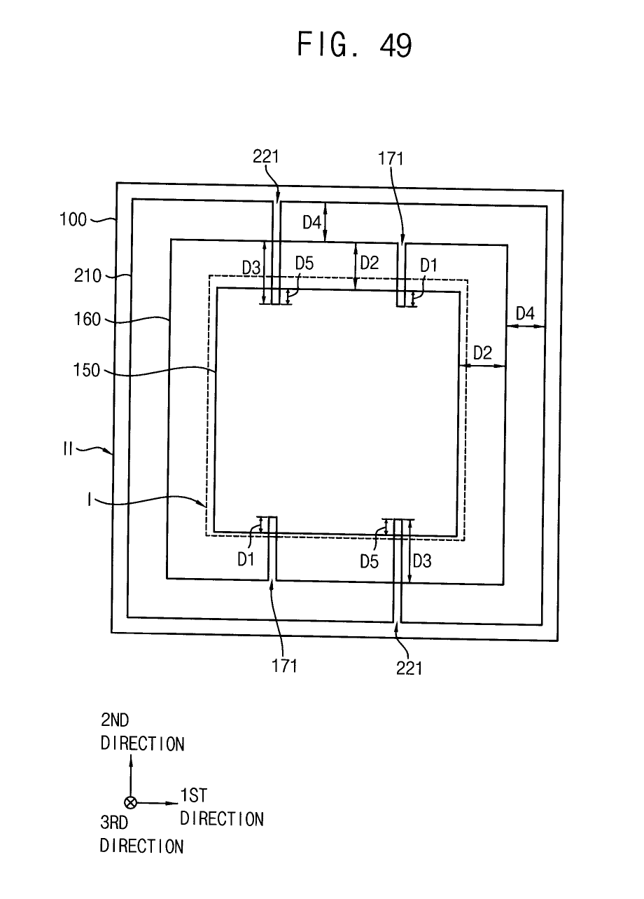

Referring to FIG. 49, the third photoresist pattern 210 may include first and second pairs of boundaries, and the fourth recess 221 partially exposing not only a peripheral portion of the second area covered by the second photoresist pattern 160 but also a peripheral portion of the first area covered by the first photoresist pattern 150 may be formed in the second pair of boundaries. The fourth recess 221 of the third photoresist pattern 210 may be spaced apart from the first recess 171 of the second photoresist pattern 160 in the first direction, and the fourth recess 221 may not overlap the first recess 171.

As the fourth recess 221 may be formed to have a deep depth, whether the third photoresist pattern 210 is formed to have a desired size may be confirmed not only by a third distance D3 between a boundary of a peripheral portion of the second area exposed by the fourth recess 221 and a boundary of the third photoresist pattern 210 in the second direction, but also by a fifth distance D5 between a boundary of a peripheral portion of the first area exposed by the fourth recess 221 and a boundary of the third photoresist pattern 210 in the second direction.

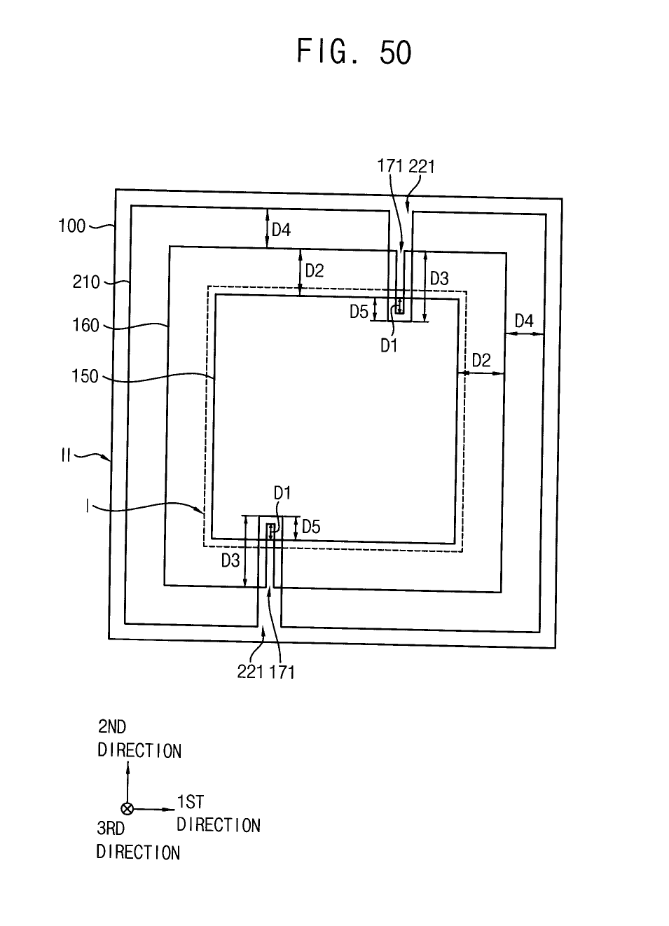

Referring to FIG. 50, the third photoresist pattern 210 may include first and second pairs of boundaries like that of FIG. 49, and the fourth recess 221 partially exposing not only a peripheral portion of the second area covered by the second photoresist pattern 160 but also a peripheral portion of the first area covered by the first photoresist pattern 150 may be formed in the second pair of boundaries. However, the fourth recess 221 of the third photoresist pattern 210 may vertically overlap the first recess 171 of the second photoresist pattern 160.

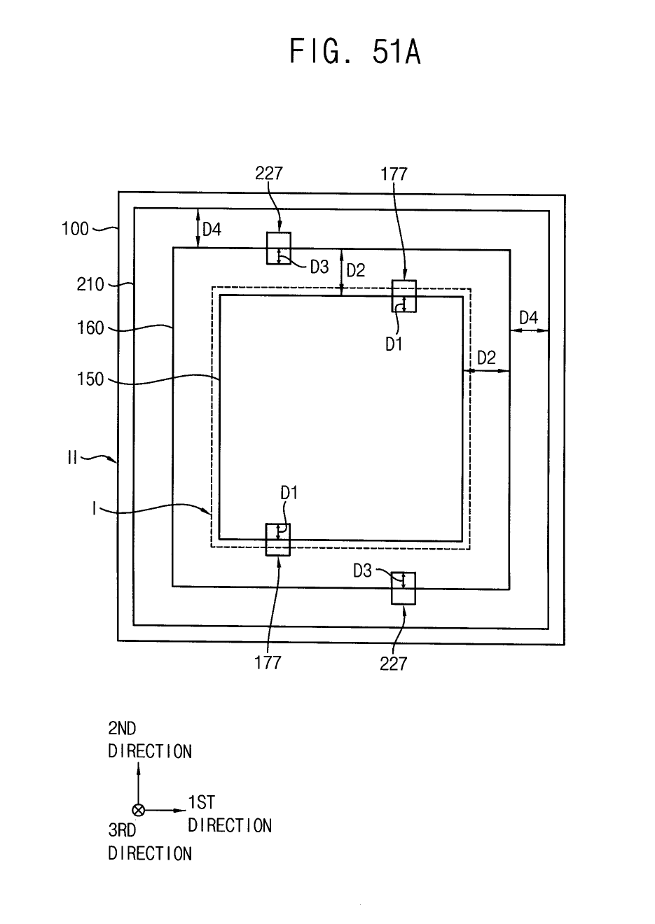

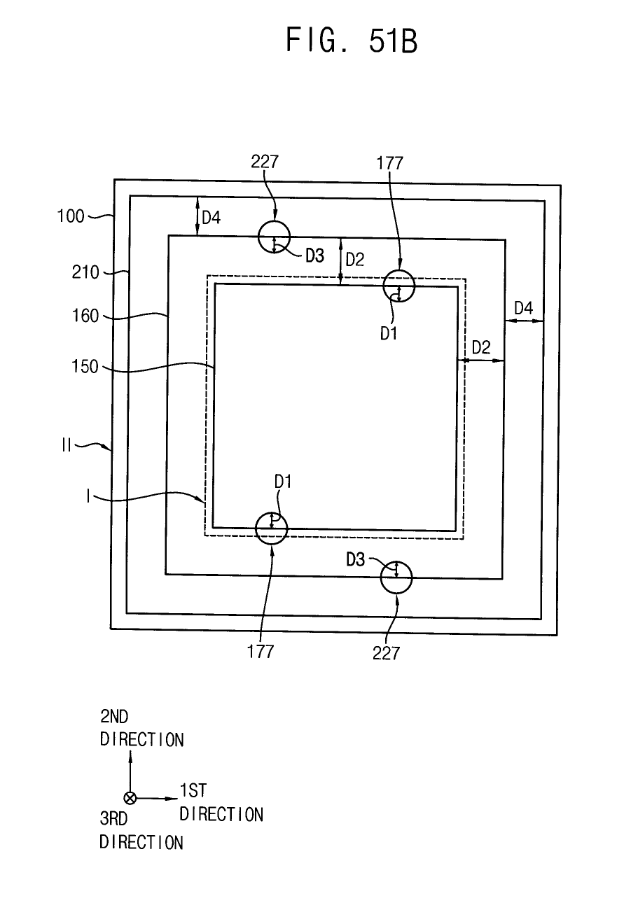

Referring to FIG. 51A, the second photoresist pattern 160 may include a fourth opening 177 partially exposing a peripheral portion of the first area covered by the first photoresist pattern 150 in the second pair of boundaries, and the third photoresist pattern 210 may include a fifth opening 227 partially exposing a peripheral portion of the second area covered by the second photoresist pattern 160 in the second pair of boundaries.

Thus, whether the second photoresist pattern 160 is formed to have a desired size and/or scale and/or position may be confirmed by a first distance D1 between a boundary of the peripheral portion of the first area exposed by the fourth opening 177 and a boundary of the second photoresist pattern 160 in the second direction, i.e., an inner wall of the fourth opening 177 in the second direction. Likewise, whether the third photoresist pattern 210 is formed to have a desired size may be confirmed by a third distance D3 between a boundary of the peripheral portion of the second area exposed by the fifth opening 227 and a boundary of the third photoresist pattern 210 in the second direction, i.e., an inner wall of the fifth opening 227 in the second direction.

Each of the fourth and fifth openings 177 and 227 may be formed only in one boundary of the second pair of boundaries of each of the second and third photoresist patterns 160 and 210.

Referring to FIG. 51B, the second and third photoresist patterns 160 and 210 may include the fourth and fifth openings 177 and 227, respectively, like those of FIG. 51A, however, the fourth and fifth openings 177 and 227 may have a circular shape in a top view.

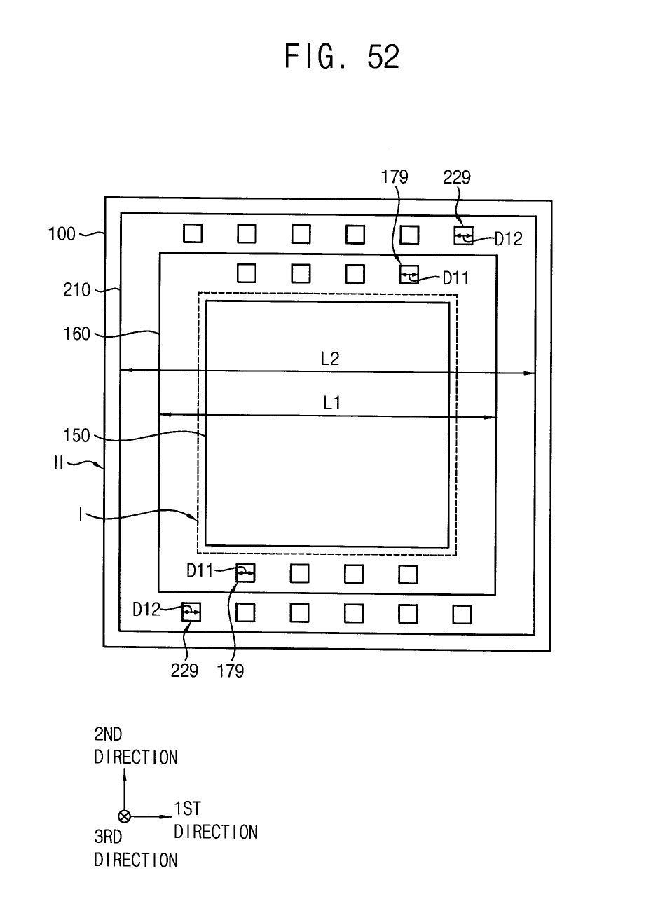

Referring to FIG. 52, the second and third photoresist patterns 160 and 210 may include sixth and seventh openings 179 and 229 therein, respectively. The sixth and seventh openings 179 and 229 may not expose the first and second areas, respectively, unlike the fourth and fifth openings 177 and 227, respectively. In example embodiments, one or a plurality of sixth openings 179 may be formed adjacent to the second pair of boundaries of the second photoresist pattern 160, and one or a plurality of seventh openings 229 may be formed adjacent to the second pair of boundaries of the third photoresist pattern 210. The sixth and seventh openings 179 and 229 may not expose the boundaries of the first and second areas, respectively, unlike the fourth and fifth openings 177 and 227, respectively, and thus whether the second and third photoresist patterns 160 and 210 are formed to have desired sizes may not be confirmed by the relationship between the first and second photoresist patterns 150 and 160 and by the relationship between the second and third photoresist patterns 160 and 210, respectively. However, first and second lengths L1 and L2 of the second and third photoresist patterns 160 and 210, respectively, may be known by sizes of the sixth and seventh openings 179 and 229, e.g., eleventh and twelfth distances D11 and D12, respectively, in the first direction, and thus whether the second and third photoresist patterns 160 and 210 are formed to have desired sizes may be confirmed.

The sixth and seventh openings 179 and 229 may be formed in a portion of the second and third photoresist patterns 160 and 210, respectively, adjacent to only one boundary of the second pair of boundaries, and may have circular shapes like those of FIG. 51B.

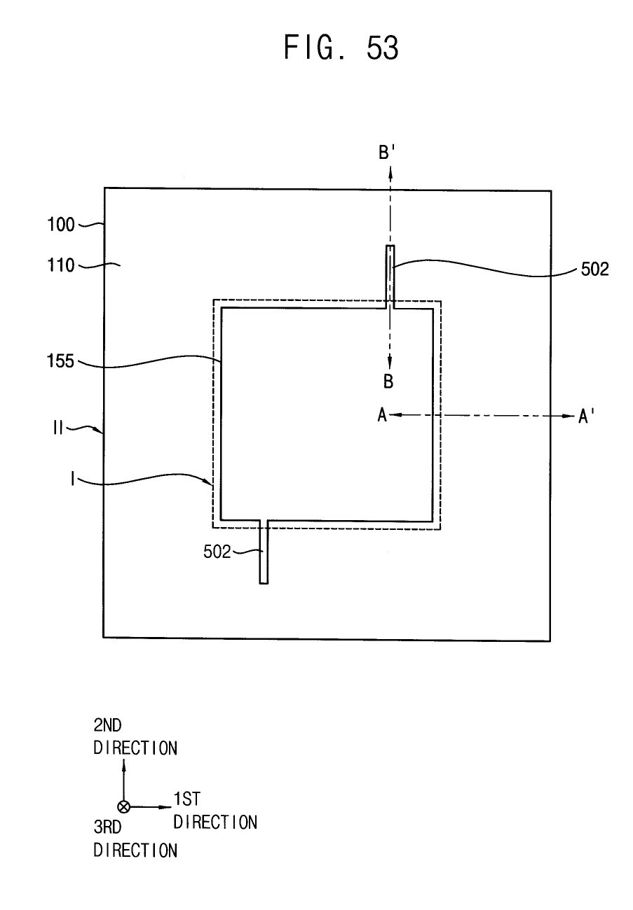

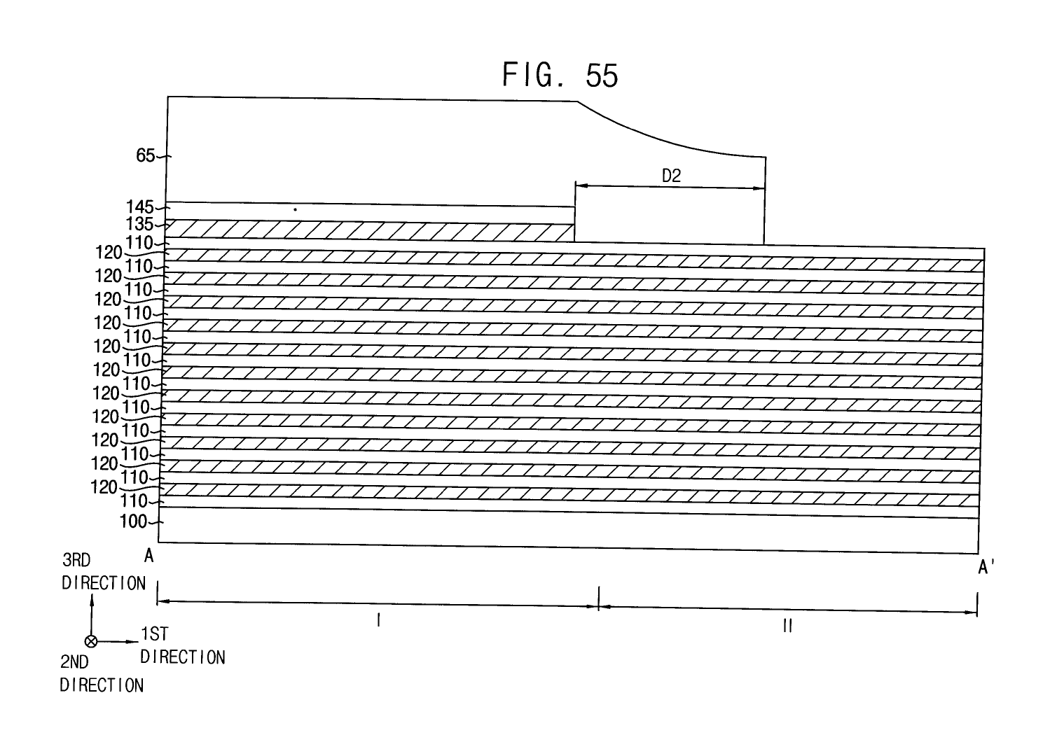

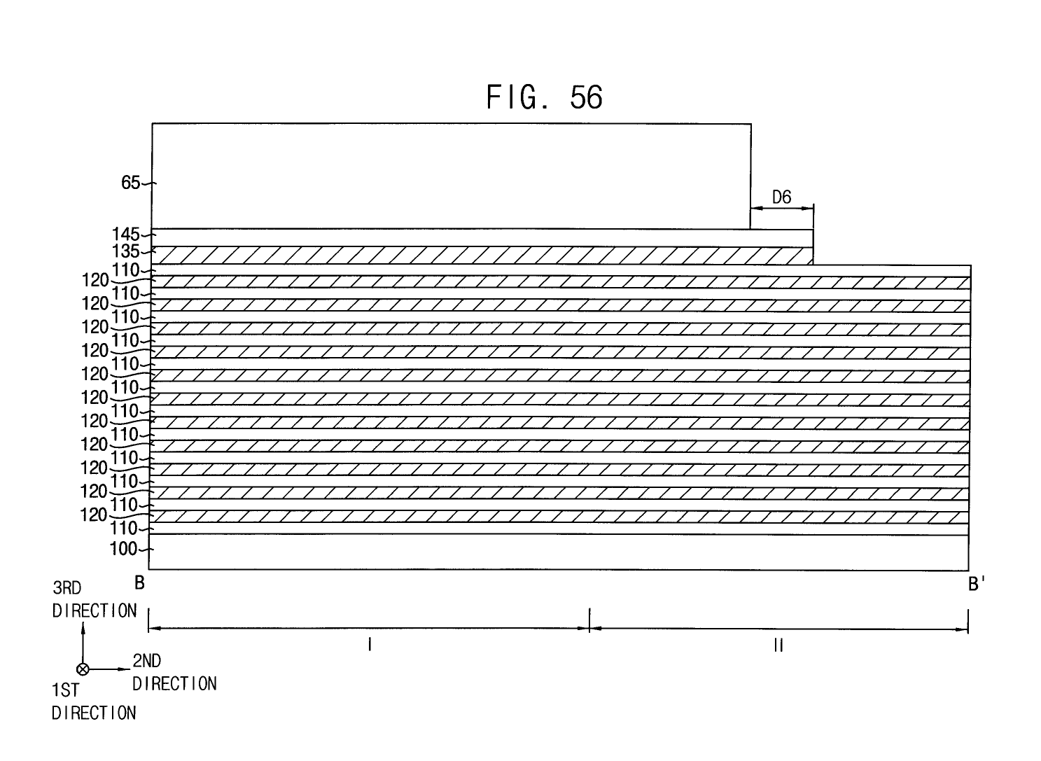

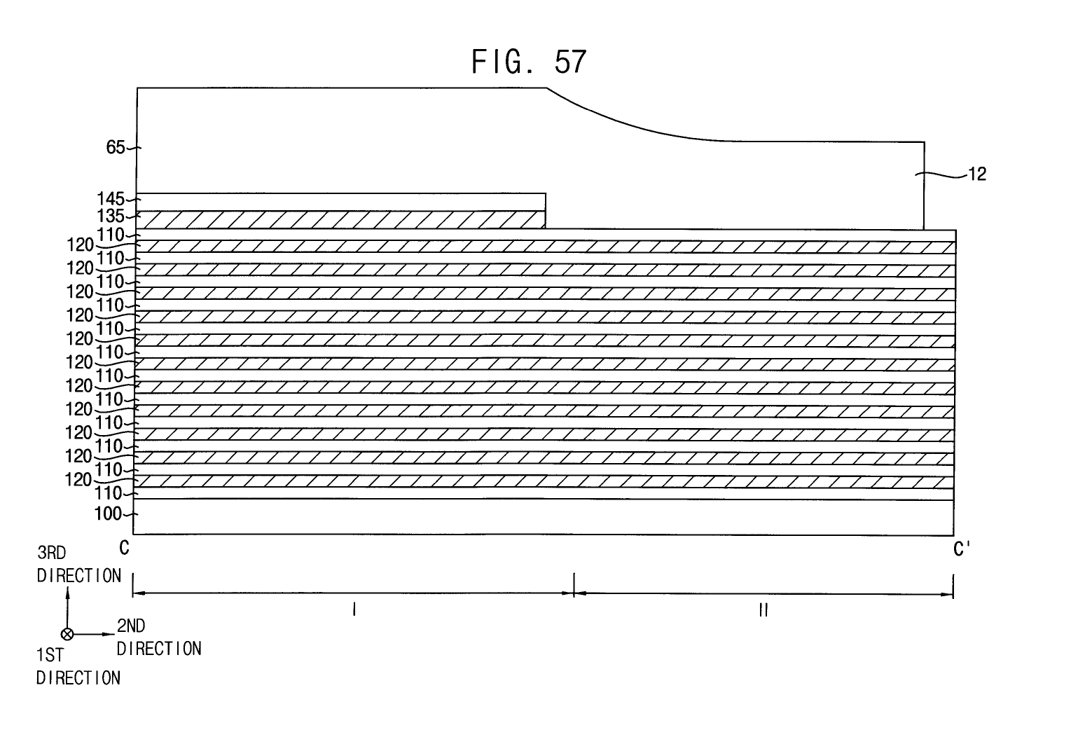

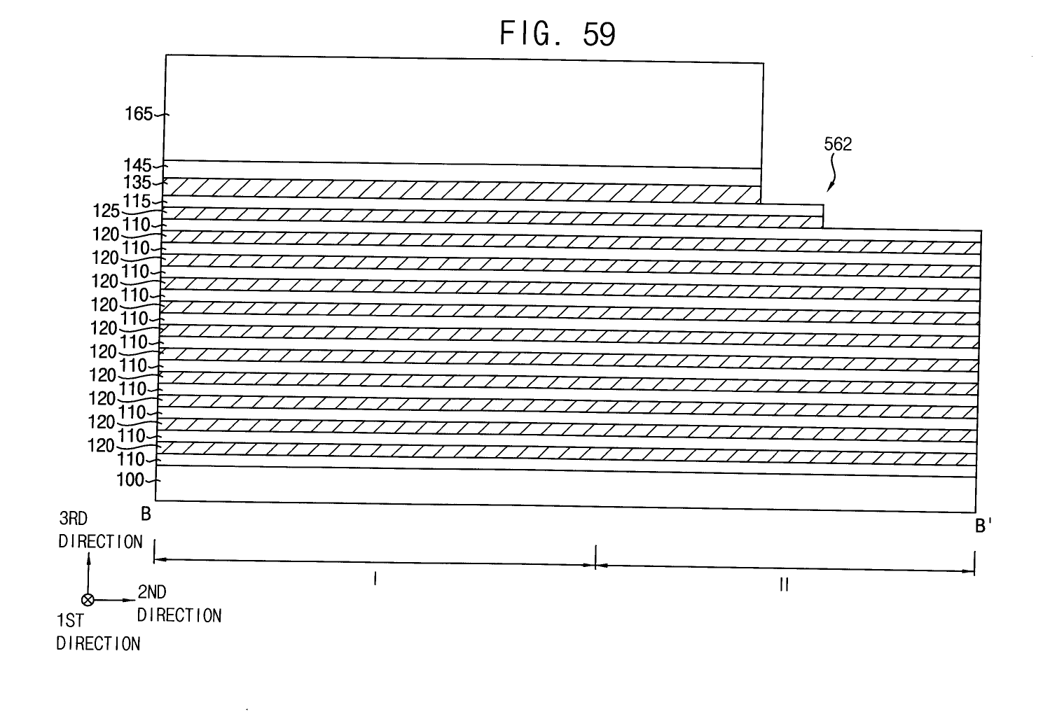

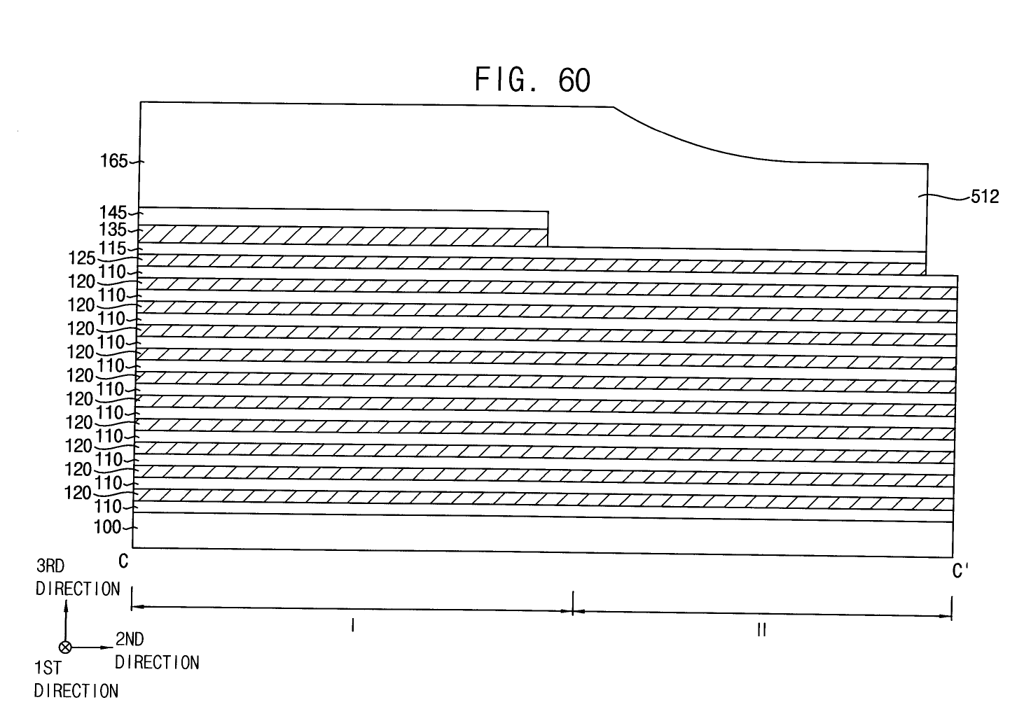

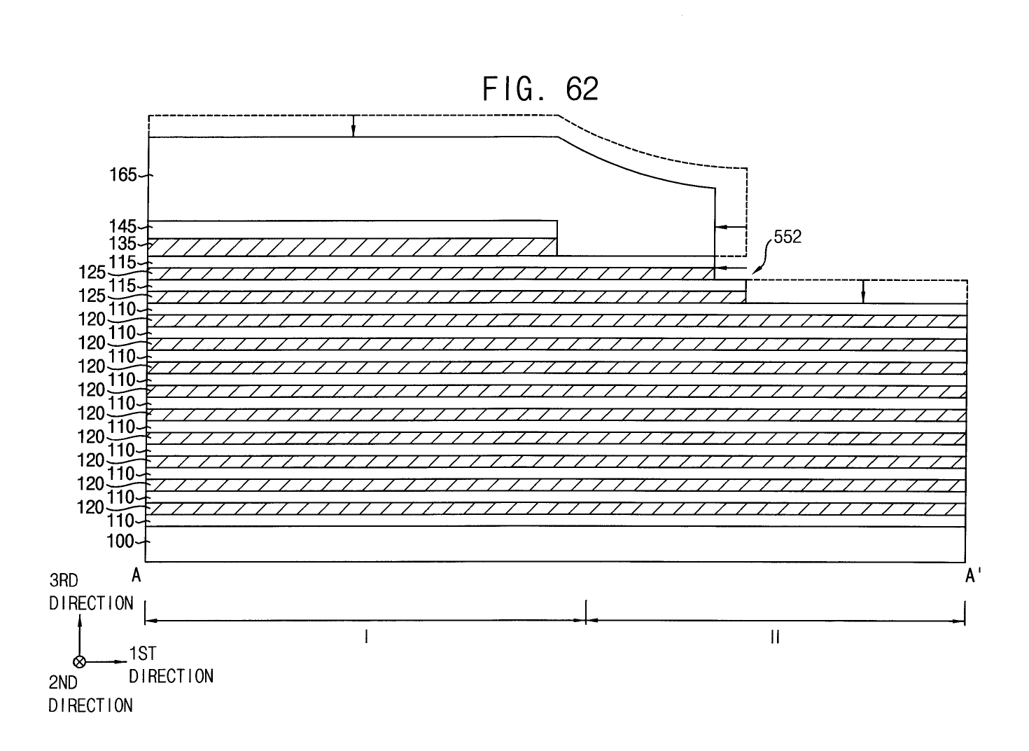

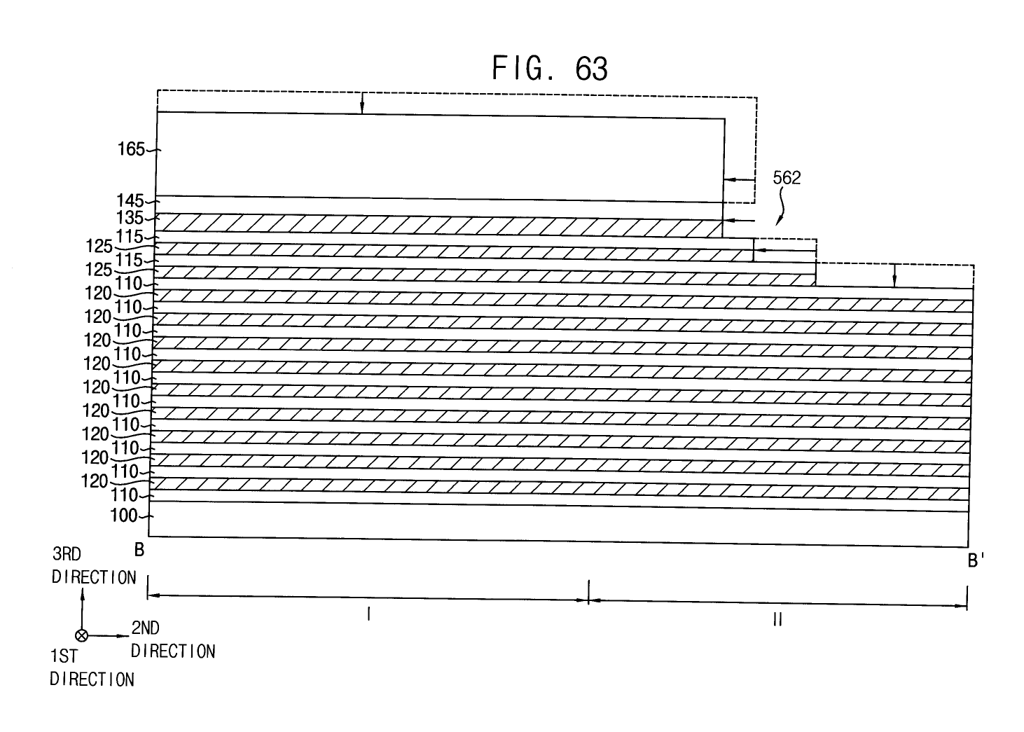

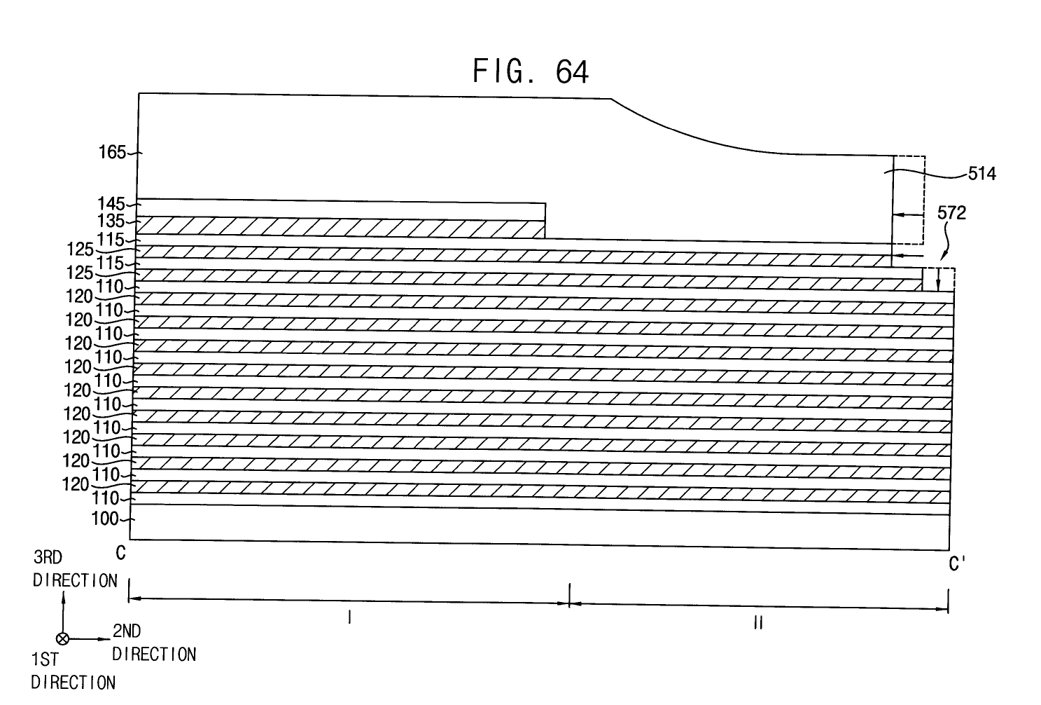

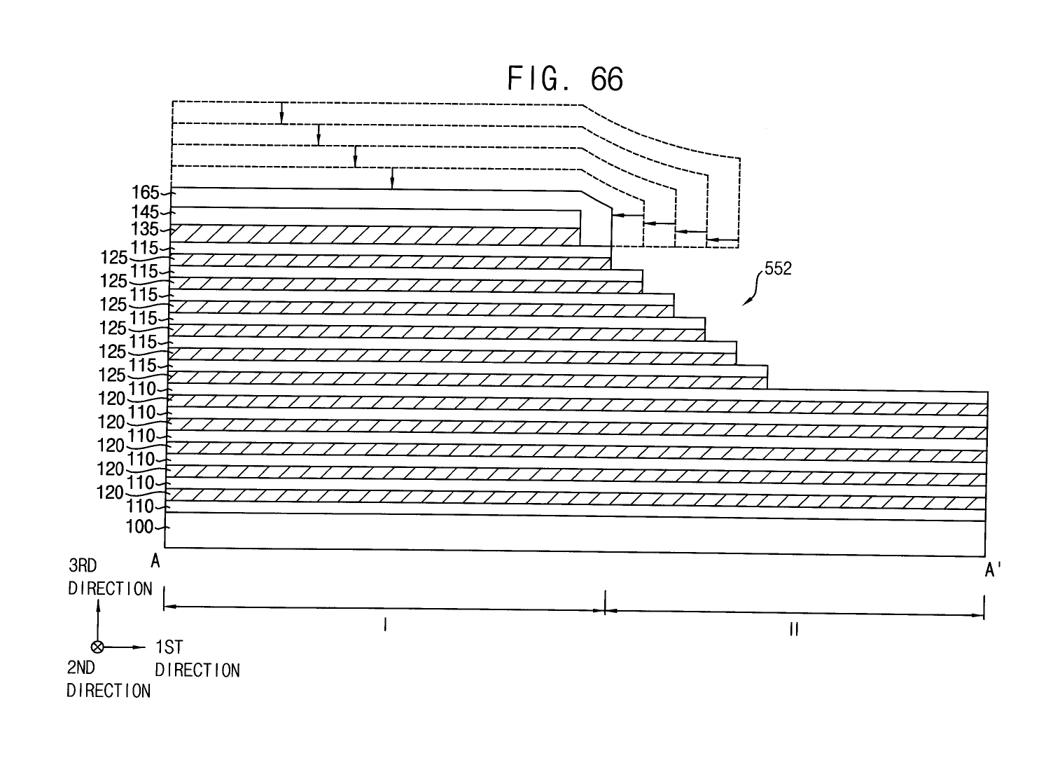

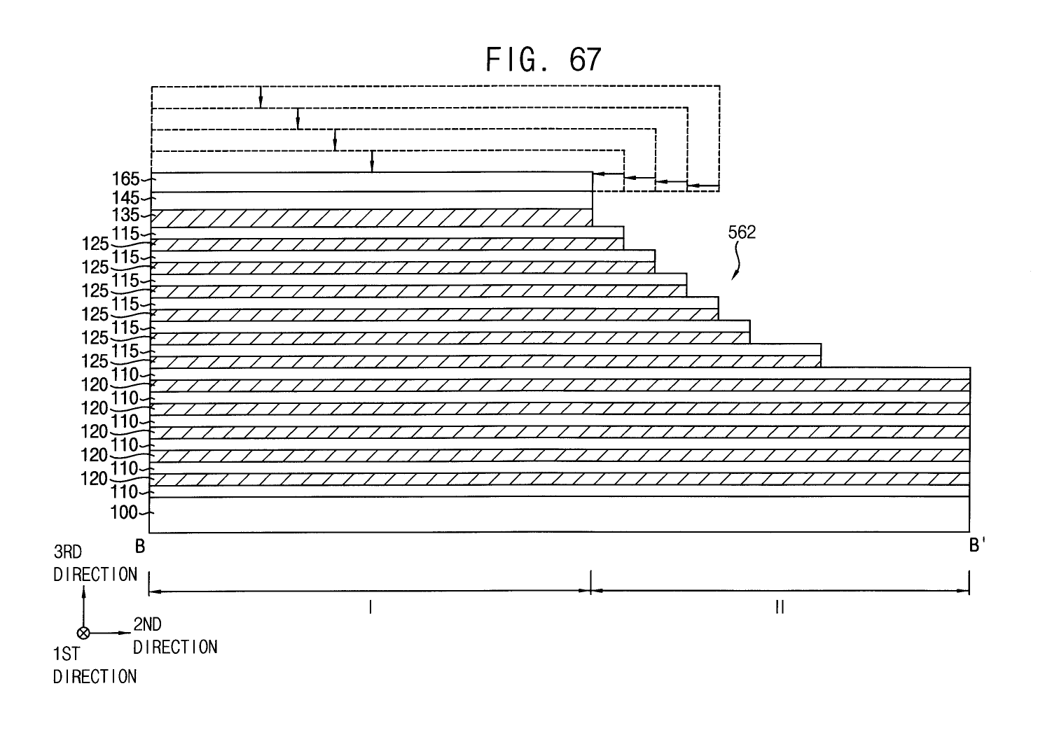

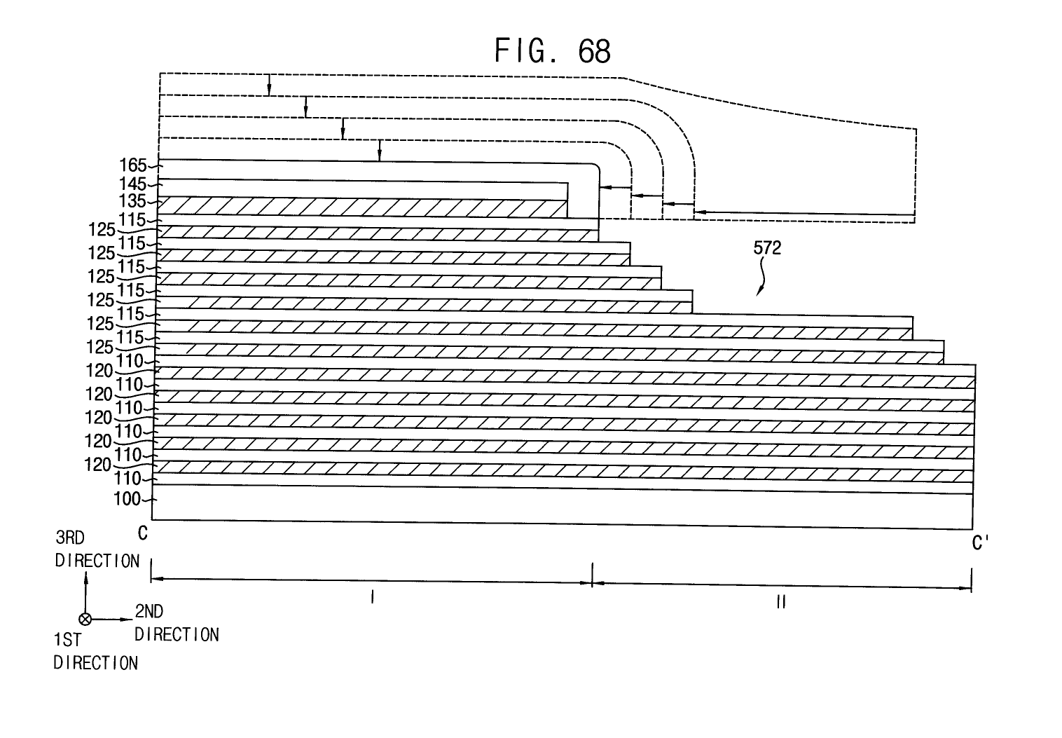

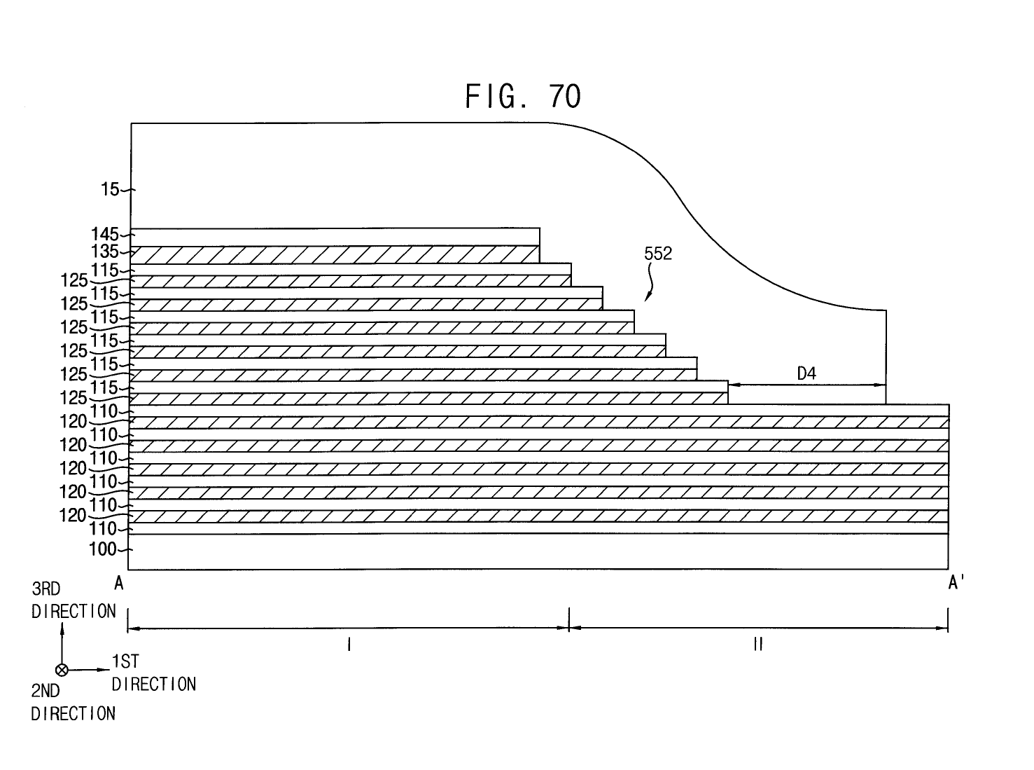

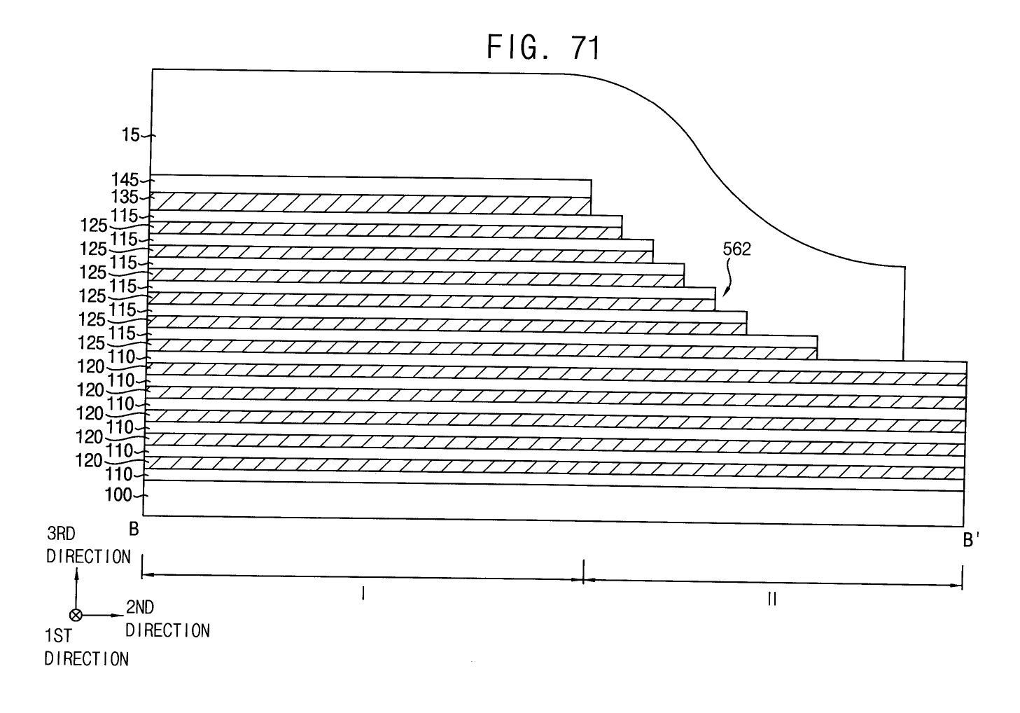

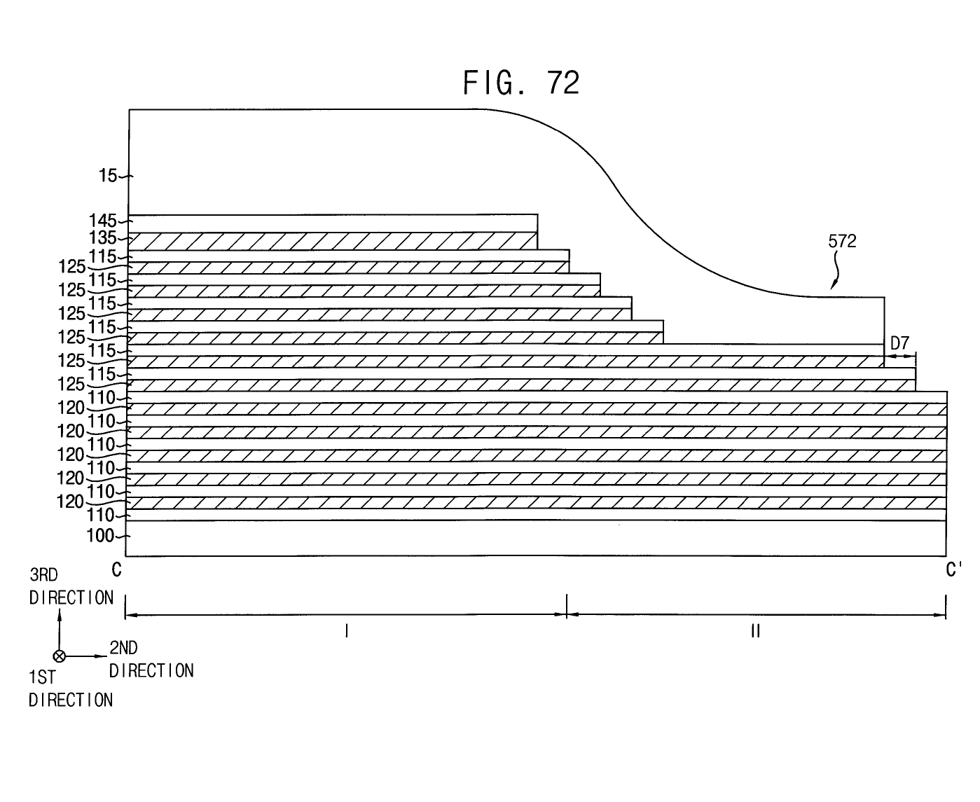

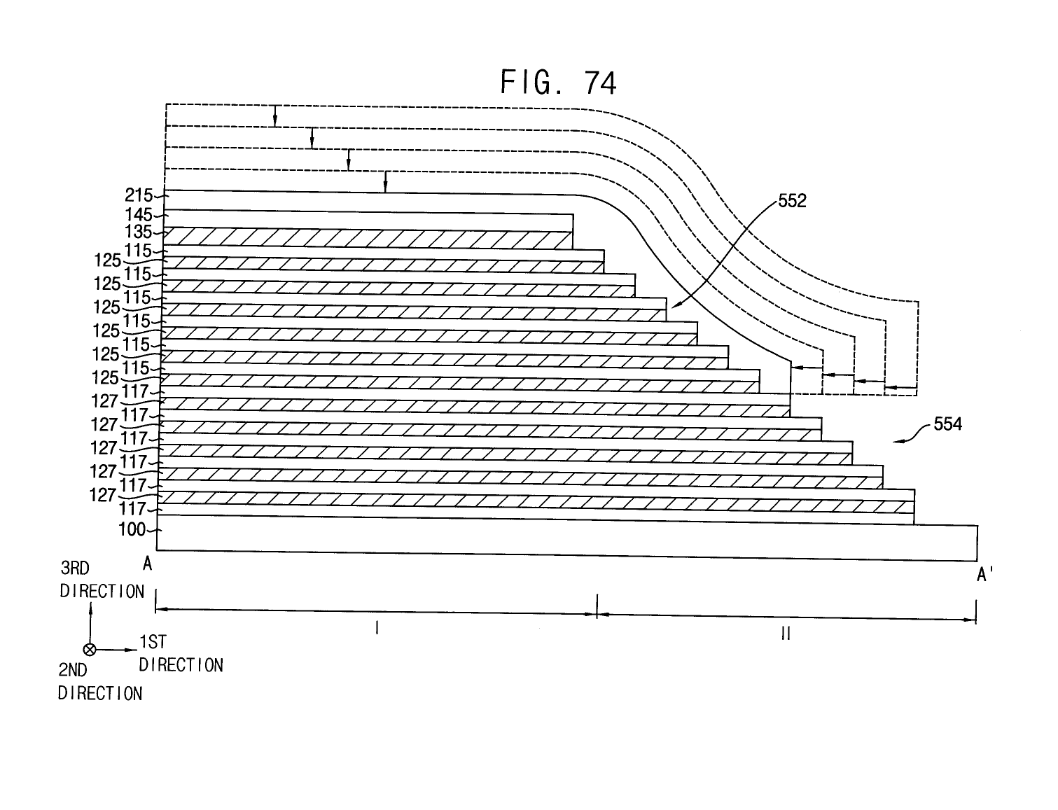

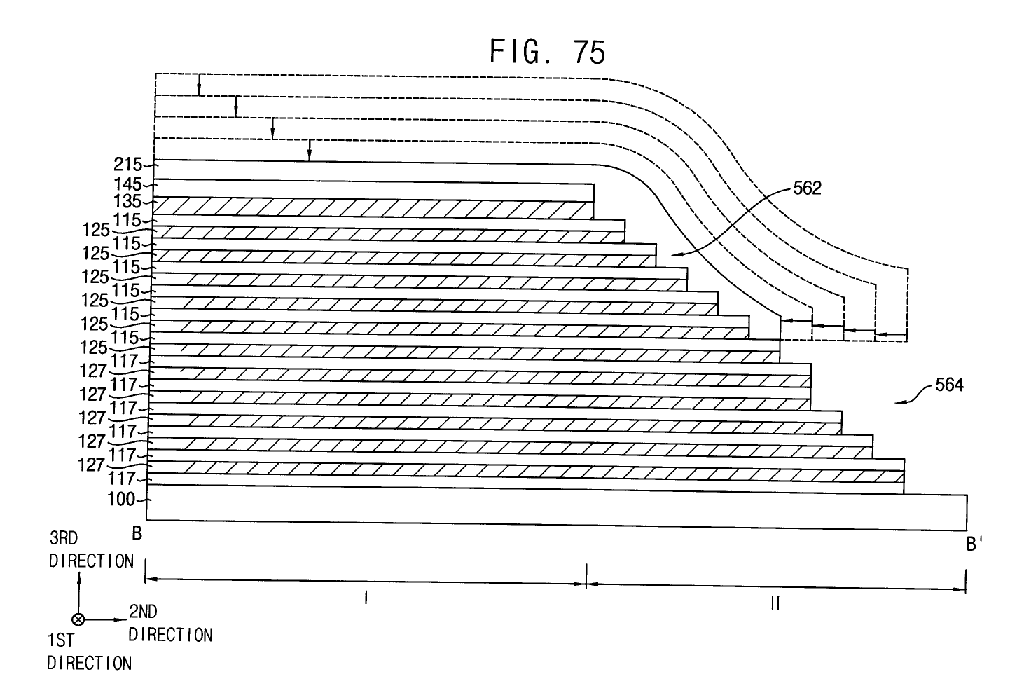

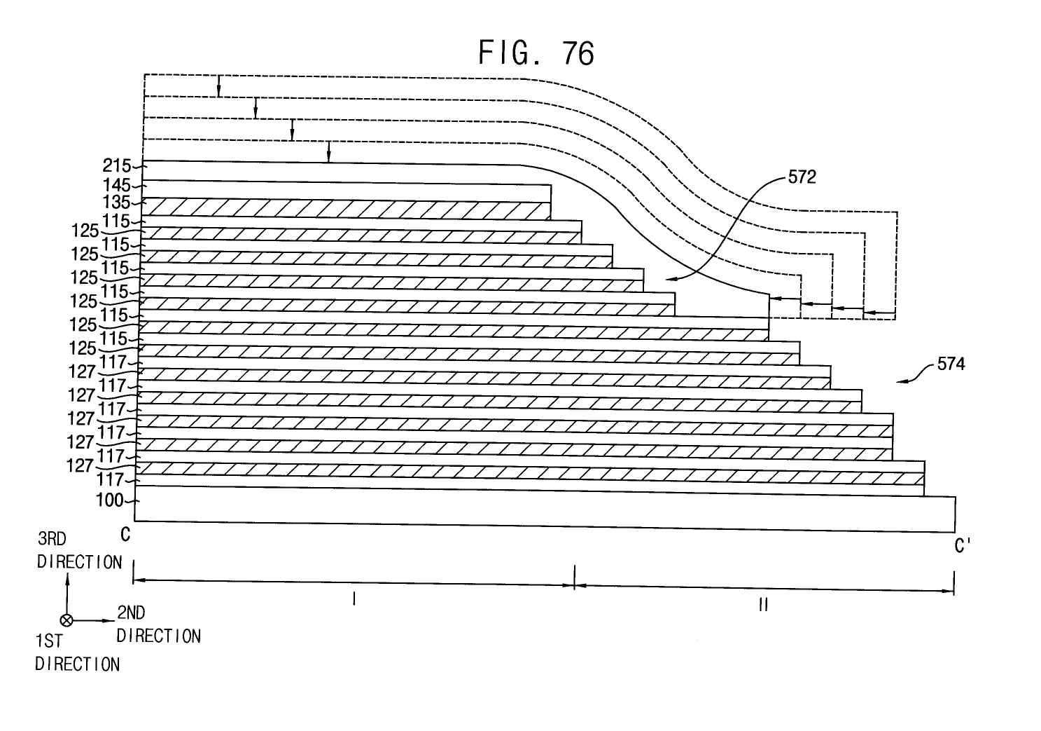

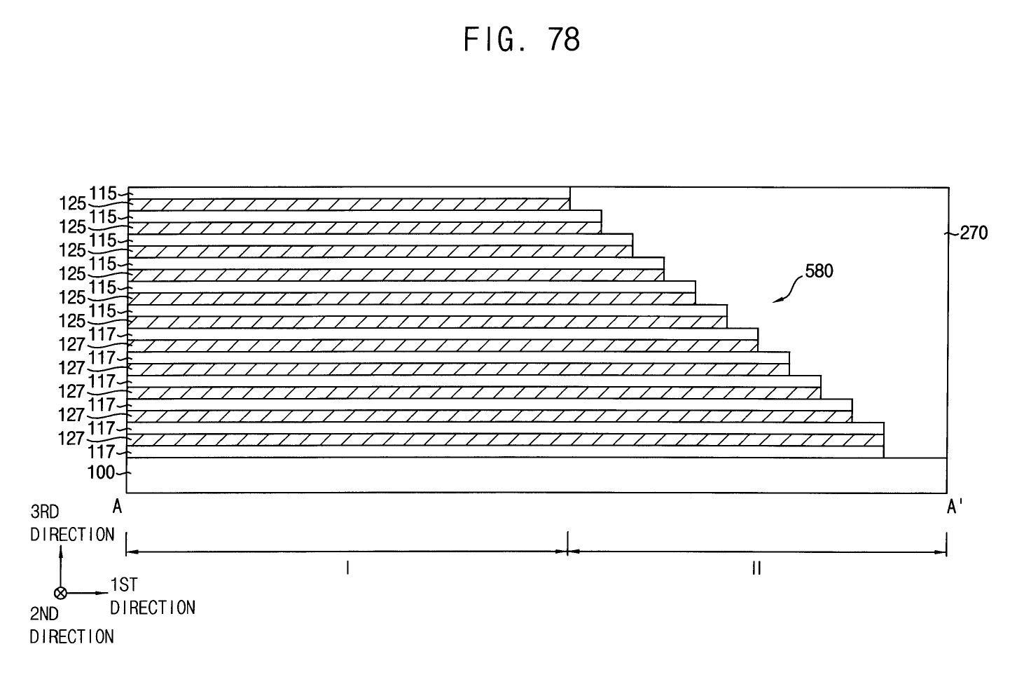

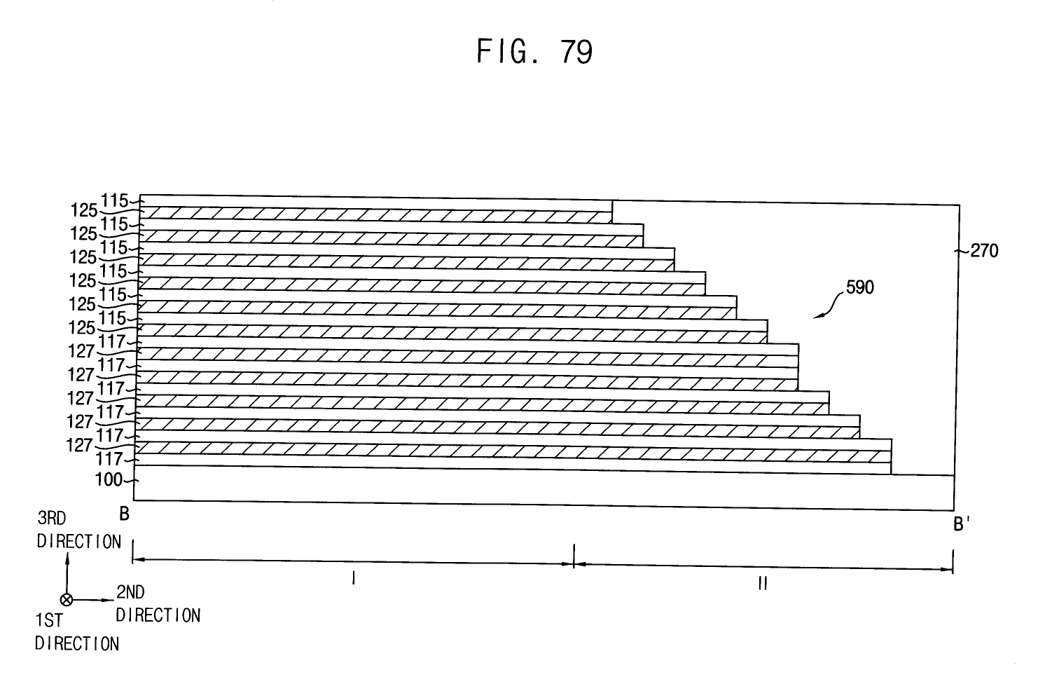

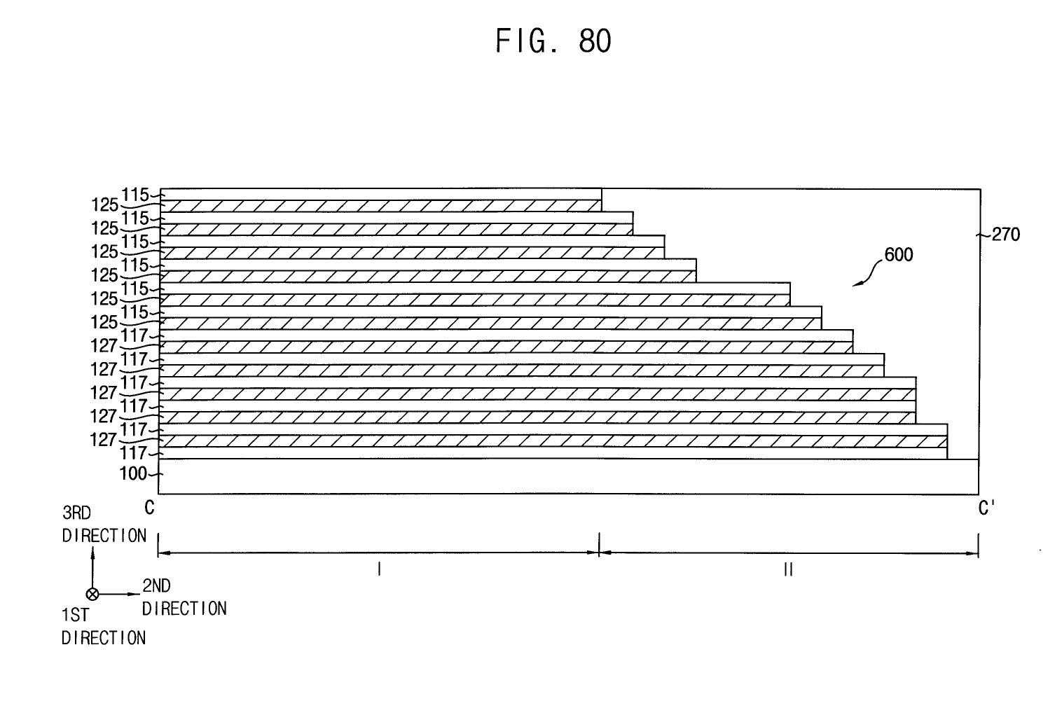

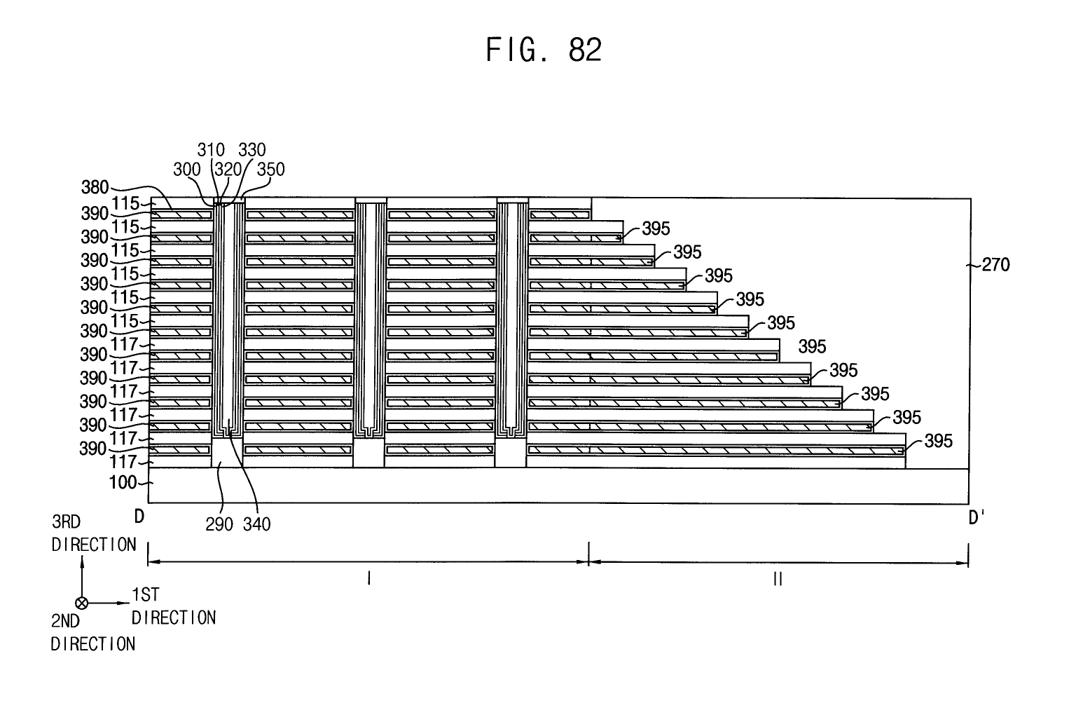

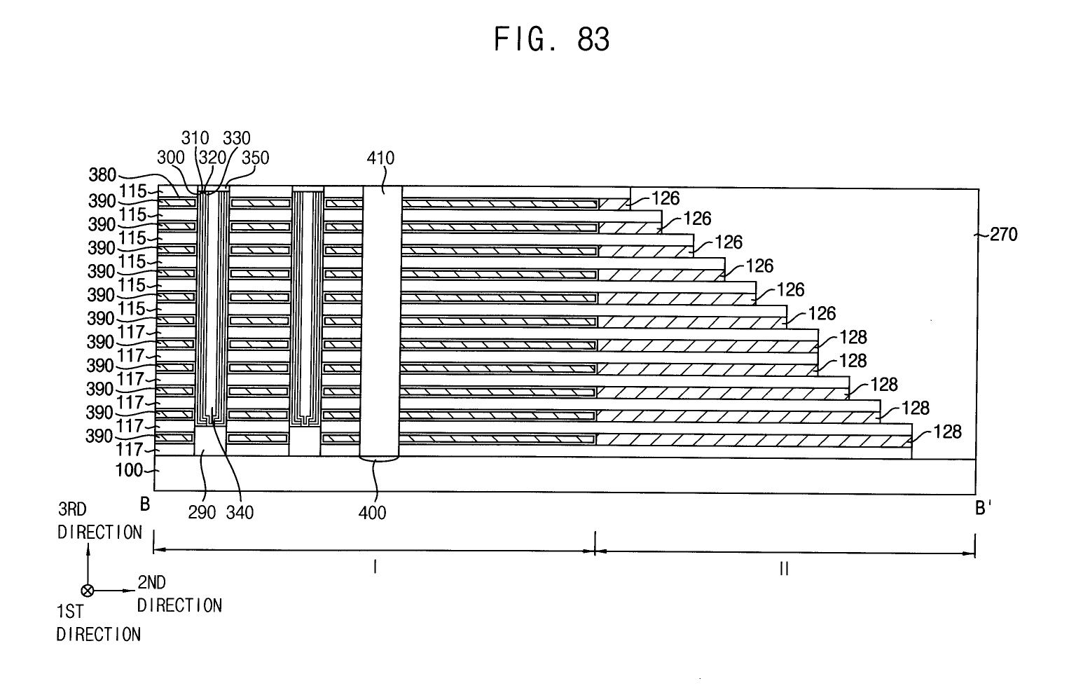

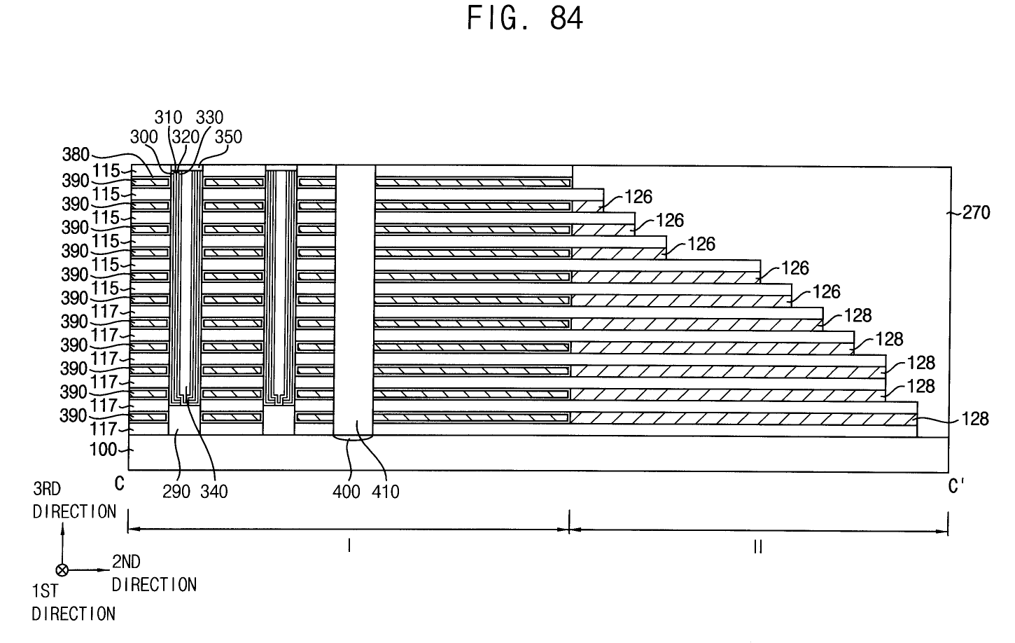

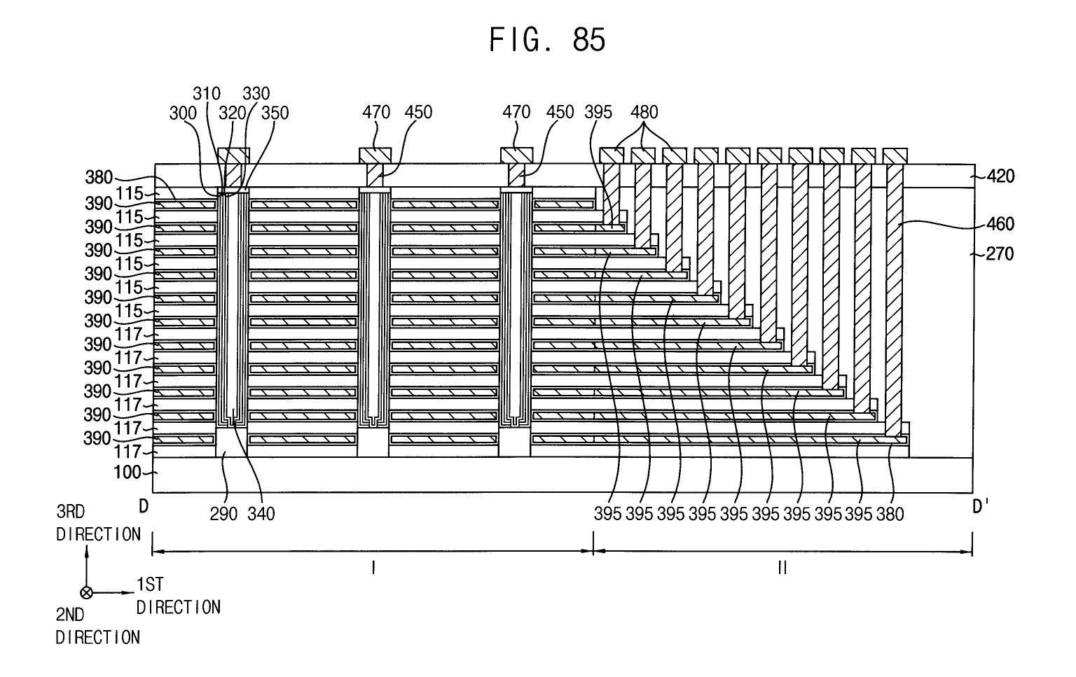

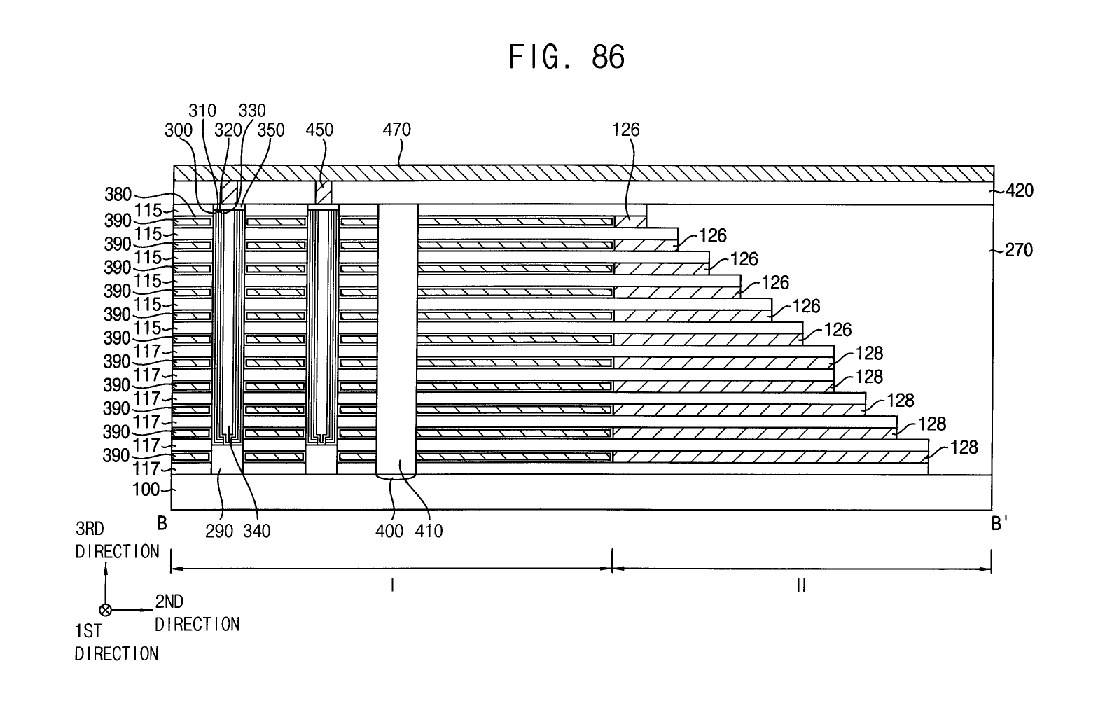

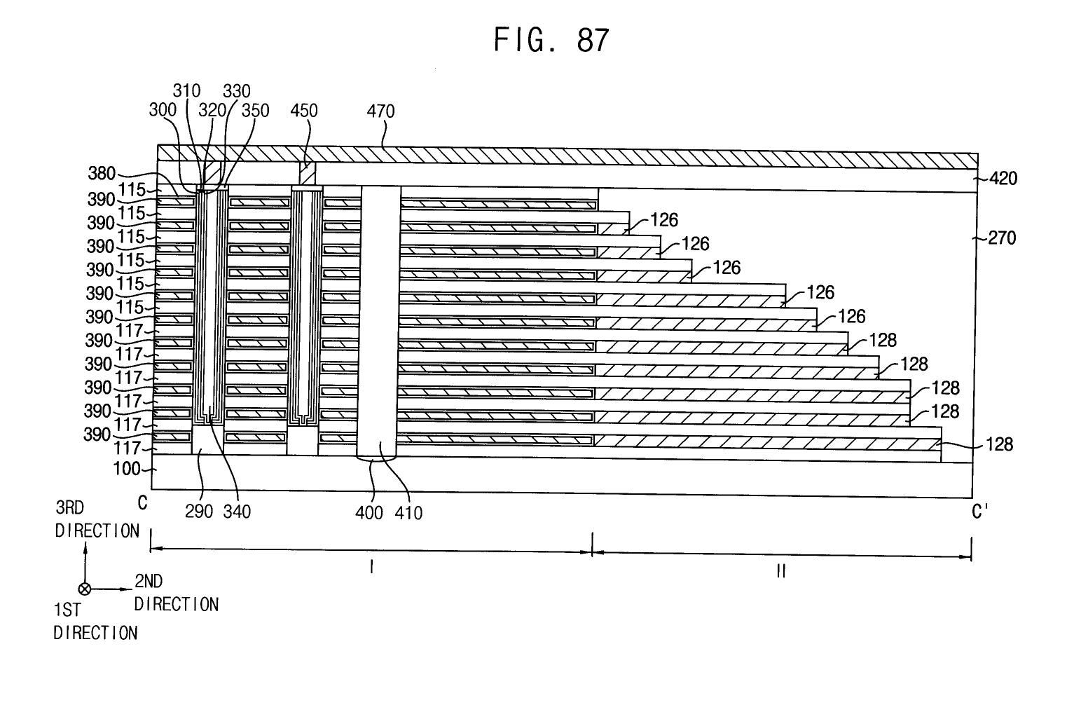

FIGS. 53 to 87 are plan views and cross-sectional views illustrating stages of a method of manufacturing a vertical non-volatile memory device in accordance with example embodiments. Particularly, FIGS. 53, 54, 61, 65, 69, 73, 77 and 81 are plan views, FIGS. 55-60, 62-64, 66-68, 70-72, 74-76, 78-80 and 82-87 are cross-sectional views. FIGS. 55, 58, 62, 66, 70, 74 and 78 are cross-sectional views cut along a line A-A′ extending in the first direction, FIGS. 56, 59, 63, 67, 71, 75, 79, 83 and 86 are cross-sectional views cut along a line B-B′ extending in the second direction, FIGS. 57, 60, 64, 68, 72, 76, 80, 84 and 87 are cross-sectional views cut along a line C-C′ extending in the second direction, and FIGS. 82 and 85 are cross-sectional views cut along a line D-D′ extending in the first direction. The method of manufacturing the vertical non-volatile memory device include processes which are substantially the same as or similar to those illustrated with reference to FIGS. 1 to 47, and thus detailed explanations thereof are omitted below.

Referring to FIG. 53, processes substantially the same as or similar to those illustrated with reference to FIGS. 1 to 5 may be performed.

That is, an insulation layer 110 and a sacrificial layer 120 (refer to FIG. 2) may be alternately and repeatedly formed on a substrate 100 having a first region I of a rectangular shape and a second region II of a rectangular ring shape surrounding the first region I, and a polish stop layer 130 (refer to FIG. 2) and an upper insulation layer 140 (refer to FIG. 2) may be sequentially formed on an uppermost one of the stacked insulation layers 110 and the sacrificial layers 120. The polish stop layer 130 and the upper insulation layer 140 may be defined as a reference layer.

A first photoresist pattern 155 may be formed on the reference layer. In example embodiments, the first photoresist pattern 155 may have a rectangular shape, which may be reduced at a given ratio from the rectangular shape of the first region I, in a top view, and partially cover the first region I. Thus, four sides of the rectangular shape of the first photoresist pattern 155 may be spaced apart from the four sides of the rectangular shape of the first region I, respectively, by substantially the same distance. A first pair of sides of the first photoresist pattern 155 may extend in the second direction, and a second pair of sides of the first photoresist pattern 155 may extend in the first direction and each side of the second pair of sides may include a first protrusion 502 extending in the second direction and partially covering a portion of the second region II adjacent to the first region I.

A area covered by the first photoresist pattern 155 in a top view may be defined as a first area.

The upper insulation layer 140 and the polish stop layer 130 may be etched using the first photoresist pattern 155 as an etching mask to form an upper insulation layer pattern 145 and a polish stop layer pattern 135, respectively. That is, the reference layer may be patterned to form a reference layer pattern including a polish stop layer pattern 135 and an upper insulation layer pattern 145 sequentially stacked. The reference layer pattern may have a shape corresponding to that of the first photoresist pattern 155, and thus may have a rectangular shape as a whole but include protrusions extending in the second direction.

The first photoresist pattern 155 may be removed by an ashing process and/or a stripping process.

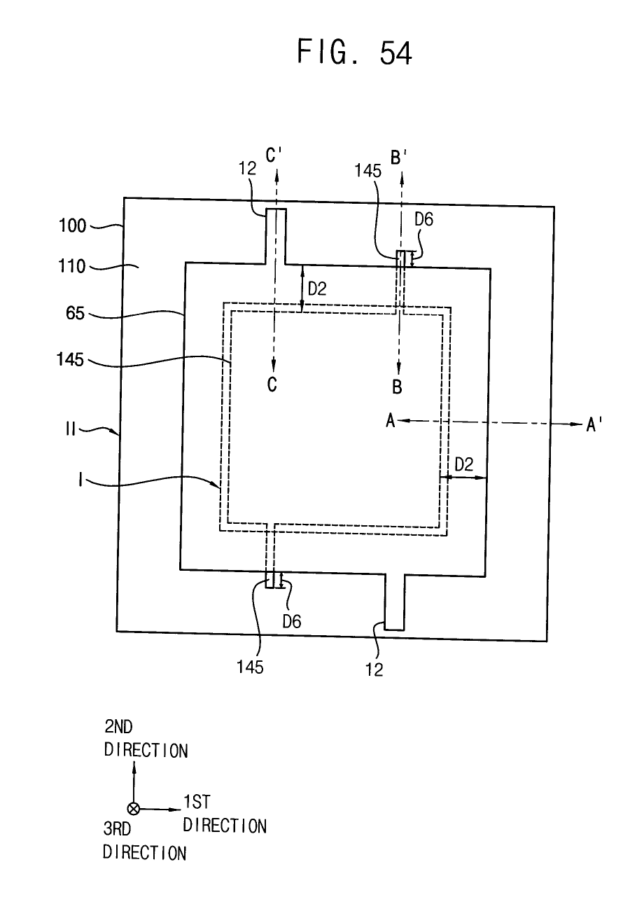

Referring to FIGS. 54 to 57, processes substantially the same as or similar to those illustrated with reference to FIGS. 6 to 10 may be performed.

That is, a preliminary second photoresist layer covering the reference layer pattern may be formed on the uppermost one of the insulation layers 110, and patterned to form a preliminary second photoresist pattern 65.

In example embodiments, the preliminary second photoresist pattern 65 may be formed to cover the reference layer pattern but to partially expose the protrusions. That is, the preliminary second photoresist pattern 65 may have a rectangular shape as a whole that may be larger than the reference layer pattern, however, the protrusions of the reference layer pattern may not be covered by the preliminary second photoresist pattern 65 but may be partially exposed. A first pair of sides of the rectangular shape of the preliminary second photoresist pattern 65 may extend in the second direction, and a second pair of sides of the rectangular shape of the preliminary second photoresist pattern 65 may extend in the first direction but each side of the second pair of sides may have a preliminary second protrusion 12 extending in the second direction.

A boundary of the protrusion of the reference layer pattern exposed by the preliminary second photoresist pattern 65, i.e., an end of the protrusion of the reference layer pattern may be spaced apart from a boundary of the preliminary second photoresist pattern 65 in the second direction by a sixth distance D6. A boundary of the reference layer pattern not exposed by the preliminary second photoresist pattern 65 may be spaced apart from the boundary of the preliminary second photoresist pattern 65 by a second distance D2. The preliminary second photoresist pattern 65 may cover almost an entire area of the reference layer pattern so that the second distance D2 may not be measured directly. That is, the second distance D2 may be calculated from the sixth distance D6 having a given relationship with the second distance D2.

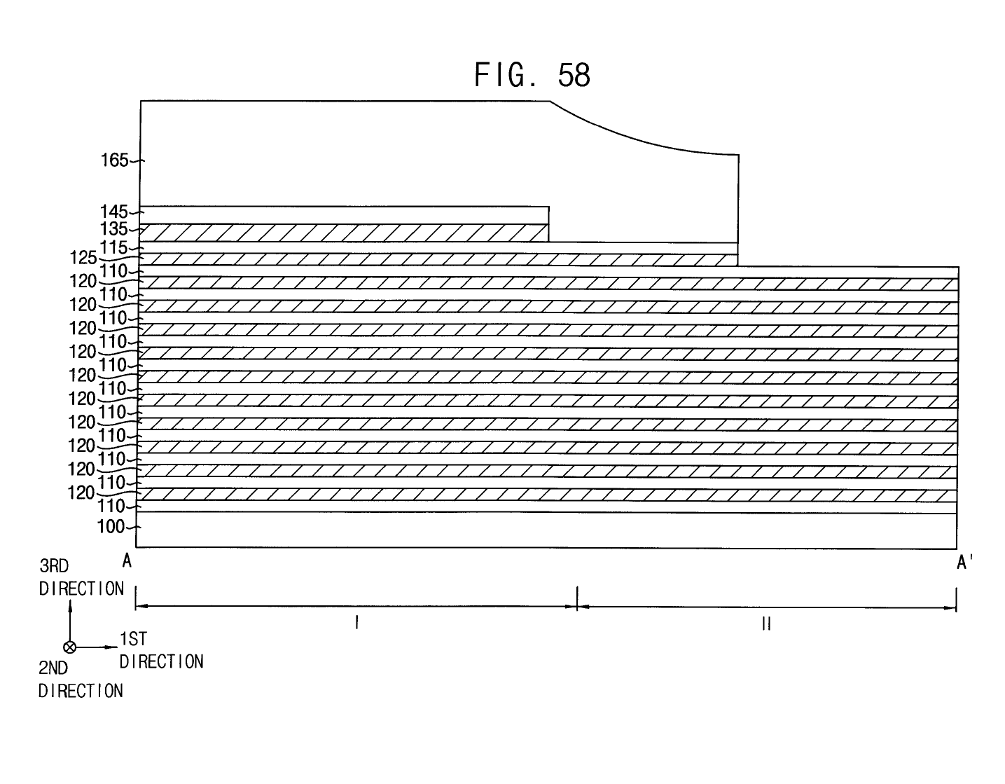

By the above method, whether the preliminary second photoresist pattern 65 having an area larger than that of the reference layer pattern is formed with a desired size and/or scale and/or a desired position with respect to the reference layer pattern may be confirmed, and if not, a second photoresist pattern 165 (refer to FIG. 58) with a desired properties with respect to the reference layer pattern may be formed by a method substantially the same as those illustrated with reference to FIGS. 9 and 10. However, when the preliminary second photoresist pattern 65 is formed with the desired properties with respect to the reference layer pattern, an etching process illustrated with reference to following FIGS. 58 to 60 may be directly performed using the preliminary second photoresist pattern 65.

As explained with reference to FIGS. 9 and 10, in the preliminary second photoresist pattern 65 having the preliminary second protrusion 12 and the second photoresist pattern 165 having the second protrusion 512 (refer to FIG. 56), the sixth distance D6 and the second distance D2 may be inverse proportional to each other.

A area covered by the second photoresist pattern 165 in a top view may be defined as a second area, which may cover the first area except for a protrusion thereof and have an area larger than that of the first area. Additionally, the second area may include protrusions extending in the second direction.

Referring to FIGS. 58 to 60, a process substantially the same as or similar to that illustrated with reference to FIGS. 11 and 12 may be performed.

That is, the uppermost one of the insulation layers 110 and an uppermost one of the sacrificial layers 120 therebeneath may be etched using the second photoresist pattern 165 as an etching mask to form a first insulation layer pattern 115 and a first sacrificial layer pattern 125, respectively. During the etching process, the exposed portion of the reference layer pattern by the second photoresist pattern 165 may be also etched.

Thus, a first level of first pattern stucture including a first sacrificial layer pattern 125 and a first insulation layer pattern 115 sequentially stacked may be formed. The first level of first pattern stucture may define a second upper step structure 562 at a second area at which the protrusion of the reference layer pattern is formed.

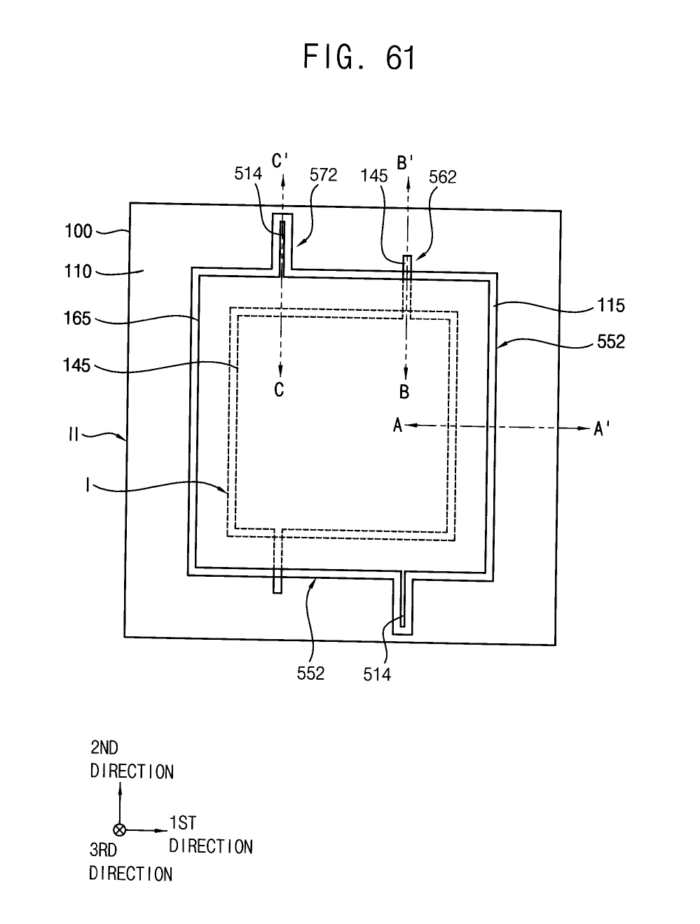

Referring to FIGS. 61, 62, 63 and 64, a process substantially the same as or similar to that illustrated with reference to FIGS. 6 to 18 may be performed.

That is, the second photoresist pattern 165 may be reduced by a trimming process to expose a portion of the first level of first pattern stucture, and the exposed portion of the first level of first pattern stucture, an uppermost one of the insulation layers 110 and an uppermost one of the sacrificial layers 120 therebeneath may be etched using the trimmed second photoresist pattern 165 as an etching mask.

Thus, a second level of first pattern stucture including a first sacrificial layer pattern 125 and a first insulation layer pattern 115 sequentially stacked may be formed beneath the first level of first pattern stucture. A third protrusion 514 having an area smaller than that of the second protrusion 512 may be formed at a third area at which the second protrusion 512 is formed by the trimming process. The second level of first pattern stucture together with the first level of first pattern stucture may define a second upper step structure 562 at the second area, may define a third upper step structure 572 at the third area, and may define a first upper step structure 552 at a first area that is the other area except for the second and third areas.

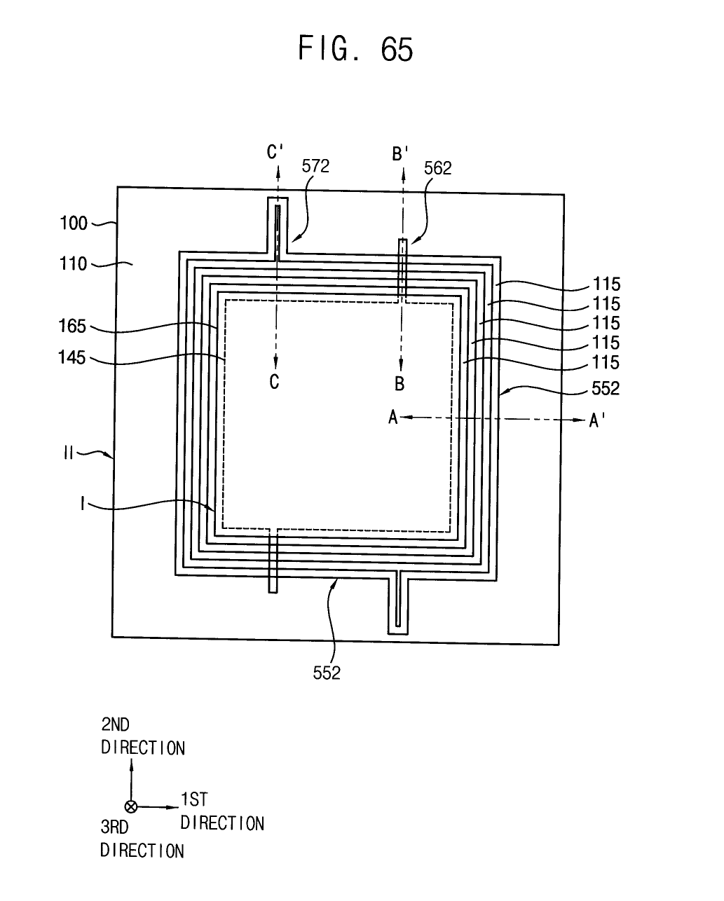

Referring to FIGS. 65, 66, 67 and 68, a process substantially the same as or similar to that illustrated with reference to FIGS. 16 to 18 may be performed.

That is, the trimming process may be performed plural times to reduce an area of the second photoresist pattern 165 with a given ratio, and an exposed portion of the first level of first pattern stucture, the second level of first pattern stucture, and an uppermost one of the insulation layers 110 and an uppermost one of the sacrificial layers 120 therebeneath may be etched using the trimmed second photoresist pattern 165 as an etching mask. Thus, a plurality of first pattern structures each of which may include a first sacrificial layer pattern 125 and a first insulation layer pattern 115 sequentially stacked may be formed under the second level of first pattern stucture. For example, four levels of first pattern structures, i.e., a third level of first pattern stucture, a fourth level of first pattern stucture, a fifth level of first pattern stucture and a sixth level of first pattern stucture may be sequentially formed, however, the number of the trimming process and the number of the level of first pattern stucture is not limited thereto.

Accordingly, a plurality of first pattern structures each of which may include one sacrificial layer pattern 125 and one insulation layer pattern 115 sequentially stacked may be formed at a plurality of levels. The third to sixth levels of first pattern structure together with the first and second levels of first pattern structure may define the first upper step structure 552 at the first area, the second upper structure 562 at the second area, and the third upper structure 572 at the third area.

In example embodiments, the first upper step structure may have a width that may gradually decrease at a constant first ratio from a bottom level to a top level.

The second photoresist pattern 165 may be removed to expose the first pattern structures.

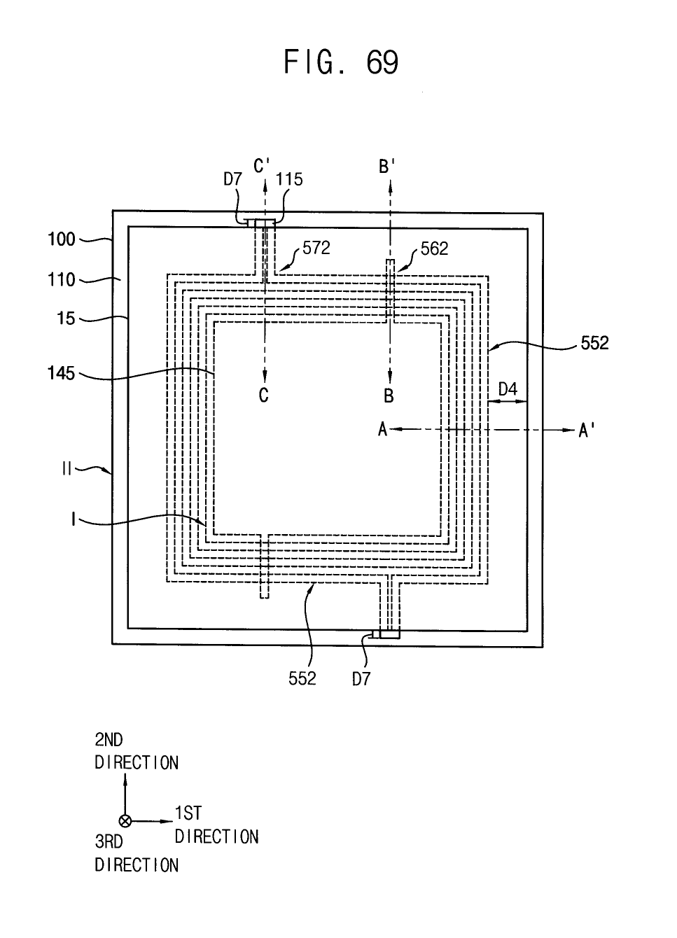

Referring to FIGS. 69, 70, 71 and 72, a process substantially the same as or similar to that illustrated with reference to FIGS. 19 to 22 may be performed.

That is, a preliminary third photoresist layer covering the exposed first pattern structures may be formed on an uppermost one of the insulation layers 110, and patterned to form a preliminary third photoresist pattern 15.

The preliminary third photoresist pattern 15 may be formed to cover the first pattern structures but to partially expose a peripheral portion of at least one of the first pattern structures. When the first pattern structures have a rectangular shape except for the second and third areas in a top view, the preliminary third photoresist pattern 15 may also have a rectangular shape that may be larger than the first pattern structures. However, the preliminary third photoresist pattern 15 may not cover the first pattern structures at the third area, but partially expose a protrusion of at least one of the first pattern structures, e.g., a protrusion of a lowermost one of the first pattern structures under the second and third protrusions 512 and 514.

A boundary of the protrusion, i.e., an end of the protrusion of the at least one of the first pattern structures, e.g., the lowermost level of first pattern stucture (the sixth level of first pattern stucture in FIGS. 69 to 72) exposed by the preliminary third photoresist pattern 15 may be spaced apart from a boundary of the preliminary third photoresist pattern 15 in the second direction by a seventh distance D7. A boundary of the at least one of the first pattern structures, e.g., the lowermost level of first pattern stucture (the sixth level of first pattern stucture in FIGS. 69 to 72) not exposed by the preliminary third photoresist pattern 15 may be spaced apart from the boundary of the preliminary third photoresist pattern 15 by a fourth distance D4. The preliminary third photoresist pattern 15 may cover almost an entire area of the first pattern structures so that the fourth distance D4 may not be measured directly, however, in example embodiments, the fourth distance D4 may be calculated from the seventh distance D7 having a given relationship with the fourth distance D4.

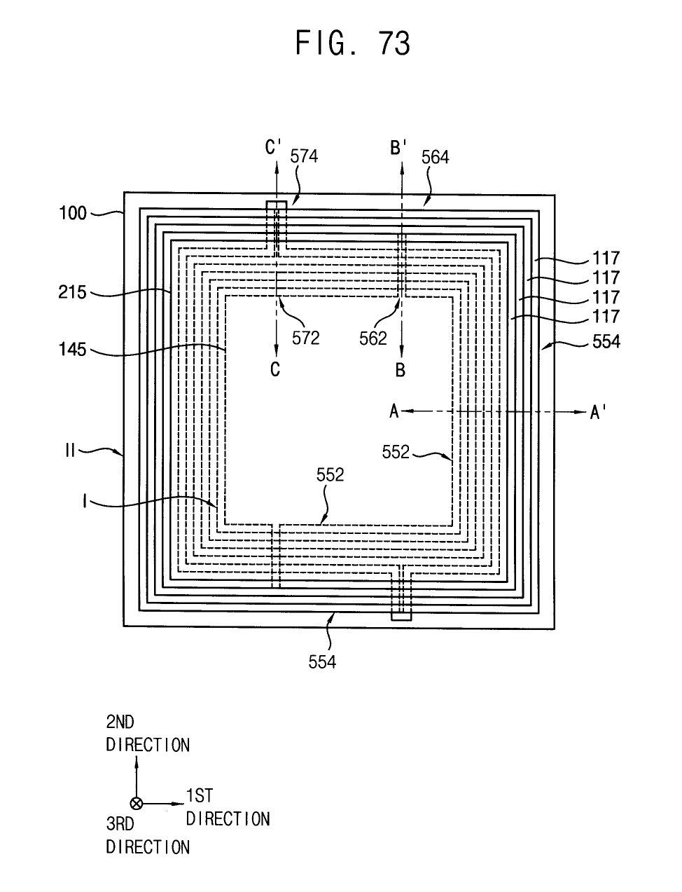

Accordingly, whether the preliminary third photoresist pattern 15 having an area larger than that of the first pattern structures is formed with a desired size and a desired position with respect to the first pattern structures may be confirmed, and if not, a third photoresist pattern 215 (refer to FIGS. 73 to 76) with a desired size and a desired position with respect to the first pattern structures may be formed by the method illustrated with reference to FIGS. 9 and 10. However, when the preliminary third photoresist pattern 15 is formed with the desired size and the desired position with respect to the first pattern structures, the method illustrated with reference to FIGS. 9 and 10 may not be performed, and an etching process illustrated with reference to following FIGS. 73 to 76 may be directly performed using the preliminary third photoresist pattern 15.

As illustrated with reference to FIGS. 9 and 10, the seventh distance D7 and the fourth distance D4 may be inverse proportional to each other.

A area covered by the third photoresist pattern 215 in a top view may be defined as a third area, which may cover the second area except for a peripheral portion of the second area, i.e., a portion of the protrusion, and have an area larger than that of the second area.

Referring to FIGS. 73, 74, 75 abd 76, processes substantially the same as or similar to those illustrated with reference to FIGS. 23 to 26 may be performed.

That is, the third photoresist pattern 215 may be reduced by at least one trimming process to expose a portion of the first pattern structures, and the exposed portion of the first pattern structures, an uppermost one of the insulation layers 110 and an uppermost one of the sacrificial layers 120 therebeneath may be etched using the trimmed third photoresist pattern 215 as an etching mask by an etching process.

Accordingly, a plurality of second pattern structures each of which may include one second sacrificial layer pattern 127 and one second insulation layer pattern 117 sequentially stacked may be formed at a plurality of levels. The second pattern structures may define a first lower step structure 554 at the first area, a second lower step structure 564 at the second area, and a third lower step structure 574 at the third area.

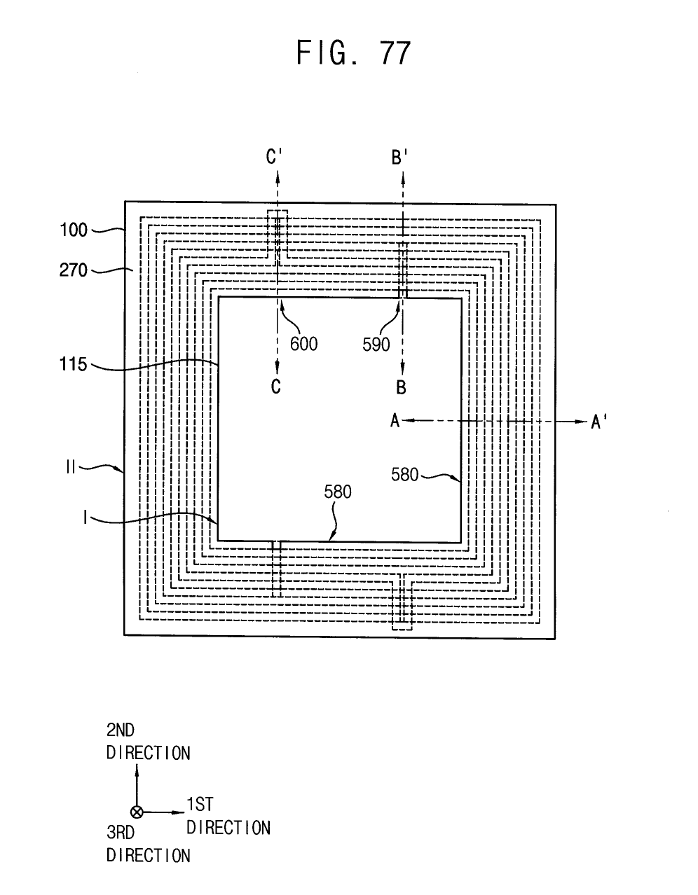

Referring to FIGS. 77, 78, 79 and 80, a process substantially the same as or similar to that illustrated with reference to FIGS. 27 to 30 may be performed.

That is, a first insulating interlayer may be formed on the substrate 100 to cover the first and second pattern structures and the reference layer pattern, and an upper portion of the first insulating interlayer may be planarized to form a first insulating interlayer pattern 270. By the planarization process, the polish stop layer pattern 135 and the upper insulation layer pattern 145 of the reference layer pattern together with the upper portion of the first insulating interlayer may be removed.

Accordingly, a first mold structure including the first and second pattern structures may be formed on the substrate 100, and the first insulating interlayer pattern 270 surrounding a sidewall of the first mold structure may be formed. The first mold structure may have a first step structure 580 including the first lower and upper step structures 554 and 552 sequentially stacked at the first area, a second step structure 590 including the second lower and upper step structures 564 and 562 sequentially stacked at the second area, and the third step structure 600 including the third lower and upper step structures 574 and 572 at the third area.

In example embodiments, portions of the first and second insulation layer patterns 115 and 117 and the first and second sacrificial layer patterns 125 and 127 defining the first step structure 580 may have a staircase shape with a width gradually decreasing at the constant first ratio from a bottom level to a top level when viewed from a lateral side. However, portions of the first and second insulation layer patterns 115 and 117 and the first and second sacrificial layer patterns 125 and 127 defining the second step structure 590 may have a staircase shape with a width that may not gradually decrease at a constant ratio from a bottom level to a top level when viewed from a lateral side. The width of the staircase shape of the portions of the first and second insulation layer patterns 115 and 117 and the first and second sacrificial layer patterns 125 and 127 defining the second step structure 590 may decrease at a second ratio that may be changed according to the level thereof. Further, portions of the first and second insulation layer patterns 115 and 117 and the first and second sacrificial layer patterns 125 and 127 defining the third step structure 600 may have a staircase shape of a width that may decrease at a third ratio that may be changed according to the level thereof.

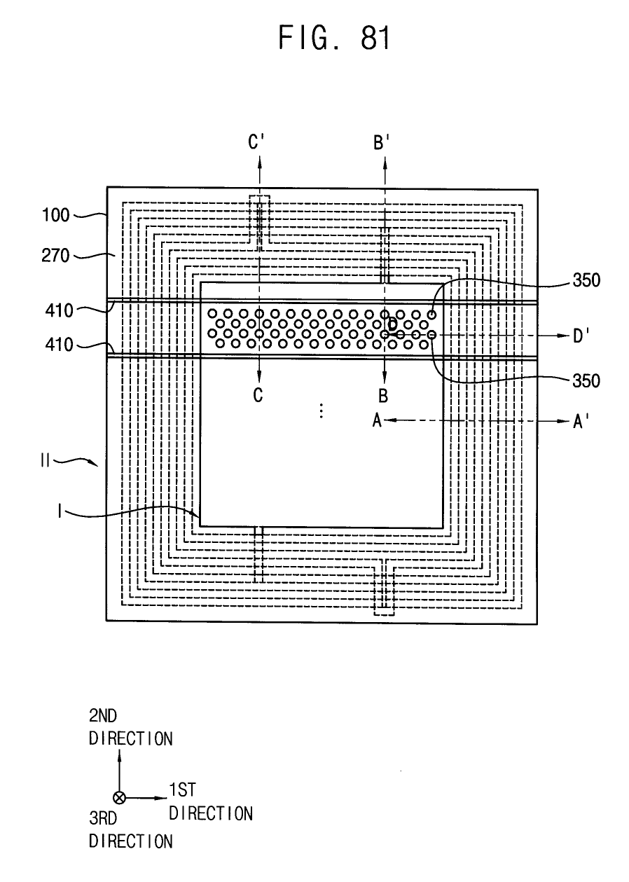

Referring to FIGS. 81, 82, 83 and 84, processes substantially the same as or similar to those illustrated with reference to FIGS. 31 to 42 may be performed.

That is, a plurality of holes 280 may be formed through the first and second insulation layer patterns 115 and 117 and the first and second sacrificial layer patterns 125 and 127 in the first region I to expose a top surface of the substrate 100. In example embodiments, the plurality of holes 280 may be formed in the first and second directions

A semiconductor pattern 290 may be formed to partially fill each hole 280, and a first blocking layer pattern 300, a charge storage layer pattern 310, a tunnel insulation layer pattern 320, a channel 330 and a first filling layer pattern 340 may be sequentially stacked on the semiconductor pattern 290 in each hole 280. Each of the first blocking layer pattern 300, the charge storage layer pattern 310 and the tunnel insulation layer pattern 320 may have a cup shape of which a central bottom is opened, the channel 330 may have a cup shape, and the first filling layer pattern 340 may have a pillar shape.

An upper portion of a first structure including the first filling layer pattern 340, the channel 330, the tunnel insulation layer pattern 320, the charge storage layer pattern 310 and the first blocking layer pattern 300 sequentially stacked in each hole 280 may be removed to form a trench (not shown), and a capping layer pattern 350 filling the trench may be formed on the first structure in each hole 280. The first structure, the semiconductor pattern 290 and the capping layer pattern 350 in each hole 280 may form a second structure.

A plurality of first openings 360 may be formed through the first and second insulation layer patterns 115 and 117 and the first and second sacrificial layer patterns 125 and 127 to expose a top surface of the substrate 100, and the first and second sacrificial layer patterns 125 and 127 exposed by the first openings 360 may be removed to form gaps 370 between the first and second insulation layer patterns 115 and 117 at adjacent levels. Portions of outer sidewalls of the first blocking layer patterns 300 and sidewalls of the semiconductor patterns 290 may be exposed by the gaps 370. Portions of the first and second sacrificial layer patterns 125 and 127 that may be formed in the second region II before and after the first region I in the second direction may not be removed by the wet etching process but may remain, which may be referred to as first and second insulation pads 126 and 128, respectively.

A second blocking layer may be formed on the exposed portions of the outer sidewalls of the first blocking layer patterns 300, the exposed portions of the sidewalls of the semiconductor patterns 290, inner walls of the gaps 370, surfaces of the first and second insulation layer patterns 115 and 117, the exposed top surface of the substrate 100 and a top surface of the capping layer pattern 350, and a conductive layer may be formed on the second blocking layer to sufficiently fill remaining portions of the gaps 370. The conductive layer may be partially removed to form a conductive structure 390 in each gap 370.

In example embodiments, each conductive structure 390 may be formed to extend in the first direction in the first region I, and may further extend to a portion of the second region II adjacent to the first region I in the first direction. Hereinafter, a portion of each conductive structure 390 in the first region I may be referred to as a gate electrode 390, and a portion of each conductive structure 390 in the second region II may be referred to as a conductive pad 395.

In example embodiments, the gate electrodes 390 may include a ground select line (GSL), a word line and a string select line (SSL) sequentially stacked on the substrate 100. When the conductive layer is partially removed, portions of the second blocking layer on surfaces of the first and second insulation layer patterns 115 and 117, on the top surface of the substrate 100, on the top surface of the capping layer patterns 350 and on the top surface of the first insulating interlayer pattern 270 may also be removed to form a second blocking layer pattern 380 surrounding sidewalls of the gate electrode 390 and the conductive pad 395 in each gap 370. The first and second blocking layer patterns 300 and 380 may define a blocking layer pattern structure.

As the conductive layer and the second blocking layer are partially removed, the first opening 360 exposing a top surface of the substrate 100 and extending in the first direction may be formed again, and impurities may be implanted into the exposed top surface of the substrate 100 to form an impurity region 400. A second filling layer pattern 410 may be formed to fill each of the first openings 360.

Referring to FIGS. 85, 86 and 87, processes substantially the same as or similar to those illustrated with reference to FIGS. 43 to 47 may be performed.

That is, after forming a second insulating interlayer 420 on the uppermost one of the first insulation layer patterns 115, the capping layer patterns 350, the first insulating interlayer pattern 270 and the second filling layer patterns 410, the second insulating interlayer 420 may be partially removed to form second openings 430 exposing top surfaces of the capping layer patterns 350, respectively, and the second insulating interlayer 420, the first insulating interlayer pattern 270, the first and second insulation layer patterns 115 and 117 and the second blocking layer pattern 380 may be partially removed to form third openings 440 exposing top surfaces of the conductive pads 395, respectively.

A plurality of bit line contacts 450 filling the second openings 430 may be formed on the capping layer patterns 350, respectively, and a plurality of first contact plugs 460 filling the third openings 440 may be formed on the conductive pads 395.

A bit line 470 electrically connected to the bit line contact 450 and a first wiring 480 electrically connected to the first contact plug 460 may be formed to complete the vertical non-volatile memory device.

As described above, in the method of manufacturing the vertical non-volatile memory device, in order to form a mold structure of a staircase shape of which a width may gradually decrease from a bottom level to a top level, after forming a reference layer pattern, a photoresist pattern serving as an etching mask for etching insulation layers and sacrificial layers may be formed to have an area greater than that of the reference layer pattern and partially expose a protrusion of the reference layer pattern. By measuring a distance between an end of the exposed protrusion of the reference layer pattern and a boundary of the photoresist pattern, whether the photoresist pattern is formed to have a desired size with respect to the reference layer pattern may be confirmed.

In the method illustrated with reference to FIGS. 53 to 87, second and third photoresist patterns are used for etching the insulation layers and the sacrificial layers in addition to a first photoresist pattern for etching a reference layer. However, the numbers of the photoresist patterns is not limited thereto, and one or a plurality of photoresist patterns may be used for etching the insulation layers and the sacrificial layers in consideration of the number of gate electrodes and/or the number of trimming processes performed. The second photoresist pattern relatively formed in advance may be formed to include a protrusion like the reference layer pattern, and thus a second area covered by the second photoresist pattern may also include a protrusion. The third photoresist pattern relatively formed subsequently may have an area greater than that of the second area and cover the second area except for the protrusion. By measuring a distance between an end of the protrusion of the second area not covered by the third area and a boundary of the third area, a determination can be made as to whether the third photoresist pattern is formed to have a desired size with respect to the second photoresist pattern.

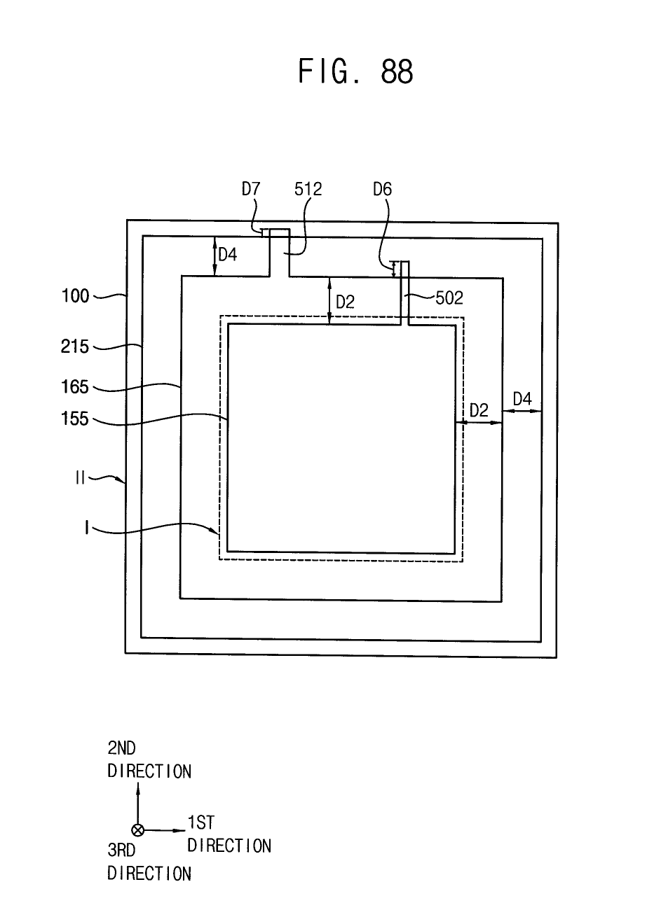

FIGS. 88, 89, 90 and 91 are plan views illustrating first, second and third photoresist patterns used for manufacturing a vertical non-volatile memory device in accordance with example embodiments. The first, second and third photoresist patterns may have a rectangular shape as a whole in a top view, like the first, second and third photoresist patterns 155, 165 and 215 illustrated with reference to FIGS. 53 to 87. However, the first, second and third photoresist patterns of FIGS. 88 to 91 may have different number or position of the protrusion. Hereinafter, only the differences of the first, second and third photoresist patterns of FIGS. 88 to 91 in comparison with those of FIGS. 53 to 87 will be illustrated.

Referring to FIG. 88, the first photoresist pattern 155 may include a first pair of boundaries that may be opposite to each other in the first direction and extend in the second direction, and a second pair of boundaries that may be opposite to each other in the second direction and extend in the first direction, and the first protrusion 502 extending in the second direction may be formed only in one boundary of the second pair of boundaries. An end of the first protrusion 502 of the first photoresist pattern 155 may be exposed by the second photoresist pattern 165. Additionally, the second photoresist pattern 165 may include first and second pairs of boundaries, and the second protrusion 512 extending in the second direction may be formed only in one boundary of the second pair of boundaries. An end of the second protrusion 512 of the second photoresist pattern 165 may be exposed by the third photoresist pattern 215. The third photoresist pattern 215 may have a rectangular shape in a top view.

Even though the first and second protrusions 502 and 512 may be formed only in one boundary of the second pair of boundaries of each of the first and second photoresist patterns 155 and 165, whether the second and third photoresist patterns 165 and 215 are formed to have desired sizes may be confirmed by measuring sizes of the first and second protrusions 502 and 512 exposed by the second and third photoresist patterns 165 and 215, respectively.

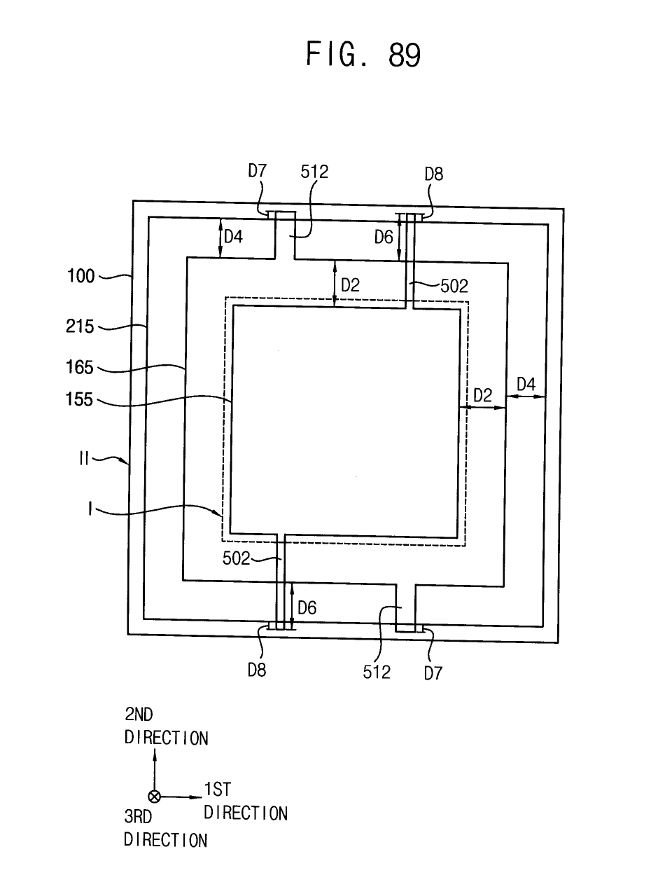

Referring to FIG. 89, the first photoresist pattern 155 may include first and second pairs of boundaries, and the first protrusion 502 having a long length in the second direction so that may be partially exposed not only by the second photoresist pattern 165 but also by the third photoresist pattern 215 may be formed in the second pair of boundaries.

As the first protrusion 502 may be formed to have a long length, whether the third photoresist pattern 215 is formed to have a desired size may be confirmed not only by a seventh distance D7 between an end of the second protrusion 512 of the second photoresist pattern 165 not covered by the third photoresist pattern 215 and a boundary of the third photoresist pattern 215 in the second direction, but also by an eighth distance D8 between an end of the first protrusion 502 of the first photoresist pattern 155 not covered by the third photoresist pattern 215 and a boundary of the third photoresist pattern 215 in the second direction.

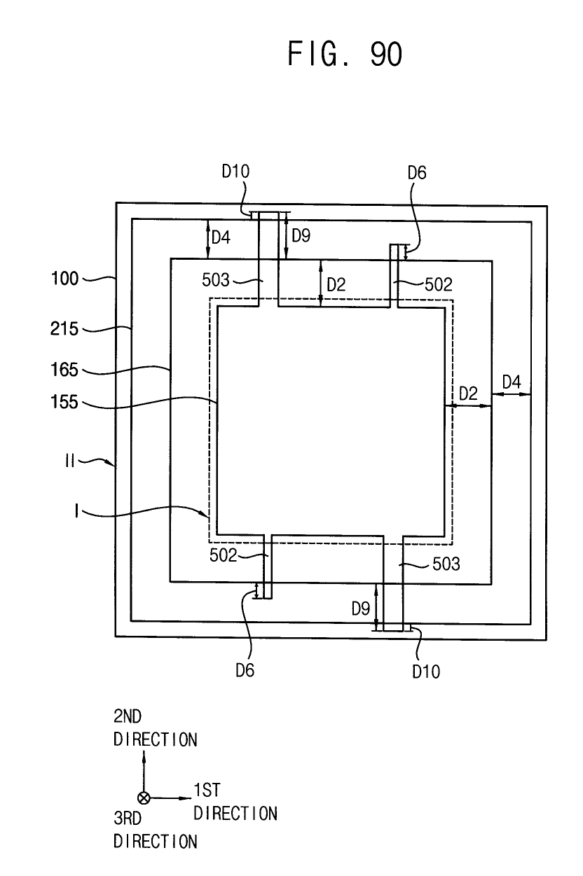

Referring to FIG. 90, the first photoresist pattern 155 may include first and second pairs of boundaries, and the first protrusion 502 and a fourth protrusion 503 may be formed in the second pair of boundaries. The first protrusion 502 may extend in the second direction, and an end of the first protrusion 502 may not be covered by the second photoresist pattern 165. The fourth protrusion 503 may extend in the second direction, and an end of the fourth protrusion 503 may not be covered by the second and third photoresist patterns 165 and 215. Each of the second and third photoresist patterns 165 and 215 may have a rectangular shape in a top view.

Thus, whether the second photoresist pattern 165 is formed to have a desired size may be confirmed by a sixth distance D6 between the end of the first protrusion 502 not covered by the second photoresist pattern 165 and a boundary of the second photoresist pattern 165 or by a ninth distance D9 between the end of the fourth protrusion 503 not covered by the second photoresist pattern 165 and a boundary of the second photoresist pattern 165. Additionally, whether the third photoresist pattern 215 is formed to have a desired size may be confirmed by a tenth distance D10 between the end of the fourth protrusion 503 not covered by the third photoresist pattern 215 and a boundary of the third photoresist pattern 215.

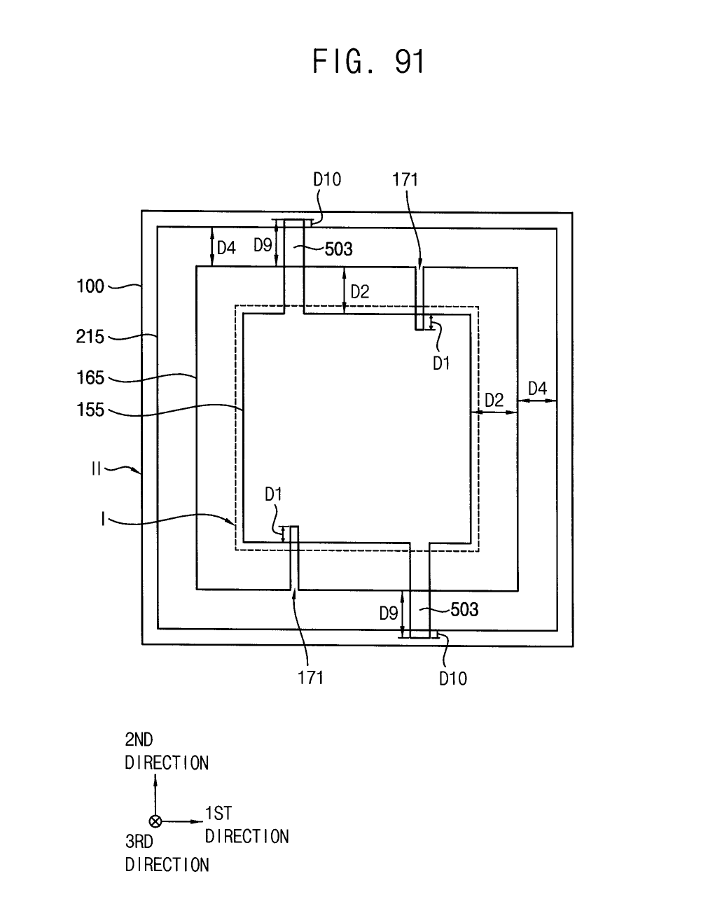

Referring to FIG. 91, the first photoresist pattern 155 may have first and second pairs of boundaries, and the fourth protrusion 503 may be formed in the second pair of boundaries. The fourth protrusion 503 may extend in the second direction, and an end of the fourth protrusion 503 may not be covered by the second and third photoresist patterns 165 and 215. The second photoresist pattern 165 may have first and second pairs of boundaries, and the first recess 171 may be formed in the second pair of boundaries. The first recess 171 may extend in the second direction, and may partially expose a peripheral portion of the first photoresist pattern 155. The third photoresist pattern 215 may have a rectangular shape in a top view.

Thus, whether the second photoresist pattern 165 is formed to have a desired size may be confirmed by a first distance D1 between a boundary of the peripheral portion of the first photoresist pattern 155 exposed by the first recess 171 and a boundary of the second photoresist pattern 165 or by a ninth distance D9 between the end of the fourth protrusion 503 of the first photoresist pattern 155 and a boundary of the second photoresist pattern 165. Additionally, whether the third photoresist pattern 215 is formed to have a desired size may be confirmed by a tenth distance D10 between the end of the fourth protrusion 503 of the first photoresist pattern 155 and a boundary of the third photoresist pattern 215.

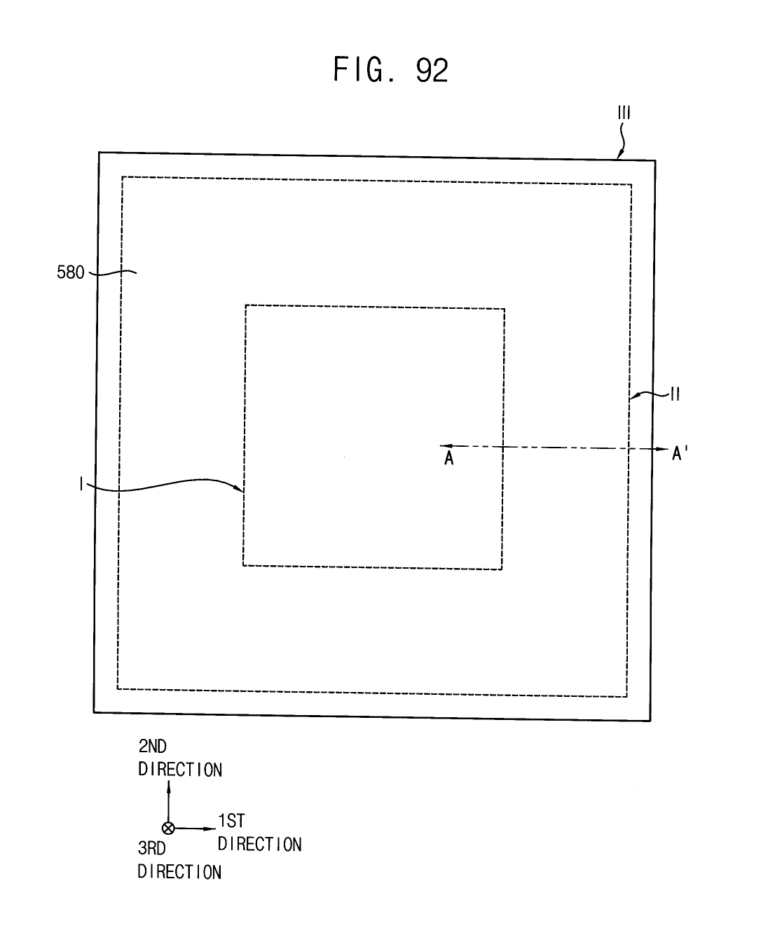

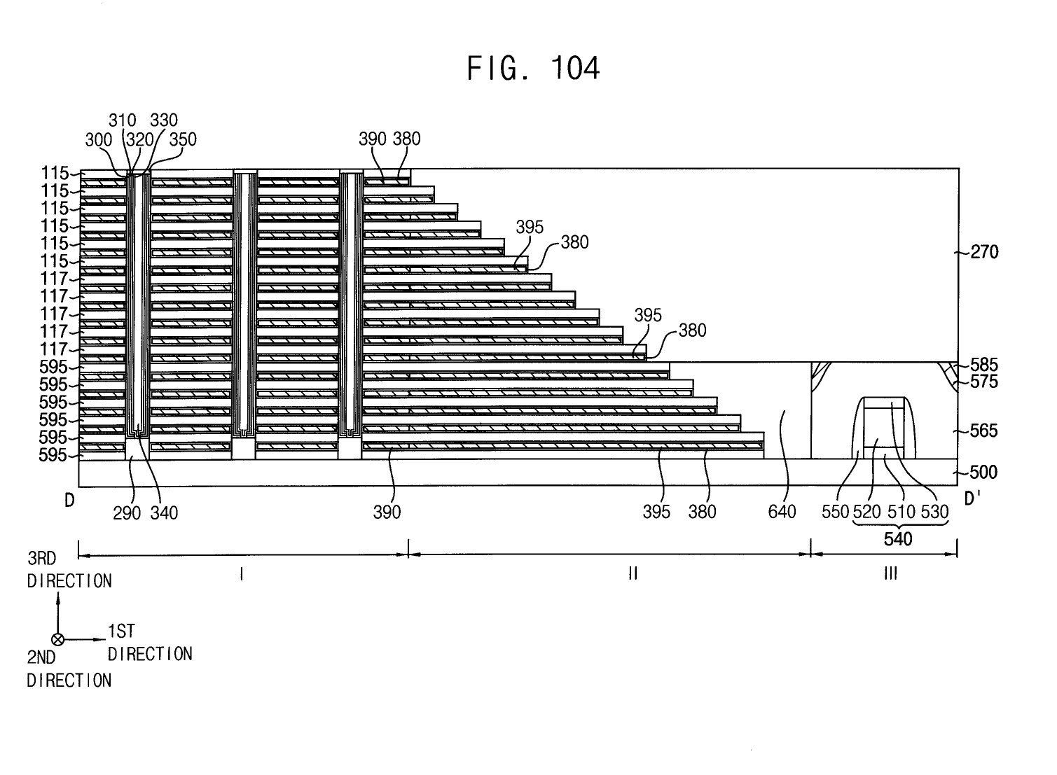

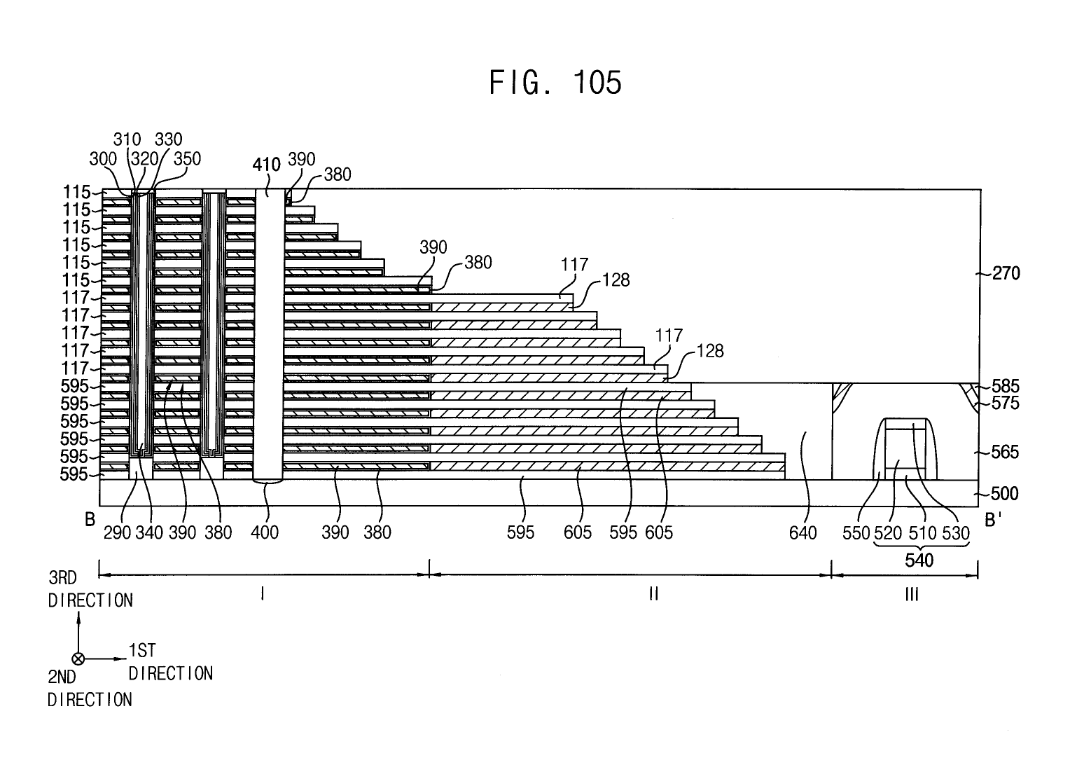

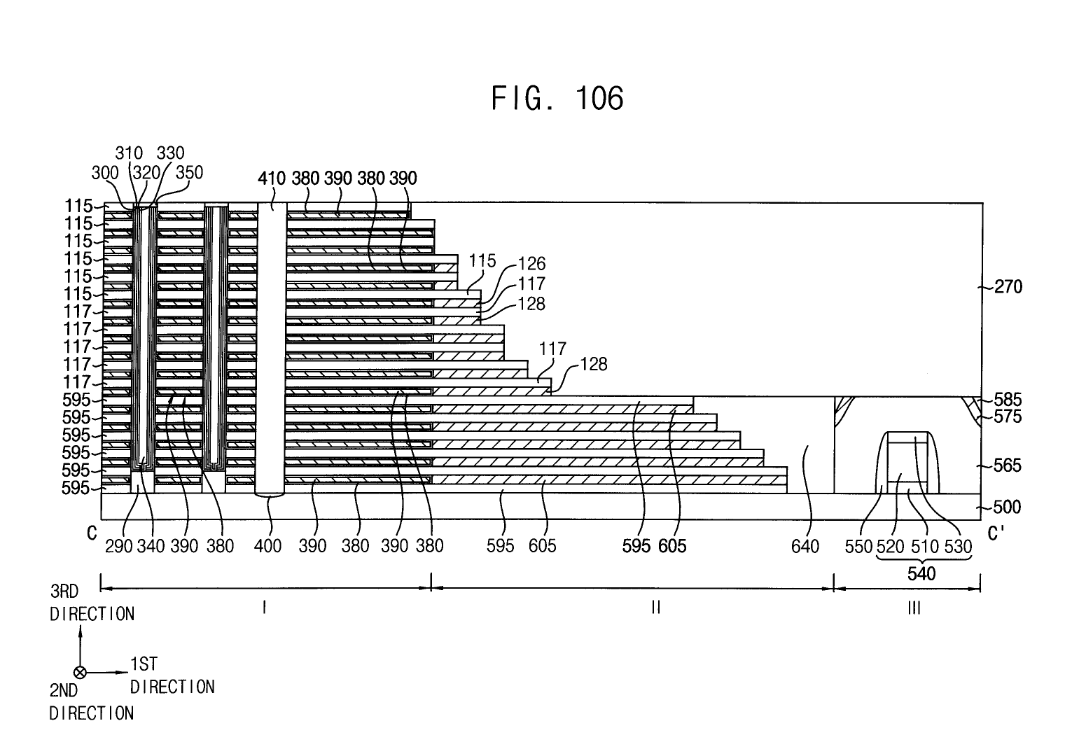

FIGS. 92 to 106 are plan views and cross-sectional views illustrating stages of a method of manufacturing a vertical non-volatile memory device in accordance with example embodiments. Particularly, FIGS. 92, 97, 99, 101 and 103 are plan views, FIGS. 93-96, 98, 100, 102 and 104-106 are cross-sectional views. FIGS. 93-96, 98, 100 and 102 are cross-sectional views cut along a line A-A′ extending in the first direction, FIG. 105 is a cross-sectional view cut along a line B-B′ extending in the second direction, FIG. 106 is a cross-sectional view cut along a line C-C′ extending in the second direction, and FIG. 104 is a cross-sectional view cut along a line D-D′ extending in the first direction. The method of manufacturing the vertical non-volatile memory device may include processes substantially the same as or similar to those illustrated with reference to FIGS. 1 to 47, and thus detailed explanations thereon are omitted below.

Referring to FIG. 92, circuit devices may be formed on a substrate 500 including first, second and third regions I, II and III. In example embodiments, the circuit devices may be formed in the third region III on the substrate 500.

In example embodiments, the first region I may serve as a cell array region in which memory cells including channels and gate electrodes may be formed, the second region II may serve as a connection region in which pads extending from the gate electrodes may be formed, and the third region III may serve as a peripheral circuit region in which the circuit devices for driving the memory cells may be formed. The first and second regions I and II may define a cell region.

In example embodiments, the first region I may have a rectangular shape in a top view. The rectangular shape may include two pairs of sides, and a first pair of opposite sides may extend in the second direction and a second pair of opposite sides may extend in the first direction. The second region II may have a rectangular ring shape surrounding the first region I in a top view, and the third region III may have a rectangular ring shape surrounding the second region II in a top view. Alternatively, the third region III may surround only neighboring two sides of the second region II.

For example, a gate structure 540 as the circuit devices may be formed in the third region III. In example embodiments, the gate structure 540 may include a gate insulation layer 510, a second gate electrode 520 and a gate mask 530 sequentially stacked on the substrate 500, and a gate spacer 550 may be formed on a sidewall of the gate structure 540. Impurity regions (not shown) may be further formed at upper portions of the substrate 500 adjacent to the gate structure 540. One or a plurality of gate structures 540 may be formed.

A first lower insulating interlayer 560 may be formed on the substrate 500 in the first, second and third regions I, II and III to cover the gate structure 540 and the gate spacer 550, and a first polish stop layer 570 and a second lower insulating interlayer 580 may be formed on the first lower insulating interlayer 560.

The gate structure 540 may be formed in the third region III on the substrate 500, and thus the first lower insulating interlayer 560 may be formed to have a height that may be higher in the third region III than in the first and second regions I and II. In example embodiments, the first and second insulating interlayers 560 and 580 may be formed to include, e.g., silicon oxide, and the first polish stop layer 570 may be formed to include, e.g., silicon nitride.

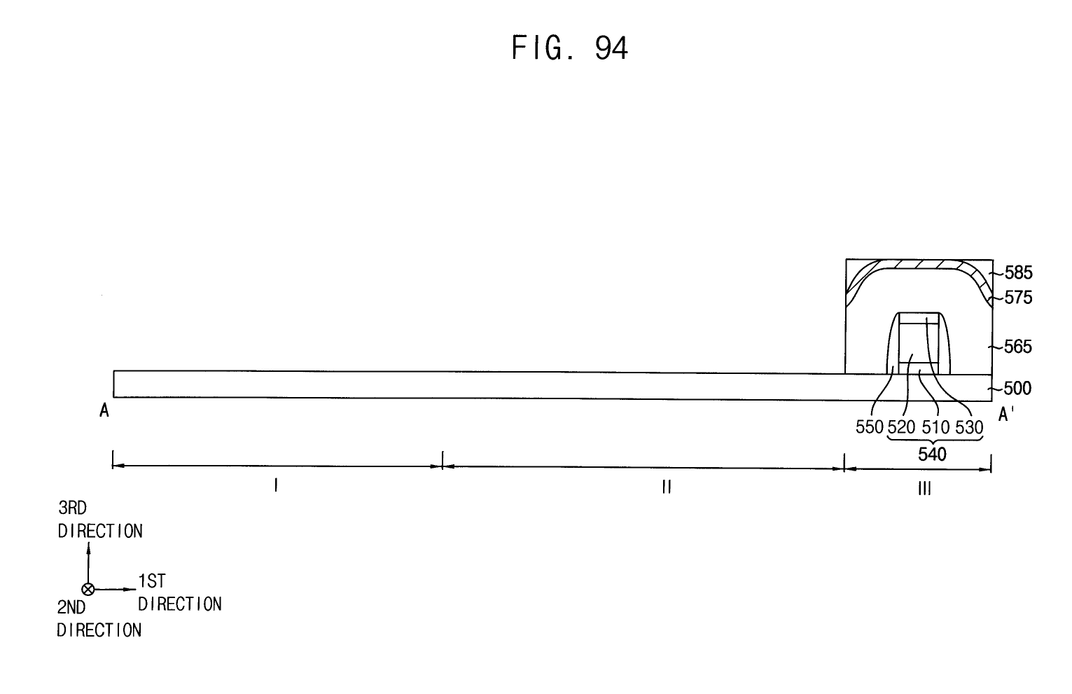

Referring to FIG. 94, an upper portion of the second lower insulating interlayer 580 may be planarized until a top surface of the first polish stop layer 570 may be exposed, and the second lower insulating interlayer 580, the first polish stop layer 570 and the first lower insulating interlayer 560 may be sequentially etched using a photoresist pattern (not shown) covering the third region III of the substrate 500 as an etching mask.

Thus, a first lower insulating interlayer pattern 565, a first polish stop layer pattern 575 and a second lower insulating interlayer pattern 585 covering the gate structure 540 and the gate spacer 550 may remain in the third region III, and a top surface of the substrate 500 may be exposed in the first and second regions I and II.

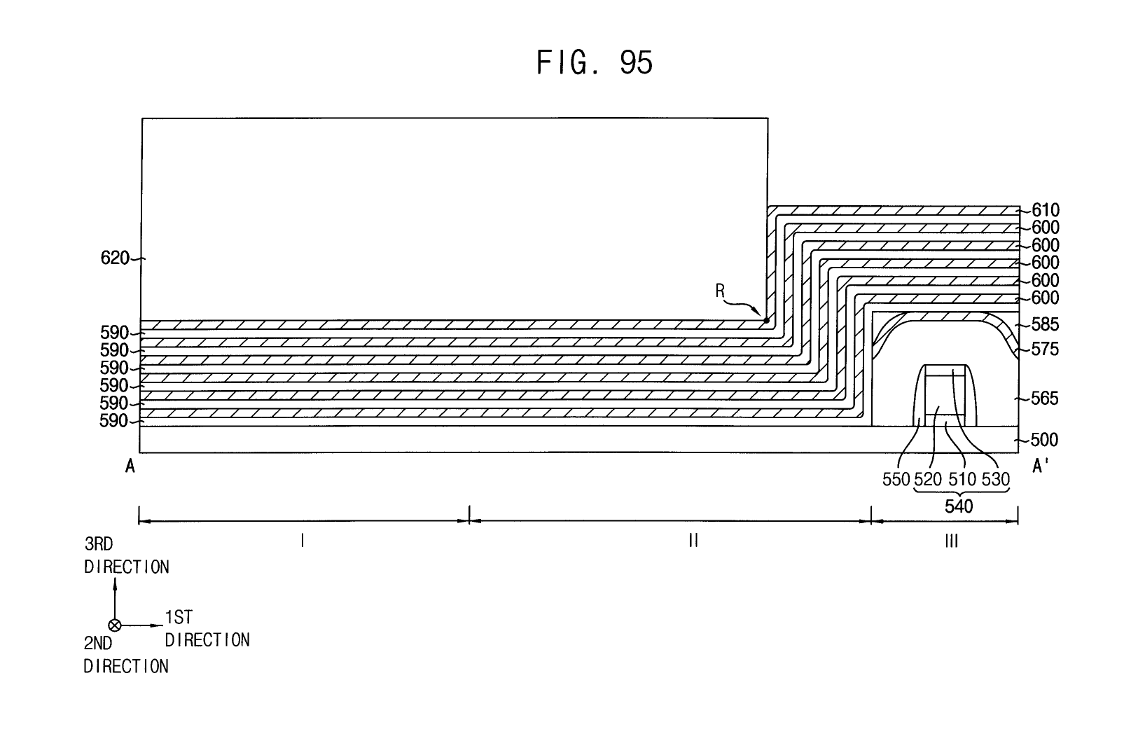

Referring to FIG. 95, a lower insulation layer 590 and a lower sacrificial layer 600 may be alternately and repeatedly formed on the substrate 500, the first lower insulating interlayer pattern 565, the first polish stop layer pattern 575 and the second lower insulating interlayer pattern 585, and a second polish stop layer 610 may be formed on an uppermost one of the lower insulation layers 590.

In example embodiments, a top surface of the second polish stop layer 610 in the first region I may be formed to be substantially coplanar with a top surface of the first polish stop layer pattern 575 in the third region III. FIG. 95 illustratively shows six levels of lower insulation layers 590 and five levels of lower sacrificial layers 600. However, the numbers of the lower insulation layers 590 and the lower sacrificial layers 600 is not limited thereto.

A lower photoresist pattern 620 covering the first region I and a portion of the second region II may be formed on the second polish stop layer 610. In example embodiments, the lower photoresist pattern 620 may be formed to have a boundary that may match a reference point R at which the second polish stop layer 610 may be bent.

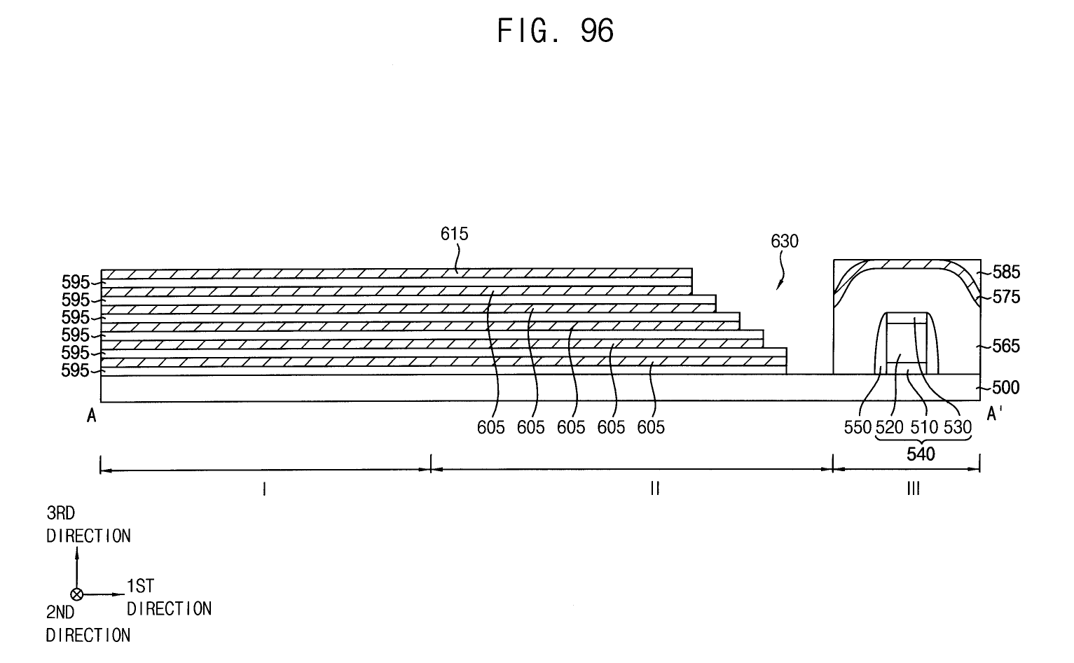

Referring to FIG. 96, the lower photoresist pattern 620 may be reduced by a trimming process, and the second polish stop layer 610, the lower insulation layers 590 and the lower sacrificial layers 600 may be patterned using the trimmed lower photoresist pattern 620 as an etching mask to form a second polish stop layer pattern 615, lower insulation layer patterns 595 and lower sacrificial layer patterns 605, respectively. Thus, a second mold structure 630 including the lower insulation layer patterns 595, the lower sacrificial layer patterns 605 and the second polish stop layer patterns 615 may be formed in the first and second regions I and II of the substrate 500. The second mold structure 630 may have a staircase shape of which a width may gradually decrease from a bottom level to a top level.

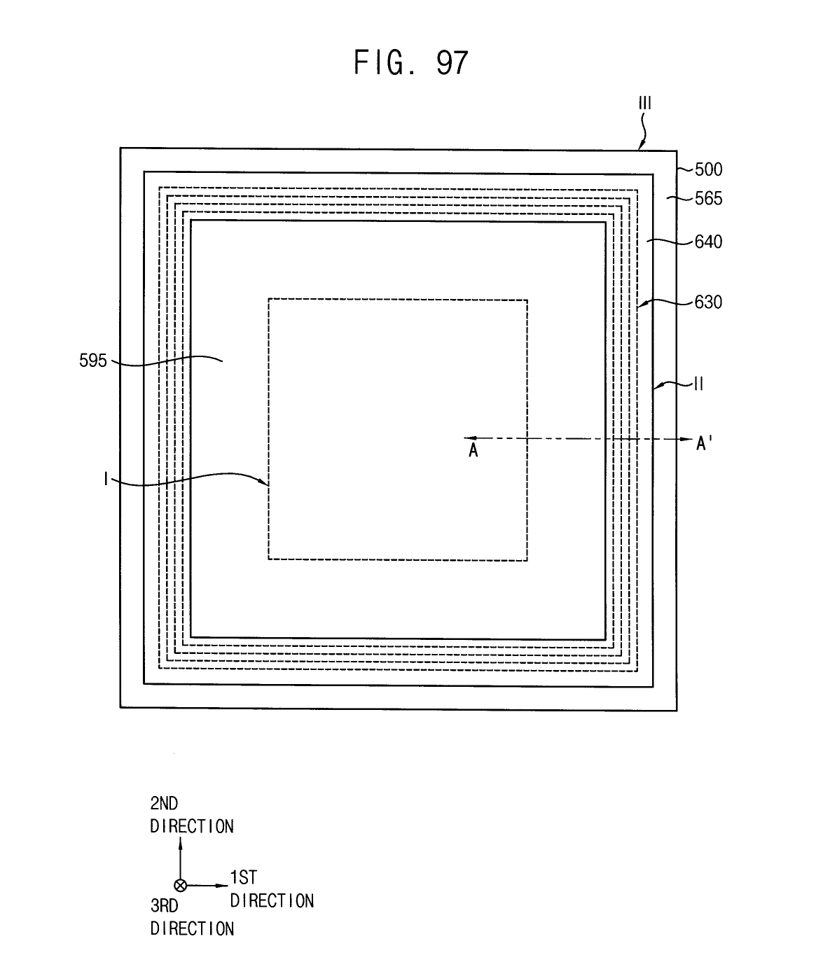

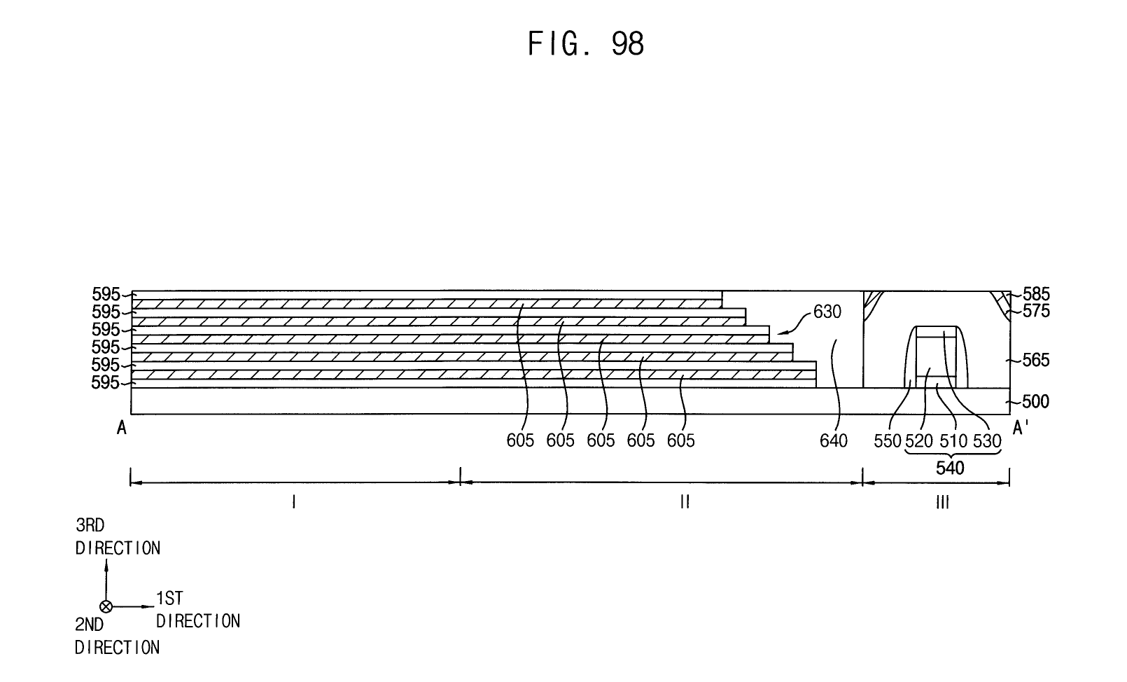

Referring to FIGS. 97 and 98, a third lower insulating interlayer may be formed on the substrate 500 on which the second mold structure 630 is formed, and an upper portion of the third lower insulating interlayer may be planarized until the first and second polish stop layer patterns 575 and 615 may be exposed to form a third lower insulating interlayer pattern 640 on the substrate 500. The third lower insulating interlayer may be formed to include an oxide, e.g., silicon oxide.

The first and second polish stop layer patterns 575 and 615 may be removed. Thus, the second mold structure 630 in the first and second regions I and II on the substrate 500 may include lower insulation layer patterns 595 and lower sacrificial layer patterns 605 alternately stacked, and a top surface of the first lower insulating interlayer pattern 565 may be exposed in the third region III on the substrate 500.

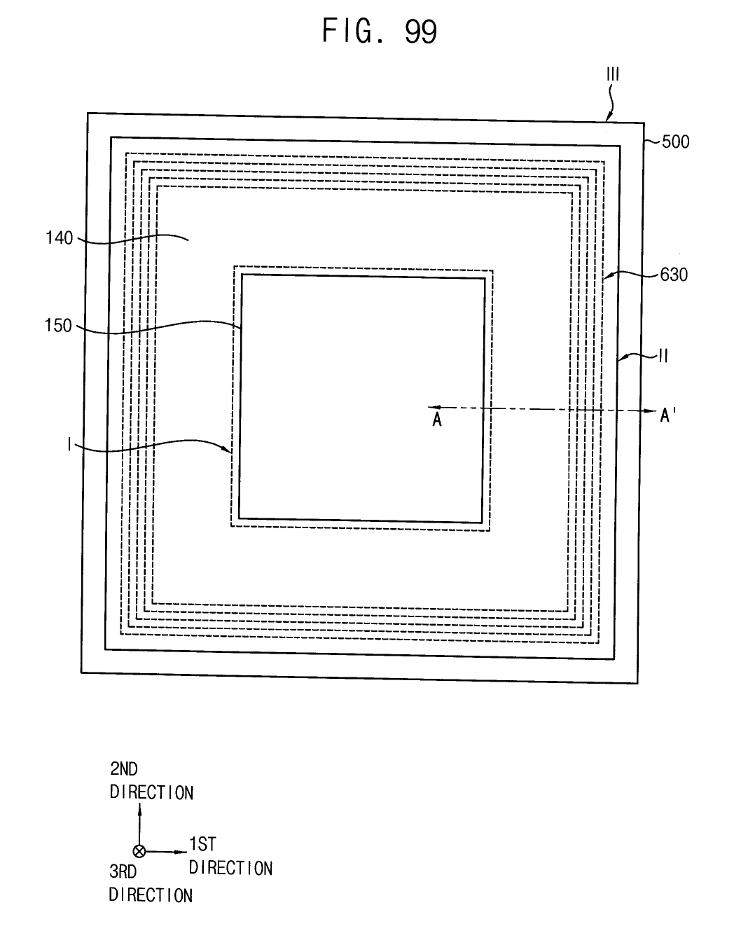

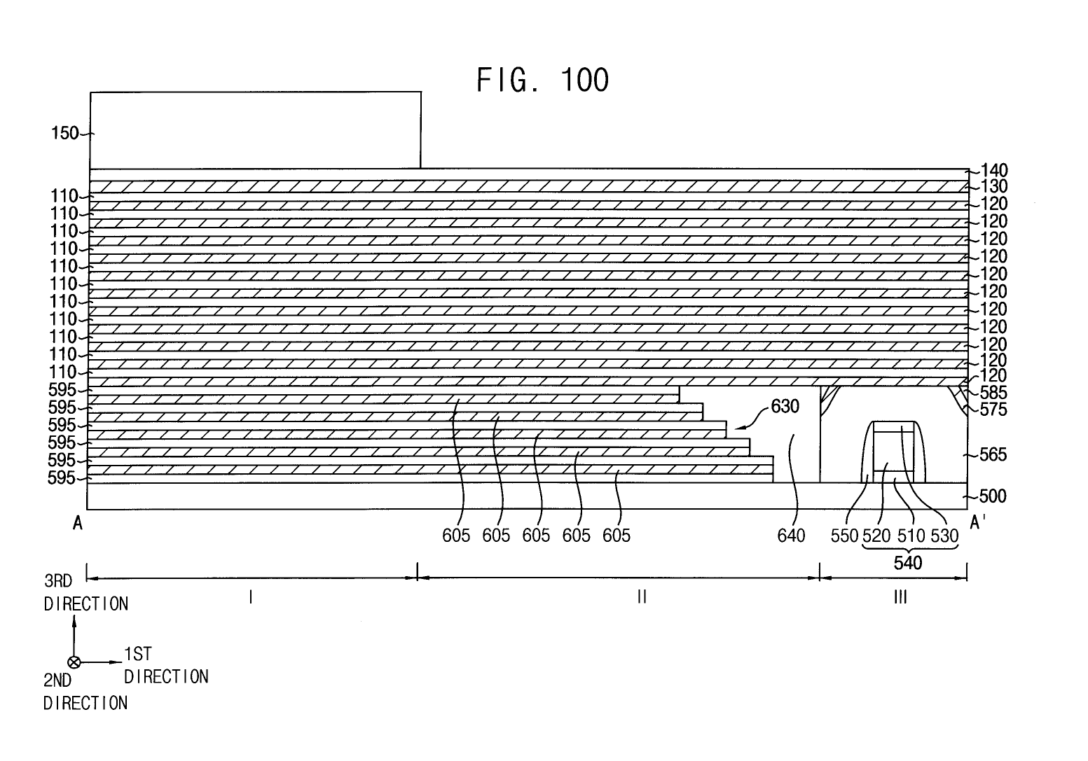

Referring to FIGS. 99 and 100, processes substantially the same as or similar to those illustrated with reference to FIGS. 1 to 4 may be performed.

That is, sacrificial layer 120 and an insulation layer 110 may be alternately and repeatedly formed on the second mold structure 630, the third lower insulating interlayer pattern 640 and the exposed top surface of the lower insulating interlayer pattern 565, and a reference layer including a polish stop layer 130 and an upper insulation layer 140 may be formed on an uppermost one of the insulation layers 110.

A first photoresist pattern 150 may be formed on the reference layer. The first photoresist pattern 150 may not cover the second and third regions II and III of the substrate 500 but partially cover the first region I of the substrate 500. In example embodiments, the first photoresist pattern 150 may have a rectangular shape reduced from the first region I at a given ratio in a top view.

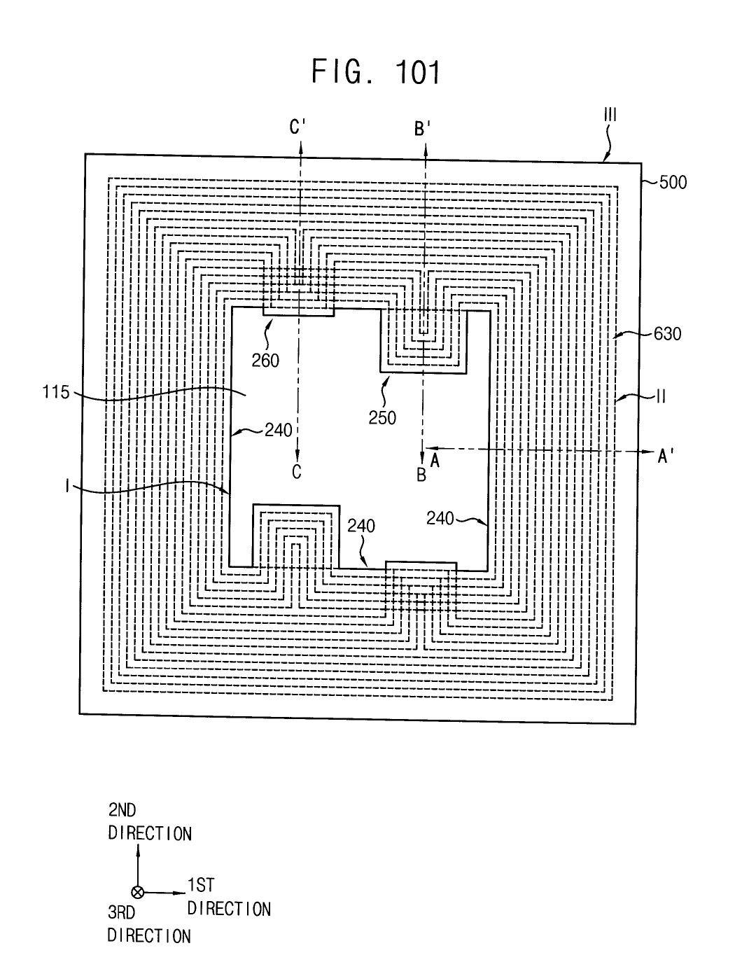

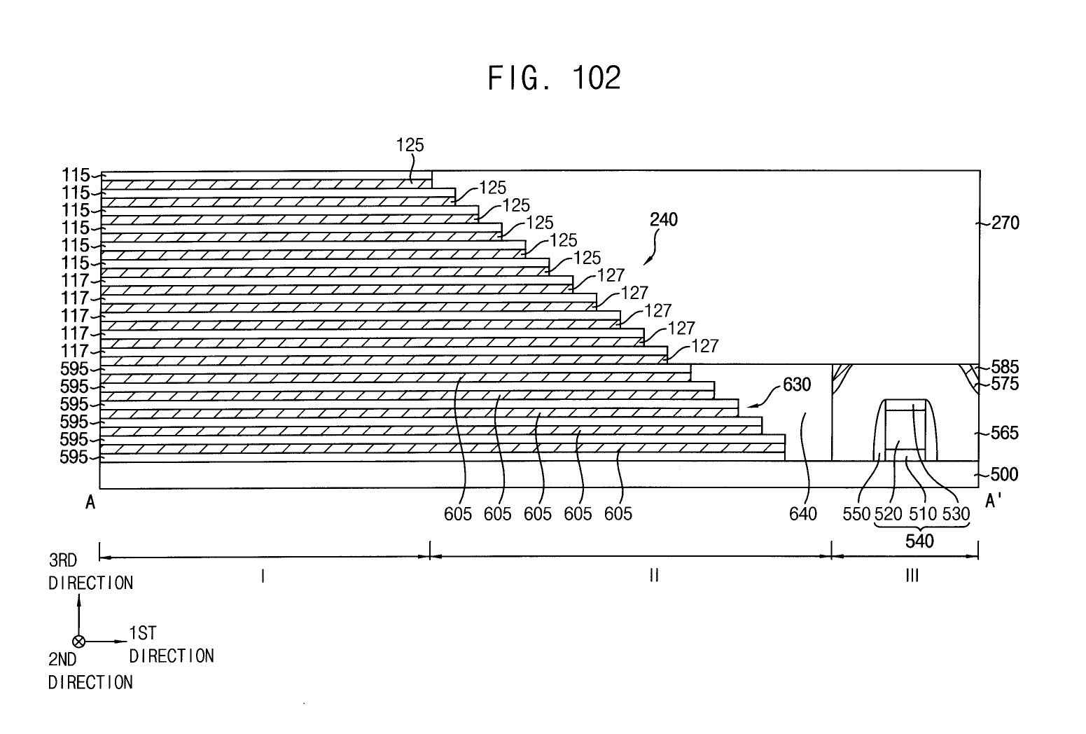

Referring to FIGS. 101 and 102, processes substantially the same as or similar to those illustrated with reference to FIGS. 5 to 30 may be performed.

Thus, a first mold structure including first and second pattern structures may be formed on the second mold structure 630, and a first insulating interlayer pattern 270 surrounding a sidewall of the first mold structure may be formed. The first mold structure may have a staircase shape of which a width may gradually decrease from a bottom level to a top level at a constant first ratio at a first area, a staircase shape of which a width may decrease from a bottom level to a top level at a changing second ratio at a second area, a staircase shape of which a width may decrease from a bottom level to a top level at a changing third ratio at a third area. Thus, the second mold structure 630 and the first mold structure as a whole may have a staircase of which a width may gradually decrease from a bottom level to a top level at the constant first ratio at the first area.

The first pattern structure may include a plurality of first insulation layer patterns 115 and a plurality of first sacrificial layer patterns 125 alternately stacked, and the second pattern structure may include a plurality of second insulation layer patterns 117 and a plurality of second sacrificial layer patterns 127 alternately stacked.

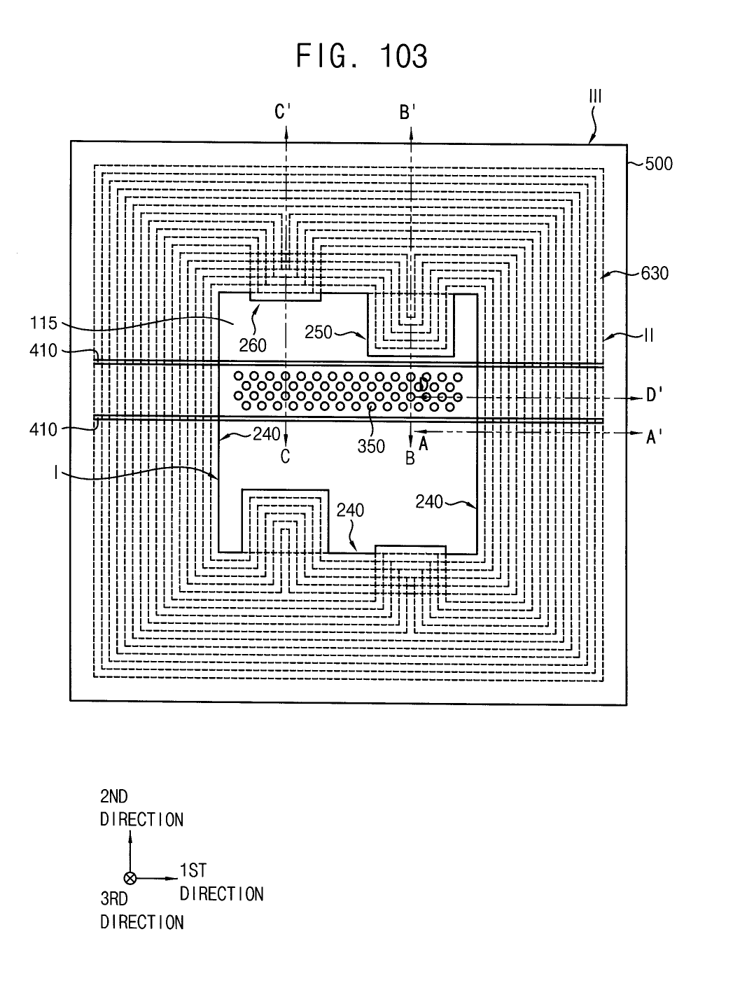

Referring to FIGS. 103, 104, 105 and 106, processes substantially the same as or similar to those illustrated with reference to FIGS. 31 to 47 may be performed.

Thus, a channel 330 may be formed through the first mold structure and the second mold structure 630 in the first region I on the substrate 500, and the first and second sacrificial layer patterns 125 and 127 and the lower sacrificial layer patterns 605 may be replaced by gate electrodes 390 and second blocking layer patterns 380. A conductive pad 395 extending in the first direction from each gate electrode 390 and an insulation pad 126 and 128 extending in the second direction from each gate electrode 390 may be formed in the second region II. A tunnel insulation layer pattern 320, a charge storage layer pattern 310, a first blocking layer pattern 300 may be formed between the channel 330 and each gate electrode 390.

Processes substantially the same as or similar to those illustrated with reference to FIGS. 43 to 47 may be performed to form a bit line contact 450, a first contact plug 460, a bit line 470 and a first wiring 480. Thus, the vertical non-volatile memory device may be manufactured.

While example embodiments have been particularly shown and described, it will be understood by one of ordinary skill in the art that variations in form and detail may be made therein without departing from the spirit and scope of the claims.

1. A semiconductor memory device, comprising:
a memory cell array region comprising an array of vertically arranged memory cells intersecting a stack of horizontally extending first connection lines;
a connection region adjacent the memory cell array region in a first direction in a top view, wherein the stack of the first connection lines extends from the memory cell array region into the connection region to define a first staircase-shaped structure in the connection region, and wherein ends of the first connection lines constitute treads of the first staircase-shaped structure;
a non-active region comprising second connection lines which define a second staircase-shaped structure in which ends of the second connection lines constitute treads of the second staircase-shaped structure,
wherein the second staircase-shaped structures comprises a staircase protrusion section located adjacent the memory cell array region in a second direction in the top view, the second direction perpendicular the first direction, and treads of the staircase protrusion section includes first tread portion protruding from second tread portions in the top view, the first tread potions extending perpendicular to the first direction in the top view.

2. The semiconductor memory device of claim 1, wherein the first tread portions protrude in a direction towards the memory cell array region in the top view.

3. The semiconductor memory device of claim 1, wherein the first tread portions protrude in a direction away from the memory cell array region in the top view.

4. The semiconductor memory device of claim 1, wherein the staircase protrusion section is a first staircase protrusion section, and further comprising a second stair protrusion section located on an opposite side of the memory cell array region relative the first staircase protrusion section.

5. The semiconductor memory device of claim 1, comprising two or more staircase protrusion sections on each of opposite sides of the memory cell array region

6. The semiconductor memory device of claim 1, wherein the staircase protrusion section is a first staircase protrusion section, and further comprising a second stair protrusion section located on a same side of the memory cell array region relative the first staircase protrusion section and closer to the memory cell array region relative to the first staircase protrusion section.

7. The semiconductor memory device of claim 1, wherein the first connections lines of the connection region are contained in same respective layers as the second connection lines of the non-active region.

8. The semiconductor memory device of claim 1, wherein a cut-line is interposed between the memory cell array area and the staircase protrusion section.

9. The semiconductor device of claim 1, wherein the first connection lines are conductive.

10. The semiconductor device of claim 9, wherein the first connection lines are word lines, and the ends of the first connection lines include respective word line pad areas.

11. A semiconductor memory device, comprising:
stack of layers; and
an isolating structure separating the stack of layers to define a active region on one side of the isolating structure and a non-active region on the other side of the isolating structure;
the active region including a memory cell array region containing a first portion of the layers, and a connection region in which a second portion of the layers defines a staircase-shaped structure, wherein ends of the second portion of the layers constitute treads of the staircase-shaped structure, and
the non-active region including a third portion of the layers, wherein the third portion of the layers includes a photolithographic reference mark pattern.

12. The semiconductor memory device of claim 11, wherein the third portion of the layers in the non-active region defines a second staircase-shaped structure, and ends of the third portion of the layers constitute treads of the second staircase-shaped structure.

13. The semiconductor memory device of claim 12, wherein at least one of the treads of the second staircase-shaped structure constitutes the photolithographic reference mark pattern.

14. The semiconductor memory device of claim 12, wherein the at least one of the treads of the second staircase-shaped structure protrudes in a direction towards or away from the memory cell array region.

15. The semiconductor device of claim 11, wherein the stack of layers comprises alternating first and second layers, and each first layer is an insulating layer.

16. The semiconductor device of claim 15, wherein each second layer within the cell region is a word line, and the ends of the second portion of the layers include respective word line pad areas.

17. The semiconductor device of claim 11, wherein the isolating structure is a cut line.

18. A semiconductor memory device, comprising:
a substrate including a cell region and peripheral region;
the cell region including a memory cell array region, a staircase-shaped connection region connected to memory cells of the memory cell array region, and a photolithographic reference mark pattern.

19. The semiconductor device of claim 18, further comprising a staircase-shaped structure which is separate from the staircase-shaped connection region and electrically isolated from the memory cells of the memory cell array region, wherein the photolithographic reference mark pattern is located within the staircase-shaped structure.

20. The semiconductor device of claim 18, wherein the staircase-shape connection region includes a plurality of treads having respective word line pads.

21-34. (canceled)
